(19) United States
(12) Patent Application Publication
(10) Pub. No.: US 2025/0204186 A1
(43) Pub. Date: Jun. 19, 2025

(54) DISPLAY PANEL AND DISPLAY DEVICE

(71) Applicants: Chengdu BOE Optoelectronics Technology Co., Ltd., Sichuan (CN); BOE TECHNOLOGY GROUP CO., LTD., Beijing (CN)

(72) Inventors: Hongjun ZHOU, Beijing (CN); Lianbin LIU, Beijing (CN); Hengzhen LIANG, Beijing (CN); Ji WANG, Beijing (CN); Xingliang SONG, Beijing (CN); Wenxiao NIU, Beijing (CN); Yingjun DENG, Beijing (CN); Xinpeng WANG, Beijing (CN); Zhihui YAN, Beijing (CN); Hang MIN, Beijing (CN)

(21) Appl. No.: 18/851,713

(22) PCT Filed: Jul. 15, 2022
(86) PCT No.: PCT/CN2022/106113

§ 371 Date: Sep. 27, 2024

(51) Int. Cl. H10K 59/131; H10K 59/121; H10K 59/35; H10K 102/00

(52) U.S. Cl. CPC H10K 59/1315; H10K 59/1213; H10K 59/353; H10K 2102/341

(57) ABSTRACT

A display panel, includes: a base substrate; an electrode layer, located on a side of the base substrate, where the electrode layer includes a plurality of electrode parts configured to form first electrodes of light-emitting units, orthographic projections of the electrode parts on the base substrate are distributed in an array along a first direction and a second direction, the first direction intersects with the second direction, electrode columns are formed by the electrode parts distributed in the second direction, and at least part of the electrode columns includes electrode parts configured to form the first electrodes of the light-emitting units of different colors; a plurality of pixel driving circuits, provided corresponding to the electrode parts, where the pixel driving circuits are connected to corresponding electrode parts, respectively, and the pixel driving circuits are configured to drive the light-emitting units to emit light; and a plurality of data lines.

### TECHNICAL FIELD

This disclosure relates to the field of display technology, and in particular, to a display panel and a display device.

### BACKGROUND

In the related art, one data line in the display panel may need to provide data signals to sub-pixel units of different colors, so the source driving circuit in the display panel may have high power consumption. In addition, high-frequency display panels are also prone to problems of color shift.

It is to be noted that the above information disclosed in this background section is only for enhancing understanding the context of the disclosure and, therefore, may contain information that does not form the prior art that is already known to those skilled in the art.

### SUMMARY

According to an aspect of this disclosure, a display panel is provided, wherein the display panel includes: a base substrate, an electrode layer, a plurality of pixel driving circuits, and a plurality of data lines. The electrode layer is located on a side of the base substrate, where the electrode layer includes a plurality of electrode parts configured to form first electrodes of light-emitting units, orthographic projections of the electrode parts on the base substrate are distributed in an array along a first direction and a second direction, the first direction intersects with the second direction, electrode columns are formed by the electrode parts distributed in the second direction, and at least part of the electrode columns includes electrode parts configured to form the first electrodes of the light-emitting units of different colors. The pixel driving circuits are provided corresponding to the electrode parts, where the pixel driving circuits are connected to corresponding electrode parts, respectively, and the pixel driving circuits are configured to drive the light-emitting units to emit light. Orthographic projections of the data lines on the base substrate extend along the second direction, the data lines are connected to the pixel driving circuits and configured to provide data signals to connected pixel driving circuits, respectively, and multiple ones of the pixel driving circuits connected to a same one of the data lines are configured to drive the light-emitting units of a same color.

In an exemplary embodiment of this disclosure, the electrode parts include first electrode parts and second electrode parts, and the first electrode parts and the second electrode parts are respectively configured to form the first electrodes of the light-emitting units of different colors. The electrode columns include: a first electrode column and a second electrode column. The first electrode column includes multiple ones of the first electrode parts and multiple ones of the second electrode parts, where in the first electrode column, orthographic projections of the first electrode parts and the second electrode parts on the base substrate are alternately distributed along the second direction. The second electrode column includes multiple ones of the first electrode parts and multiple ones of the second electrode parts, where in the second electrode column, orthographic projections of the first electrode parts and the second electrode parts on the base substrate are alternately distributed along the second direction. In the first electrode column and the second electrode column, the first electrode part and the second electrode part are located in a same row. The data lines include: a first data line and a second data line. A pixel driving circuit connected to the first data line is connected to the first electrode parts in the first electrode column and the second electrode column; and a pixel driving circuit connected to the second data line is connected to the second electrode parts in the first electrode column and the second electrode column.

In an exemplary embodiment of this disclosure, the electrode parts further include third electrode parts, where the first electrode parts, the second electrode parts, and the third electrode parts are respectively configured to form the first electrodes of the light-emitting units of different colors. The electrode columns further include: a third electrode column and a fourth electrode column, and the first electrode column, the third electrode column, the second electrode column and the fourth electrode column are alternately distributed in sequence along the first direction. The third electrode column includes multiple ones of the third electrode parts, and orthographic projections of the third electrode parts in the third electrode column on the base substrate are spaced apart in the second direction. The fourth electrode column includes multiple ones of the third electrode parts, and orthographic projections of the third electrode parts in the fourth electrode column on the base substrate are spaced apart in the second direction.

In an exemplary embodiment of this disclosure, orthographic projections of the pixel driving circuits on the base substrate are distributed in an array along the first direction and the second direction, pixel circuit columns are formed by the pixel driving circuits distributed in the second direction, and the pixel circuit columns include a first pixel circuit column and a second pixel circuit column. Pixel driving circuits in the first pixel circuit column are connected to the electrode parts in the first electrode column. Pixel driving circuits in the second pixel circuit column are connected to the electrode parts in the second electrode column. The first data line is connected to the pixel driving circuit connected to the first electrode parts in the first electrode column and the second electrode column. The second data line is connected to the pixel driving circuit connected to the second electrode parts in the first electrode column and the second electrode column.

In an exemplary embodiment of this disclosure, orthographic projections of the pixel driving circuits on the base substrate are distributed in an array along the first direction and the second direction, pixel circuit columns are formed by the pixel driving circuits distributed in the second direction, and the pixel circuit columns include a first pixel circuit column and a second pixel circuit column. The first data line is connected to pixel driving circuits in the first pixel circuit column, and the second data line is connected to pixel driving circuits in the second pixel circuit column. Pixel driving circuits in the first pixel circuit column are connected to the first electrode parts in the first and second electrode columns. Pixel driving circuits in the second pixel circuit column are connected to the second electrode parts in the first and second electrode columns.

In an exemplary embodiment of this disclosure, the display panel further includes: a first bridging part and a second bridging part. The first bridging part is connected between the pixel driving circuit in the first pixel circuit column and the first electrode part in the second electrode column. The second bridging part is connected between the pixel driving circuit in the second pixel circuit column and the second electrode part in the first electrode column.

In an exemplary embodiment of this disclosure, the display panel further includes a first signal line and a second signal line. An orthographic projection of the first signal line on the base substrate extends along the first direction; and an orthographic projection of the second signal line on the base substrate extends along the first direction, where the first signal line and the second signal line are configured to provide stable voltage signals. The first bridging part includes a first extension portion, the second bridging part includes a second extension portion, and an orthographic projection of the first extension portion on the base substrate and an orthographic projection of the second extension portion on the base substrate extend along the first direction. The orthographic projection of the first extension portion on the base substrate at least partially overlaps with the orthographic projection of the first signal line on the base substrate, and/or the orthographic projection of the second extension portion on the base substrate at least partially overlaps with the orthographic projection of the second signal line on the base substrate.

In an exemplary embodiment of this disclosure, the pixel driving circuit includes a driving transistor, a first transistor, and a seventh transistor, a first electrode of the first transistor is connected to a first initial signal line, a second electrode of the first transistor is connected to a gate of the driving transistor, a first electrode of the seventh transistor is connected to a second initial signal line, and a second electrode of the seventh transistor is connected to a second electrode of the driving transistor. The first initial signal line forms the first signal line, and the second initial signal line forms the second signal line; or, the first initial signal line forms the second signal line, and the second initial signal line forms the first signal line.

In an exemplary embodiment of this disclosure, the pixel driving circuit includes a driving transistor and a first transistor, a first electrode of the first transistor is connected to a first initial signal line, and a second electrode of the first transistor is connected to a gate of the driving transistor. Two adjacent first initial signal lines form the first signal line and the second signal line respectively.

In an exemplary embodiment of this disclosure, the display panel further includes a third signal line, where an orthographic projection of the third signal line on the base substrate extends along the second direction, and the third signal line is configured to provide a stable voltage signal. The second bridging part further includes a third extension portion, an orthographic projection of the third extension portion on the base substrate extends along the second direction, and the orthographic projection of the third extension portion on the base substrate at least partially overlaps with the orthographic projection of the third signal line on the base substrate.

In an exemplary embodiment of this disclosure, the display panel further includes a fourth signal line, where an orthographic projection of the fourth signal line on the base substrate extends along the second direction, and the fourth signal line is configured to provide a stable voltage signal. The first bridging part further includes a sixth extension portion, where an orthographic projection of the sixth extension portion on the base substrate extends along the second direction, and the orthographic projection of the sixth extension portion on the base substrate at least partially overlaps with the orthographic projection of the fourth signal line on the base substrate.

In an exemplary embodiment of this disclosure, the pixel driving circuit includes a driving transistor and a second transistor, where a first electrode of the second transistor is connected to a gate of the driving transistor, and a second electrode of the second transistor is connected to a second electrode of the driving transistor. The display panel further includes: a first active layer, located between the base substrate and the electrode layer, where the first active layer includes a second active part configured to form a channel region of the second transistor. The second bridging part includes a second extension portion, a third extension portion, and a seventh extension portion connected between the second extension portion and the third extension portion, where an orthographic projection of the second extension portion on the base substrate extends along the first direction, an orthographic projection of the third extension portion on the base substrate extends along the second direction, and an orthographic projection of the seventh extension portion on the base substrate at least partially overlaps with an orthographic projection of the second active part on the base substrate.

In an exemplary embodiment of this disclosure, the display panel further includes a third bridging part and a fourth bridging part. The third bridging part is connected between the pixel driving circuit in the first pixel circuit column and the first electrode part in the first electrode column. The fourth bridging part is connected between the pixel driving circuit in the second pixel circuit column and the second electrode part in the second electrode column.

In an exemplary embodiment of this disclosure, the first bridging part is connected between a pixel driving circuit and an electrode part located in a same row, the second bridging part is connected between a pixel driving circuit and an electrode part located in a same row, the third bridging part is connected between a pixel driving circuit and an electrode part located in a same row and column, and the fourth bridging part is connected between a pixel driving circuit and an electrode part located in a same row and column.

In an exemplary embodiment of this disclosure, a parasitic capacitance formed by the first bridging part and other structures is C1, a parasitic capacitance formed by the second bridging part and other structures is C2, a parasitic capacitance formed by the third bridging part and other structures is C3, and a parasitic capacitance formed by the fourth bridging part and other structures is C4. Herein, C1=N1*C3, C2=N2*C4, where N1 is greater than or equal to 70% and less than or equal to 130%, and N2 is greater than or equal to 70% and less than or equal to 130%.

In an exemplary embodiment of this disclosure, the display panel further includes a plurality of third signal lines, where orthogonal projections of the third signal lines on the base substrate are spaced apart along the first direction and extend along the second direction, and the third signal lines are configured to provide a stable voltage signal. The third bridging part includes a fourth extension portion, the fourth bridging part includes a fifth extension portion, and an orthogonal projection of the fourth extension portion on the base substrate and an orthogonal projection of the fifth extension portion on the base substrate extend along the second direction. The orthographic projection of the fourth extension portion on the base substrate at least partially overlaps with an orthographic projection of a third signal line on the base substrate, and the orthographic projection of the fifth extension portion on the base substrate at least partially overlaps with an orthographic projection of another third signal line on the base substrate.

In an exemplary embodiment of this disclosure, the pixel driving circuit includes a driving transistor, and the display panel further includes a first power line connected to a first electrode of the driving transistor, where the first power line forms the third signal line.

In an exemplary embodiment of this disclosure, the display panel further includes a first source-drain layer and a second source-drain layer. The first source-drain layer is located between the base substrate and the electrode layer. The second source-drain layer is located between the first source-drain layer and the electrode layer. The first bridging part, the second bridging part, the third bridging part, and the fourth bridging part are located on the electrode layer; or, the first bridging part, the second bridging part, the third bridging part, and the fourth bridging part are located on a conductive layer between the second source-drain layer and the electrode layer; or, the first bridging part, the second bridging part, the third bridging part, and the fourth bridging part are located on a conductive layer between the second source-drain layer and the first source-drain layer.

In an exemplary embodiment of this disclosure, the display panel further includes a source driving circuit, where the source driving circuit includes a data latch and a data reset circuit. The data latch is configured to receive a plurality of original data signals, where the original data signals include multiple pieces of serial original data, the original data in at least part of the original data signals is configured to drive the light-emitting units of different colors. The data reset circuit is configured to generate a reset data signal according to the original data signal, where the reset data signal includes multiple pieces of serial reset data, and the reset data in the reset data signal is configured to drive the light-emitting units of the same color.

In an exemplary embodiment of this disclosure, the pixel driving circuit includes a driving transistor and a second transistor, a first electrode of the second transistor is connected to a gate of the driving transistor, and a second electrode of the second transistor is connected to a second electrode of the driving transistor. The display panel further includes a first active layer located between the base substrate and the electrode layer, where the first active layer includes a second active part, and the second active part is configured to form a channel region of the second transistor. The electrode layer further includes an addition part connected to the electrode part, where an orthographic projection of the addition part on the base substrate at least partially overlaps with an orthographic projection of the second active part on the base substrate.

In an exemplary embodiment of this disclosure, the pixel driving circuit includes a driving transistor and a first transistor, a first electrode of the first transistor is connected to a first initial signal line, and a second electrode of the first transistor is connected to a gate of the driving transistor. The display panel further includes a second gate layer and a first source-drain layer. The second gate layer is located between the base substrate and the electrode layer, where the second gate layer includes the first initial signal line, and an orthographic projection of the first initial signal line on the base substrate extends along the first direction. The first source-drain layer is located between the second gate layer and the electrode layer, where the first source-drain layer includes a first initial connection line, an orthographic projection of the first initial connection line on the base substrate extends along the second direction, the first initial connection line is connected, through a via, to the first initial signal line having orthographic projection on the base substrate intersects with the orthographic projection of the first initial connection line, and the first initial connection line is connected to the first electrode of the first transistor.

In an exemplary embodiment of this disclosure, the display panel includes a plurality of repeating units distributed in an array along the first direction and the second direction. Each of the repeating units includes two of the pixel driving circuits distributed along the first direction, and the two of pixel driving circuits in the each of the repeating units are arranged in mirror symmetry. The pixel driving circuit includes a driving transistor and a capacitor, a first electrode of the capacitor is connected to a gate of the driving transistor, and a second electrode of the capacitor is connected to a first power line. The display panel further includes a second gate layer and a second source-drain layer. The second gate layer is located between the base substrate and the electrode layer, where the second gate layer includes a third conductive part, and the third conductive part is configured to form the second electrode of the capacitor. The second source-drain layer is located between the second gate layer and the electrode layer, where the second source-drain layer includes the first power line, and two adjacent first power lines in the each of the repeating units are connected. Two adjacent third conductive parts in two of the repeating units adjacent in the first direction are connected.

In an exemplary embodiment of this disclosure, the display panel further includes a first source-drain layer, located between the second gate layer and the second source-drain layer, where the first source-drain layer includes a power connection line, an orthographic projection of the power connection line on the base substrate extends along the first direction, and the power connection lines are respectively connected to the third conductive part and the first power line through vias.

In an exemplary embodiment of this disclosure, the first power line includes: a first power line segment, a second power line segment, and a third power line segment, and the second power line segment is connected between the first power line segment and the third power line segment. A size, in the first direction, of an orthographic projection of the second power line segment on the base substrate is greater than a size, in the first direction, of an orthogonal projection of the first power line segment on the base substrate, and the size, in the first direction, of the orthographic projection of the second power line segment on the base substrate is greater than a size, in the first direction, of an orthogonal projection of the third power line segment on the base substrate. In a same repeating unit, two adjacent ones of the second power line segments are connected, and orthographic projections of the connected second power line segments on the base substrate cover orthographic projections of the electrode parts, intersecting with the connected second power line segments, on the base substrate.

In an exemplary embodiment of this disclosure, the first power line includes: a first power line segment, a second power line segment, and a third power line segment, and the second power line segment is connected between the first power line segment and the third power line segment. A size, in the first direction, of an orthographic projection of the second power line segment on the base substrate is greater than a size, in the first direction, of an orthogonal projection of the first power line segment on the base substrate, and the size, in the first direction, of the orthographic projection of the second power line segment on the base substrate is greater than a size, in the first direction, of an orthogonal projection of the third power line segment on the base substrate. In a same repeating unit, two adjacent ones of the first power line segments are connected, two adjacent ones of the third power line segments are connected, an opening is formed on the connected first power line segments and/or the connected third power line segments, and the opening is located in a light-transmitting area of the display panel.

According to an aspect of this disclosure, a display device is provided and includes the above-mentioned display panel.

It is to be understood that both the foregoing general description and the following detailed description are exemplary and explanatory only and are not restrictive of this disclosure.

### BRIEF DESCRIPTION OF THE DRAWINGS

The accompanying drawings, which are incorporated in and constitute a part of this specification, illustrate embodiments consistent with the disclosure and together with the description serve to explain the principles of the disclosure. Apparently, the drawings in the following description are only some embodiments of this disclosure, and those skilled in the art can obtain other drawings according to these drawings without creative efforts.

FIG. 1 is a schematic structural diagram of a display panel in the related art.

FIG. 2 shows a timing diagram of different data lines when the display panel displays a pure red picture.

FIG. 3 is a schematic structural diagram of a display panel according to another exemplary embodiment of this disclosure.

FIG. 4 is a timing diagram of signals on data lines at different locations in the fan-out area of the display panel.

FIG. 5 is a schematic structural diagram of a display panel according to an exemplary embodiment of this disclosure.

FIG. 6 is a schematic structural diagram of a display panel according to another exemplary embodiment of this disclosure.

FIG. 7 is a distribution diagram of the pixel driving circuits in FIG. 6.

FIG. 8 is a schematic structural diagram of a display panel according to another exemplary embodiment of this disclosure.

FIG. 9 is a distribution diagram of the pixel driving circuits in FIG. 8.

FIG. 10 is a schematic circuit structure diagram of a pixel driving circuit in the display panel according to an exemplary embodiment of this disclosure.

FIG. 11 is a timing diagram of each node signal in a driving method of the pixel driving circuit shown in FIG. 10.

FIG. 12 is a structural layout of a display panel according to an exemplary embodiment of this disclosure.

FIG. 13 is a structural layout of the first active layer in FIG. 12.

FIG. 14 is a structural layout of the first gate layer in FIG. 12.

FIG. 15 is a structural layout of the second gate layer in FIG. 12.

FIG. 16 is a structural layout of the first source-drain layer in FIG. 12.

FIG. 17 is a structural layout of the second source-drain layer in FIG. 12.

FIG. 18 is a structural layout of the bridging layer in FIG. 12.

FIG. 19 is a structural layout of the electrode layer in FIG. 12.

FIG. 20 is a structural layout of the first active layer and the first gate layer in

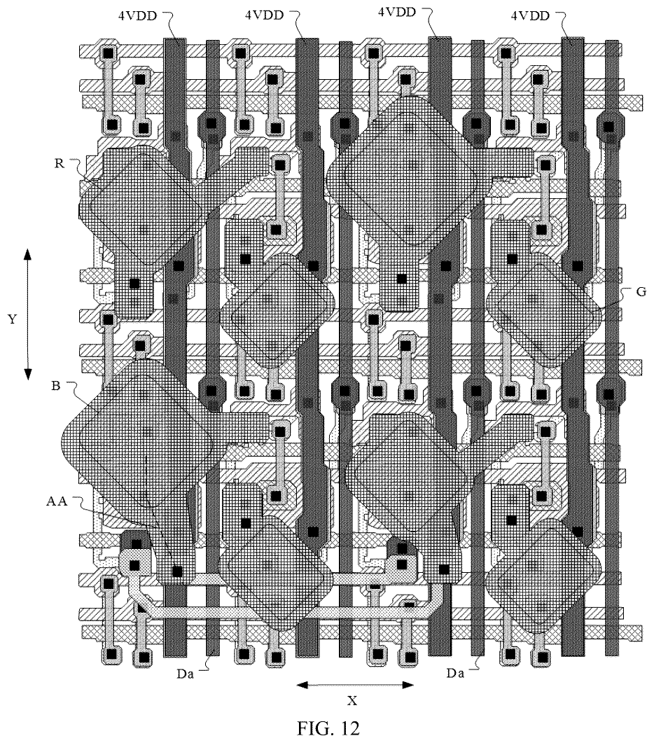

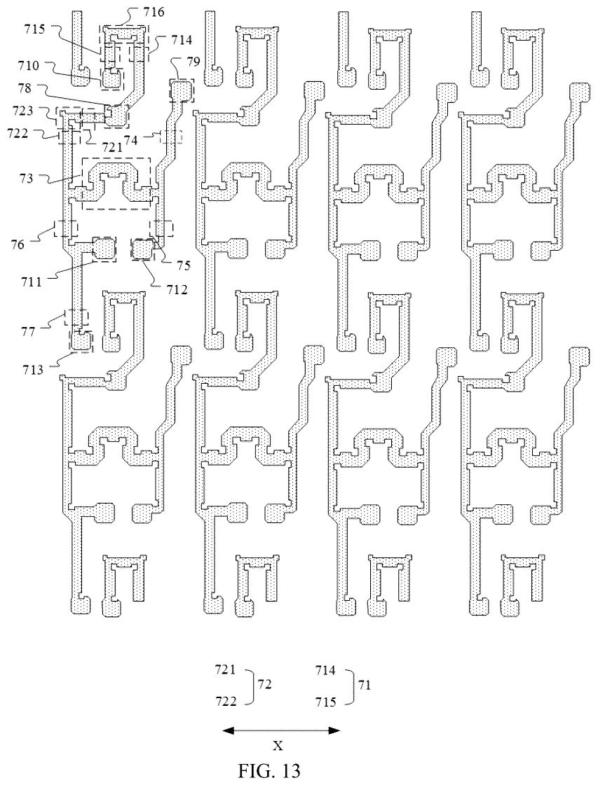

FIG. 12.

FIG. 21 is a structural layout of the first active layer, the first gate layer, and the second gate layer in FIG. 12.

FIG. 22 is a structural layout of the first active layer, the first gate layer, the second gate layer, and the first source-drain layer in FIG. 12.

FIG. 23 is a structural layout of the first active layer, the first gate layer, the second gate layer, the first source-drain layer, and the second source-drain layer in FIG. 12.

FIG. 24 is a structural layout of the first active layer, the first gate layer, the second gate layer, the first source-drain layer, the second source-drain layer, and the bridging layer in FIG. 12.

FIG. 25 is a partial cross-sectional view of the display panel shown in FIG. 12 taken along the dotted line AA.

FIG. 26 is a structural layout of a display panel according to another exemplary embodiment of this disclosure.

FIG. 27 is a structural layout of the first active layer, the first gate layer, the second gate layer, the first source-drain layer, the second source-drain layer, and the bridging layer in FIG. 26.

FIG. 28 is the structural layout of the bridging layer in FIG. 26.

FIG. 29 is a structural layout of a display panel according to another exemplary embodiment of this disclosure.

FIG. 30 is a structural layout of the first active layer, the first gate layer, the second gate layer, the first source-drain layer, the second source-drain layer, and the bridging layer in FIG. 29.

FIG. 31 is a structural layout of the bridging layer in FIG. 29.

FIG. 32 is a structural layout of a display panel according to an exemplary embodiment of this disclosure.

FIG. 33 is a structural layout of the first active layer in FIG. 32.

FIG. 34 is a structural layout of the first gate layer in FIG. 32.

FIG. 35 is a structural layout of the second gate layer in FIG. 32.

FIG. 36 is a structural layout of the first source-drain layer in FIG. 32.

FIG. 37 is a structural layout of the second source-drain layer in FIG. 32.

FIG. 38 is the structural layout of the bridging layer in FIG. 32.

FIG. 39 is a structural layout of the electrode layer in FIG. 32.

FIG. 40 is a structural layout of the first active layer and the first gate layer in

FIG. 32.

FIG. 41 is a structural layout of the first active layer, the first gate layer, and the second gate layer in FIG. 32.

FIG. 42 is a structural layout of the first active layer, the first gate layer, the second gate layer, and the first source-drain layer in FIG. 32.

FIG. 43 is a structural layout of the first active layer, the first gate layer, the second gate layer, the first source-drain layer, and the second source-drain layer in FIG. 32.

FIG. 44 is a structural layout of the first active layer, the first gate layer, the second gate layer, the first source-drain layer, the second source-drain layer, and the bridging layer in FIG. 32.

FIG. 45 is a partial cross-sectional view of the display panel shown in FIG. 32 taken along the dotted line BB.

FIG. 46 is a structural layout of a display panel according to another exemplary embodiment of this disclosure.

FIG. 47 is a structural layout of the electrode layer in FIG. 46.

FIG. 48 is a schematic circuit structure diagram of the pixel driving circuit in a display panel of this disclosure.

FIG. 49 is a timing diagram of each node in a driving method of the pixel driving circuit in FIG. 48.

FIG. 50 is a structural layout of a display panel according to an exemplary embodiment of this disclosure.

FIG. 51 is a structural layout of the shielding layer in FIG. 50.

FIG. 52 is a structural layout of the first active layer in FIG. 50.

FIG. 53 is a structural layout of the first gate layer in FIG. 50.

FIG. 54 is a structural layout of the second gate layer in FIG. 50.

FIG. 55 is a structural layout of the second active layer in FIG. 50.

FIG. 56 is a structural layout of the third gate layer in FIG. 50.

FIG. 57 is a structural layout of the first source-drain layer in FIG. 50.

FIG. 58 is a structural layout of the second source-drain layer in FIG. 50.

FIG. 59 is a structural layout of the electrode layer in FIG. 50.

FIG. 60 is a structural layout of the shielding layer and the first active layer in

FIG. 50.

FIG. 61 is a structural layout of the shielding layer, the first active layer, and the first gate layer in FIG. 50.

FIG. 62 is a structural layout of the shielding layer, the first active layer, the first gate layer, and the second gate layer in FIG. 50.

FIG. 63 is a structural layout of the shielding layer, the first active layer, the first gate layer, the second gate layer, and the second active layer in FIG. 50.

FIG. 64 is a structural layout of the shielding layer, the first active layer, the first gate layer, the second gate layer, the second active layer and the third gate layer in FIG. 50.

FIG. 65 is a structural layout of the shielding layer, the first active layer, the first gate layer, the second gate layer, the second active layer, the third gate layer, and the first source-drain layer in FIG. 50.

FIG. 66 is a structural layout of the shielding layer, the first active layer, the first gate layer, the second gate layer, the second active layer, the third gate layer, the first source-drain layer, and the second source-drain layer in FIG. 50.

FIG. 67 is a partial cross-sectional view of the display panel shown in FIG. 50 taken along the dotted line CC.

FIG. 68 is a structural layout of a display panel according to another exemplary embodiment of this disclosure.

FIG. 69 is a structural layout of the first active layer, the first gate layer, the second gate layer, the first source-drain layer, the second source-drain layer, and the bridging layer in FIG. 68.

FIG. 70 is a structural layout of the bridging layer in FIG. 68.

FIG. 71 is a schematic structural diagram of a source driving circuit in a display panel of this disclosure.

### DETAILED DESCRIPTION

Exemplary embodiments will now be described more fully with reference to the accompanying drawings. Exemplary embodiments may, however, be embodied in many forms and should not be construed as limited to the embodiments set forth herein. Rather, these embodiments are provided so that this disclosure will be thorough and complete, and will fully convey the concept of exemplary embodiments to those skilled in the art. The same reference numerals in the drawings denote the same or similar structures, and thus their detailed descriptions will be omitted.

The terms “a”, “an”, “the”, “said” and “at least one” are configured to indicate the presence of one or more elements/components/etc.; the terms “comprise/include” and “have” are configured to indicate an open inclusion and means that there may be additional elements/components/etc. in addition to the listed elements/components/etc.

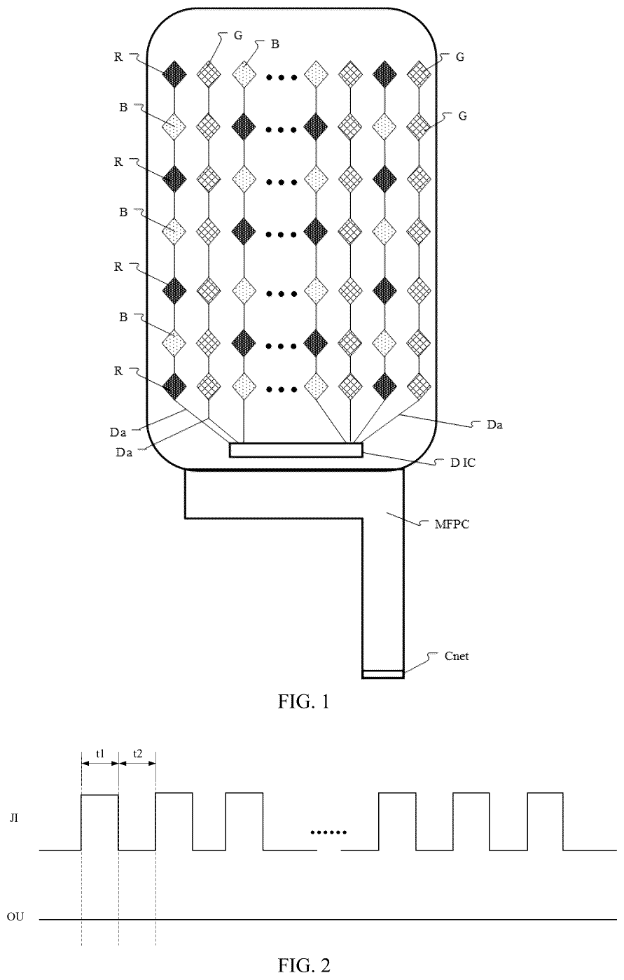

As shown in FIG. 1, it is a schematic structural diagram of a display panel in the related art. The display panel may include a red sub-pixel R, a green sub-pixel G, a blue sub-pixel B, a data line Da, a source driving circuit D IC, a main flexible circuit board MFPC, and a connector Cnet. Each sub-pixel may include a light-emitting unit and a pixel driving circuit for driving the light-emitting unit, and the light-emitting unit may be an OLED light-emitting unit. The data line Da connects multiple sub-pixels located in the same column, and the data line Da is configured to provide data signals to the sub-pixels connected thereto. The source driving circuit D IC is configured to provide data signals to each data line. In addition, the source driving circuit D IC can be connected to other driving chips through the main flexible circuit board MFPC and connector Cnet. As shown in FIG. 1, in the display panel according to this exemplary embodiment, the same data line needs to provide data signals to the red sub-pixel R and the blue sub-pixel B respectively.

However, the luminous efficiency of the luminescent material corresponding to the red light-emitting unit is much higher than that of the luminescent material corresponding to the blue light-emitting unit. Under the same gray scale, the data signal required by the blue sub-pixel and the data signal required by the red sub-pixel are different in size, that is, the data signal voltage range corresponding to the blue sub-pixel is greater than the data signal voltage range corresponding to the red sub-pixel. For example, when the driving transistor in the pixel driving circuit is a P-type transistor, in the case of a white screen, the voltage of the data signal required by the blue sub-pixel is smaller than the voltage of the data signal required by the red sub-pixel. Therefore, when the display panel is scanned row by row in the column direction, the voltage on the data line Da needs to jump between the data signal voltage required by the red sub-pixel and the data signal voltage required by the blue sub-pixel.

When the display panel displays a pure red or pure blue picture, the voltage fluctuation on the data line Da is greater. For example, as shown in FIG. 2, it is the timing diagram of different data lines when the display panel displays a pure red picture. Herein, JI represents the timing diagram of the odd-numbered column data lines in FIG. 1, and OU represents the timing diagram of the even-numbered column data lines in FIG. 1. In the first stage t1, a certain odd-numbered column data line provides data signals to blue sub-pixels, and an even-numbered column data line provides data signals to green sub-pixels. In the second stage t2, this data line provides data signals to red sub-pixels, and the even-numbered column data line provides data signals to the green subpixels. In the first stage t1, the gray level corresponding to the blue sub-pixels and the green sub-pixels is 0; in the second stage t2, the red sub-pixels correspond to the maximum gray level, and the gray level corresponding to the green sub-pixels is 0. Therefore, when the display panel displays pure red, the voltage on the data line Da fluctuates greatly. In the same way, when the display panel displays pure blue, the voltage fluctuation on the data line Da is also great.

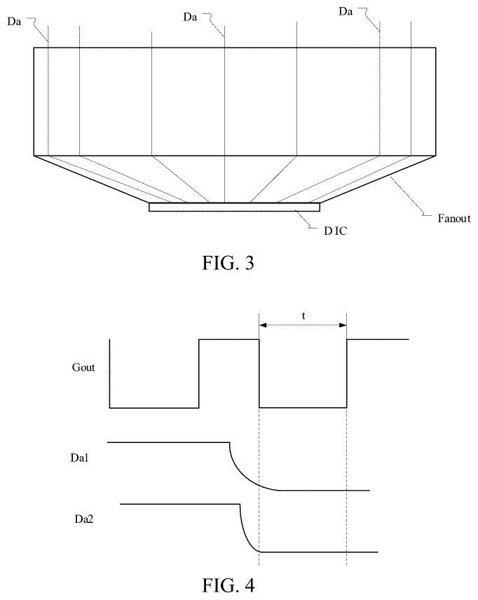

Large voltage fluctuations on the data line Da will cause the power consumption of the source driving circuit D IC to increase. In addition, in some display panels with high frequencies or large data signal delays, when the data lines alternately provide red data signals and blue data signals, it is easy to cause false provision in the data signals, resulting in color shift (also referred to as color cast). For example, as shown in FIG. 3, it is a schematic structural diagram of a display panel according to another exemplary embodiment of this disclosure. The display panel may include a fan-out area Fanout, and the data lines Da are fan out in the fan-out area Fanout and are connected to the source driving circuit D IC. In the fan-out area of the display panel, the lengths of the data lines on both sides of the fan-out area are longer, and the lengths of the data lines in the middle of the fan-out area are shorter, thereby resulting in a longer delay of the data signals on the data lines on both sides of the fan-out area, while the data signal delay of the data lines in the middle of the fan-out area is small. As shown in FIG. 4, it is a timing diagram of the signals on the data lines at different locations in the fan-out area of the display panel. Hrerein, Gout represents the timing diagram of data writing to the transistor gate in the pixel drive circuit, Da1 represents the timing diagram of the signal on the data lines on both sides of the fan-out area, and Da2 represents the timing diagram of the signal on the data lines in the middle of the fan-out area. After the data writing transistor is turned on, the data line can write data signals to the pixel driving circuit. As shown in FIG. 4, in the data writing stage t, the data lines write the data signals to the pixel driving circuit. According to FIG. 4, it can be seen that the falling edge of the signal on the data lines on both sides of the fan-out area is longer, and the falling edge of the signal on the data lines in the middle of the fan-out area is shorter. The data lines on both sides of the fan-out area are prone to mistakenly sending data signals to the pixel driving circuit.

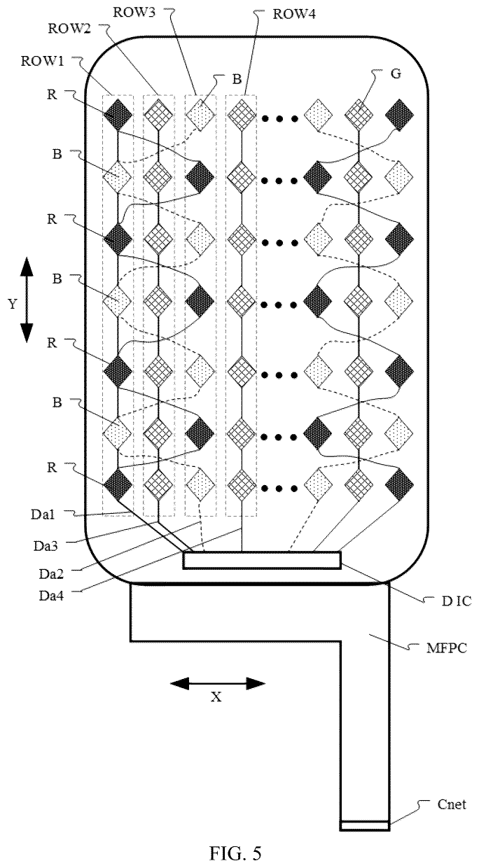

In view of above, exemplary embodiments provide a display panel. As shown in FIG. 5, it is a schematic structural diagram of a display panel according to an exemplary embodiment of this disclosure. The display panel can also include red sub-pixels R, green sub-pixels G, blue sub-pixels B, data lines, source driving circuit D IC, main flexible circuit board MFPC, and connector Cnet. In some embodiments, in the first direction X, red sub-pixels R, green sub-pixels G, blue sub-pixels B, and green sub-pixels G are distributed in sequence. The display panel includes a plurality of sub-pixel column groups, and each sub-pixel column group includes a first sub-pixel column ROW1, a second sub-pixel column ROW2, a third sub-pixel column ROW3, and a fourth sub-pixel column ROW4 that are sequentially adjacent. Herein, the first sub-pixel column ROW1 includes red sub-pixels R and blue sub-pixels B distributed alternately in the second direction Y; the second sub-pixel column ROW2 includes a plurality of green sub-pixels G distributed in the second direction Y; the third sub-pixel column ROW3 includes blue sub-pixels B and red sub-pixels R distributed alternately in the second direction Y; and the fourth sub-pixel column ROW4 includes a plurality of green sub-pixels G distributed in the second direction Y. The first direction X may intersect with the second direction Y. For example, the first direction X may be a row direction and the second direction may be a column direction. Compared with the display panel shown in FIG. 1, the data lines in the display panel shown in FIG. 5 include a first data line Da1, a second data line Da2, a third data line Da3, and a fourth data line Da4. In the same sub-pixel column group, the first data line Da1 alternately connects the red sub-pixels R in the first sub-pixel column ROW1 and the third sub-pixel column ROW3 row by row along the second direction Y, and the second data line alternately connects the blue sub-pixels B in the first sub-pixel column ROW1 and the third sub-pixel column ROW3 row by row along the second direction Y. The green sub-pixels G in the second sub-pixel column ROW2 are connected to the third data line Da3, and the green sub-pixels G in the fourth sub-pixel column ROW4 are connected to the fourth data line Da4. When displaying white, the first data line Da1 and the second data line Da2 only need to provide a stable voltage signal, and the first data line Da1 and the second data line Da2 no longer need to provide changing signals. Therefore, the above-mentioned technical problems of high power consumption and color shift of the source driving circuit D IC can be solved is this display panel.

As shown in FIG. 5, in this exemplary embodiment, the pixel driving circuit and the light-emitting unit in the same sub-pixel are connected. The first data line Da1 and the second data line Da2 may be connected to pixel driving circuits in different sub-pixel columns by detour wiring. In some embodiments, the position where the first data line Da1 and the second data line Da2 intersect at their orthographic projections on the base substrate in the display panel can be transferred through other conductive layers to avoid short circuiting between the first data line Da1 and the second data line Da2.

It should be understood that in other exemplary embodiments, the first data line Da1 may also be connected with the red sub-pixels R in the first sub-pixel column ROW1 and the third sub-pixel column ROW3 in another detour wiring manner; and the second data line Da2 may also be connected with the blue sub-pixels B in the first sub-pixel column ROW1 and the third sub-pixel column ROW3 in another detour wiring manner. As long as the first data line Da1 can be connected with the red sub-pixels R in the first sub-pixel column ROW1 and the third sub-pixel column ROW3, and the second data line Da2 can be connected with the blue sub-pixels R in the first sub-pixel column ROW1 and the third sub-pixel column ROW3, the above technical effects can be achieved.

In addition, in other exemplary embodiments, the pixel arrangement structure in the display panel can also be in other ways. As long as the same column of sub-pixels includes sub-pixels of different colors, the power consumption of the source driving circuit can be reduced and the color shift can be improved through connecting the same data line with the sub-pixel columns of the same color.

It should be noted that in the exemplary embodiments, the above technical problem can be solved as long as the pixel driving circuits connected to the same data line drive the light-emitting units of the same color. Therefore, in other exemplary embodiments, the data line can still connect the pixel driving circuits located in the same column, while the pixel driving circuits connected to the same data line can be configured to drive the light-emitting units of the same color by changing the light-emitting units connected to the pixel driving circuits.

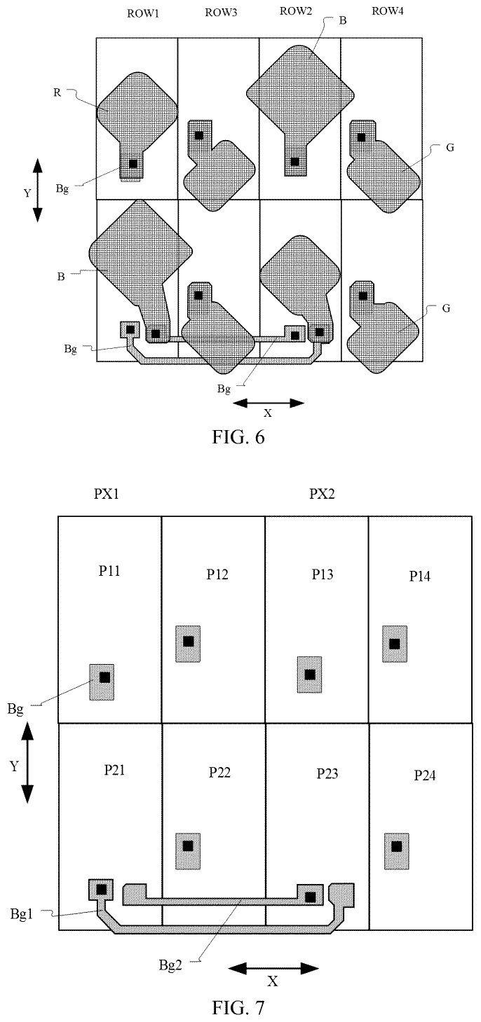

As shown in FIGS. 6-7, FIG. 6 is a schematic structural diagram of the display panel according to another exemplary embodiment of this disclosure, and FIG. 7 is a distribution diagram of the pixel driving circuit in FIG. 6. The display panel may include a base substrate, a plurality of pixel driving circuits P11, P12, P13, . . . , P24, etc. located on the base substrate, and a plurality of electrode parts connected to the pixel driving circuits. As shown in FIGS. 6-7, the plurality of electrode parts include a first electrode part R, a second electrode part B, and a third electrode part G. The first electrode part R can be configured to form the first electrode of the red light-emitting unit; the second electrode part B can be configured to form the first electrode of the blue light-emitting unit; and the third electrode part G can be configured to form the first electrode of the green light-emitting unit. A plurality of pixel driving circuits are arranged in an array along the first direction X and the second direction Y, and the same column of pixel driving circuits can be connected to the same data line. In the first direction X, the first electrode part R, the third electrode part G, the second electrode part B, and the third electrode part G are distributed in sequence. The plurality of electrode parts may form a plurality of electrode columns, with each electrode column includes a plurality of electrode parts, and the orthographic projections of the plurality of electrode parts in the same electrode column on the base substrate are spaced apart along the second direction Y. The plurality of electrode columns may include a first electrode column ROW1, a second electrode column ROW2, a third electrode column ROW3, and a fourth electrode column ROW4. Orthographic projections of the first electrode column ROW1, the third electrode column ROW3, the second electrode column ROW2, and the fourth electrode column ROW4 on the base substrate may be alternately distributed in the first direction X. Herein, the first electrode column ROW1 includes first electrode parts R and second electrode parts B distributed alternately in the second direction Y; the third electrode column ROW3 includes a plurality of third electrode parts G distributed in the second direction Y; the second electrode column ROW2 includes second electrode parts B and first electrode parts R distributed alternately in the second direction Y; and the fourth electrode column ROW4 includes a plurality of third electrode parts G distributed in the second direction Y.

The orthographic projections of a plurality of the pixel driving circuits on the base substrate are distributed in an array along the first direction X and the second direction Y, and the pixel driving circuits distributed in the second direction Y are configured to form pixel circuit columns, including a first pixel circuit column PX1 and a second pixel circuit column PX2. The display panel may further include a plurality of bridging parts Bg, which include a first bridging part Bg1 and a second bridging part Bg2. The first bridging part Bg1 is connected between the pixel driving circuit in the first pixel circuit column PX1 and the first electrode part R in the second electrode column ROW2; and the second bridging part Bg2 is connected between the pixel driving circuit in the second pixel circuit column PX2 and the second electrode part in the first electrode column ROW1.

As shown in FIGS. 6-7, the pixel driving circuit P21 can be connected to the first electrode part R in the second electrode column ROW2 through the first bridging part Bg1, and the pixel driving circuit P23 can be connected to the second electrode part B in the first electrode column ROW1 through the second bridging part Bg2. Therefore, the same data line can be configured to drive the light-emitting units of the same color in the display panel.

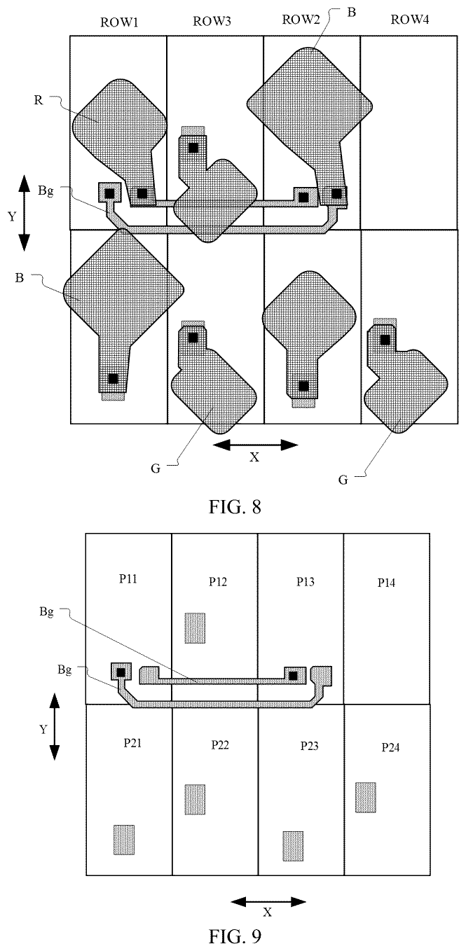

As shown in FIGS. 8-9, FIG. 8 is a schematic structural diagram of the display panel according to another exemplary embodiment of this disclosure, and FIG. 9 is a distribution diagram of the pixel driving circuit in FIG. 8. The pixel driving circuit P13 may be connected to the first electrode part R in the first electrode column ROW1 through the bridging part Bg, and the pixel driving circuit P11 may also be connected to the second electrode part B in the second electrode column ROW2 through the bridging part Bg. This setting can also enable the pixel driving circuits connected to the same data line to connect to light-emitting units of the same color.

In some exemplary embodiments, the electrode parts may be located on the electrode layer, and the bridging part Bg may be located on any conductive layer between the electrode layer and the base substrate. In addition, the bridging part Bg may also be located on the electrode layer. The bridging part Bg can be configured to connect pixel driving circuits and electrode parts located in the same row.

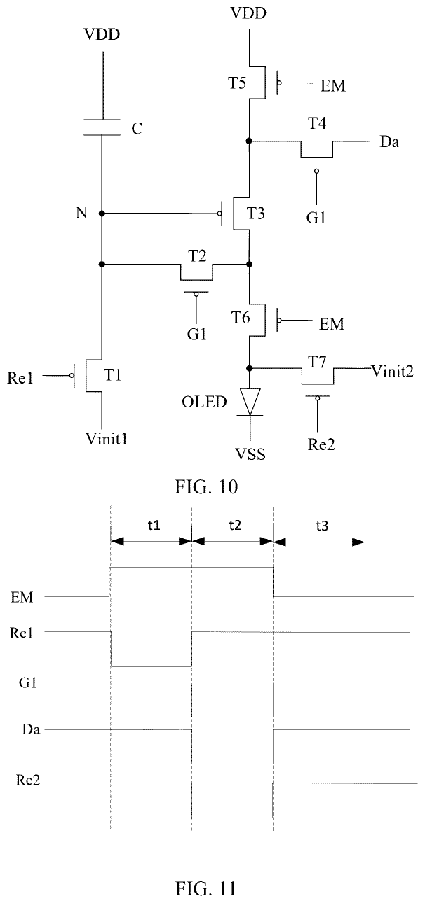

As shown in FIG. 10, it is a schematic circuit structure diagram of a pixel driving circuit in the display panel according to an exemplary embodiment of this disclosure. The pixel driving circuit may include: a first transistor T1, a second transistor T2, a driving transistor T3, a fourth transistor T4, a fifth transistor T5, a sixth transistor T6, a seventh transistor T7, and a capacitor C. Herein, the first electrode of the first transistor T1 is connected to the first initial signal terminal Vinit1, the second electrode thereof is connected to a node N, and the gate thereof is connected to the first reset signal terminal Re1. The first electrode of the second transistor T2 is connected to the gate of the driving transistor T3, the second electrode thereof is connected to the second electrode of the driving transistor T3, and the gate thereof is connected to the first gate driving signal terminal G1. The gate of the driving transistor T3 is connected to the node N. The first electrode of the fourth transistor T4 is connected to the data signal terminal Da, the second electrode thereof is connected to the first electrode of the third transistor T3, and the gate thereof is connected to the first gate driving signal terminal G1. The first electrode of the fifth transistor T5 is connected to the first power terminal VDD, the second electrode thereof is connected to the first electrode of the driving transistor T3, and the gate thereof is connected to the enable signal terminal EM. The first electrode of the sixth transistor T6 is connected to the second electrode of the driving transistor T3, and the gate thereof is connected to the enable signal terminal EM. The first electrode of the seventh transistor T7 is connected to the second initial signal terminal Vinit2, the second electrode thereof is connected to the second electrode of the sixth transistor T6, and the gate thereof is connected to the second reset signal terminal Re2. The first electrode of the capacitor C is connected to the gate of the driving transistor T3, and the second electrode of the capacitor C is connected to the first power terminal VDD. The pixel driving circuit can be connected to a light-emitting unit OLED. The pixel driving circuit is configured to drive the light-emitting unit OLED to emit light. The first electrode of the light-emitting unit OLED can be connected to the second electrode of the sixth transistor T6, and the second electrode thereof can be connected the second power terminal VSS. The first transistor T1, the second transistor T2, the driving transistor T3, the fourth transistor T4, the fifth transistor T5, the sixth transistor T6, and the seventh transistor T7 may all be P-type transistors.

As shown in FIG. 11, it is a timing diagram of each node signal in a driving method of the pixel driving circuit shown in FIG. 10. Herein, G1 represents the signal timing of the first gate driving signal terminal G1, Re1 represents the signal timing of the first reset signal terminal Re1, Re2 represents the signal timing of the second reset signal terminal Re2, EM represents the signal timing of the enable signal terminal EM, and Da represents the signal timing of the data signal terminal Da. The driving method of the pixel driving circuit may include a reset phase t1, a data writing phase t2, and a light emitting phase t3. In the reset phase t1, the first reset signal terminal Re1 outputs a low-level signal, the first transistor T1 is turned on, and the first initial signal terminal Vinit1 inputs the first initial signal to the node N. In the data writing phase t2, the second reset signal terminal Re2 and the first gate driving signal terminal G1 output low-level signals, the fourth transistor T4, the second transistor T2, and the seventh transistor T7 are turned on; at the same time, the data signal terminal Da outputs the data signal to write the voltage Vdata+Vth to the node N, where Vdata is the voltage of the data signal, and Vth is the threshold voltage of the driving transistor T3; the second initial signal terminal Vinit2 inputs the second initial signal to the second electrode of the sixth transistor T6. In the light emitting phase t3, the enable signal terminal EM outputs a low-level signal, the sixth transistor T6 and the fifth transistor T5 are turned on, and the driving transistor T3, under the action of the voltage Vdata+Vth of the node N, drives the light-emitting unit to emit light. In the pixel driving circuit of this disclosure, the output current of the driving transistor is I=(μWCox/2L) (Vdata+Vth−Vdd−Vth) 2, where μ is the carrier mobility, Cox is the gate capacitance per unit area, W is the channel width of the driving transistor, L is the channel length of the driving transistor, Vgs is the gate-source voltage difference of the driving transistor, and Vth is the threshold voltage of the driving transistor. The influence caused by the threshold of the driving transistor on the output current can be avoided in the pixel driving circuit.

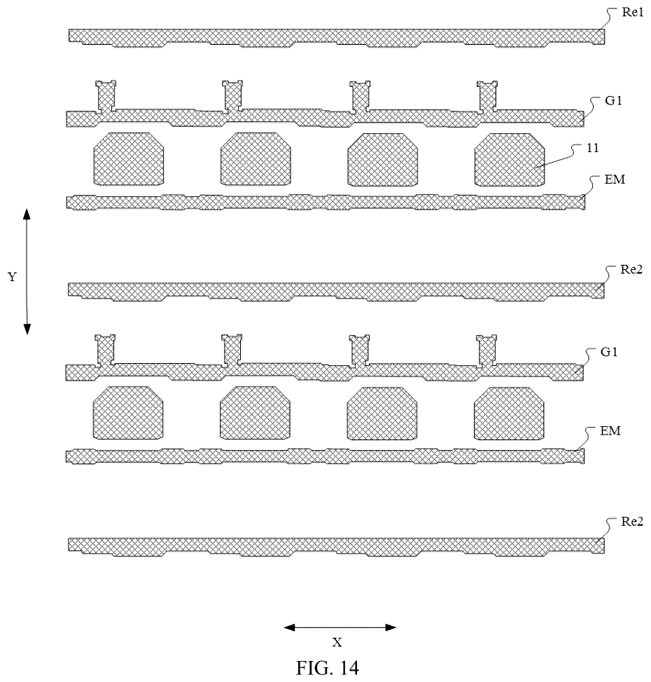

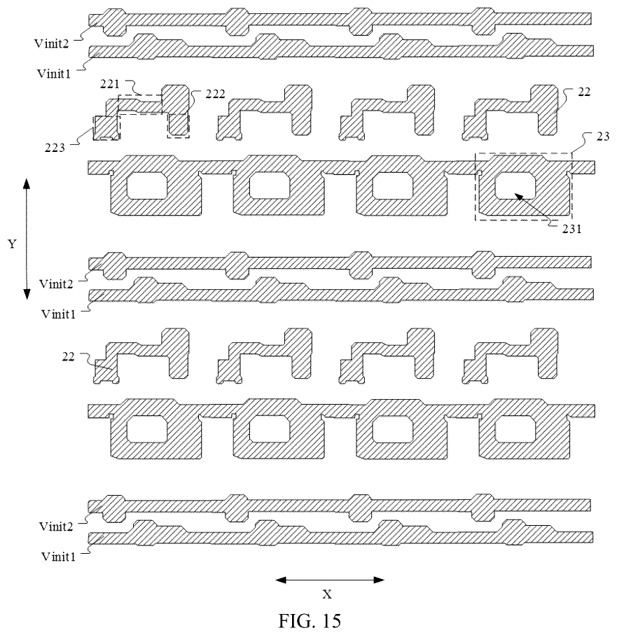

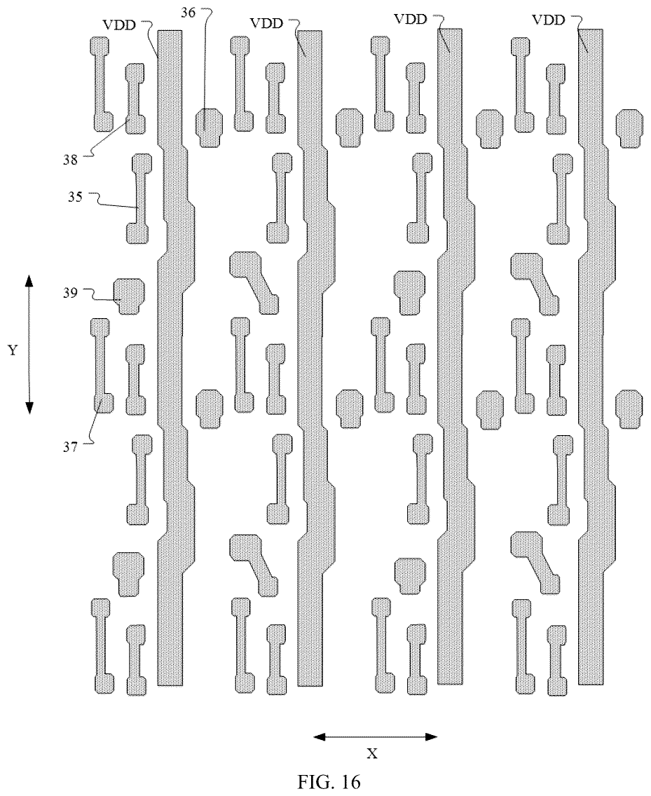

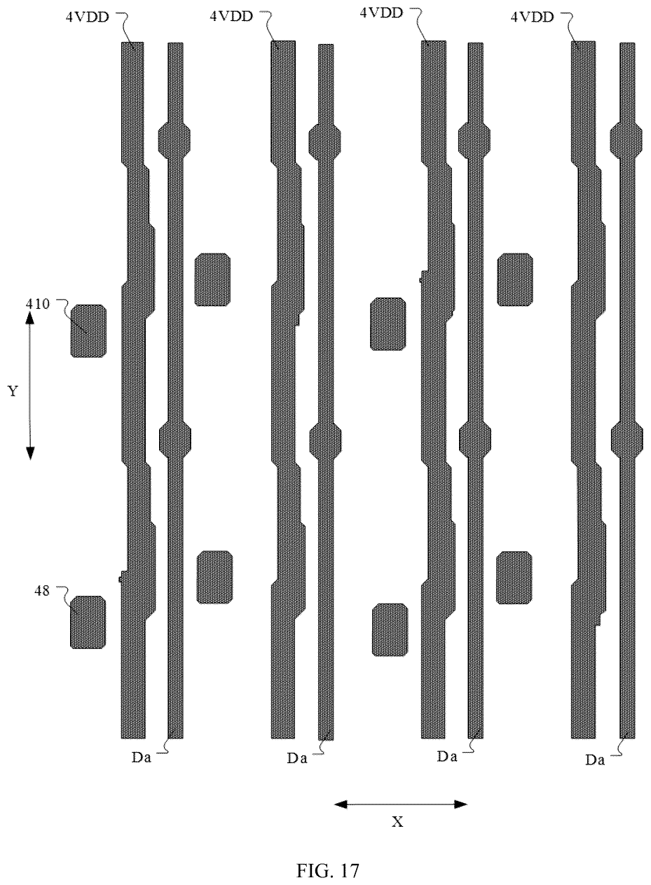

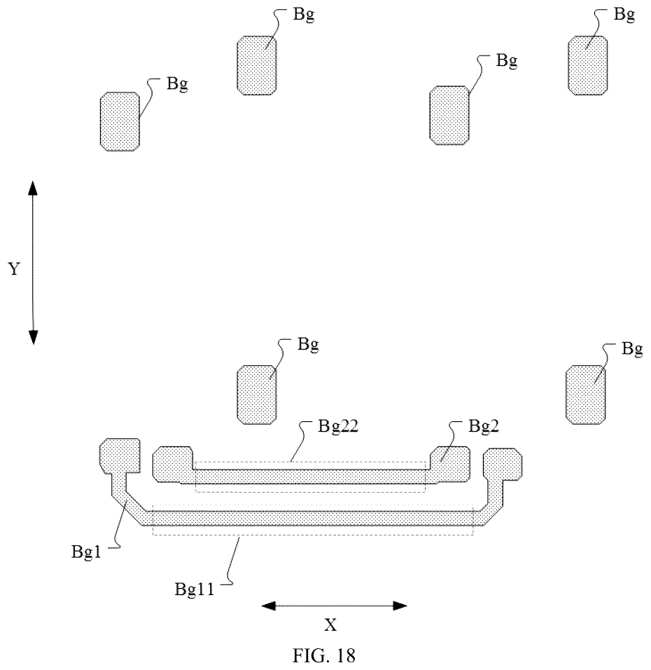

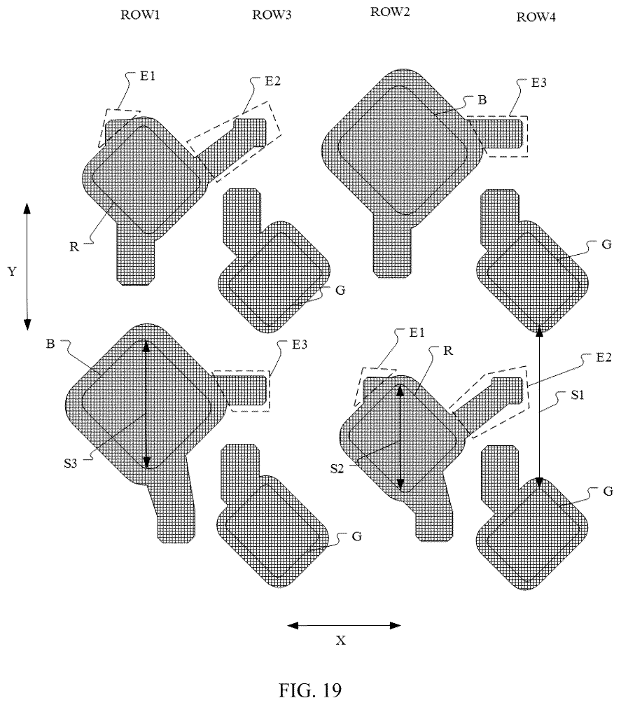

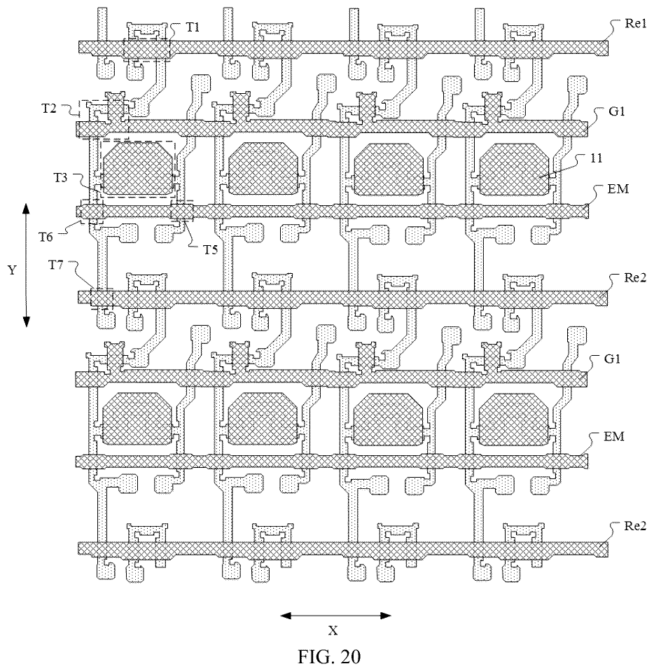

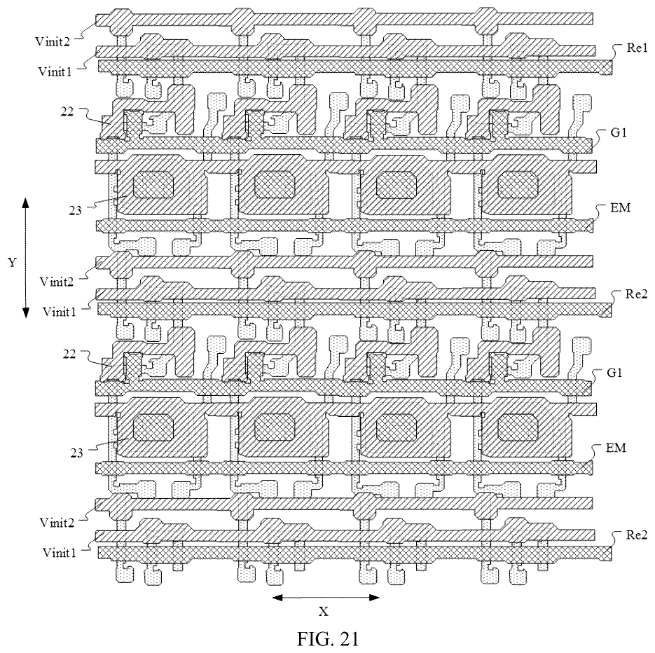

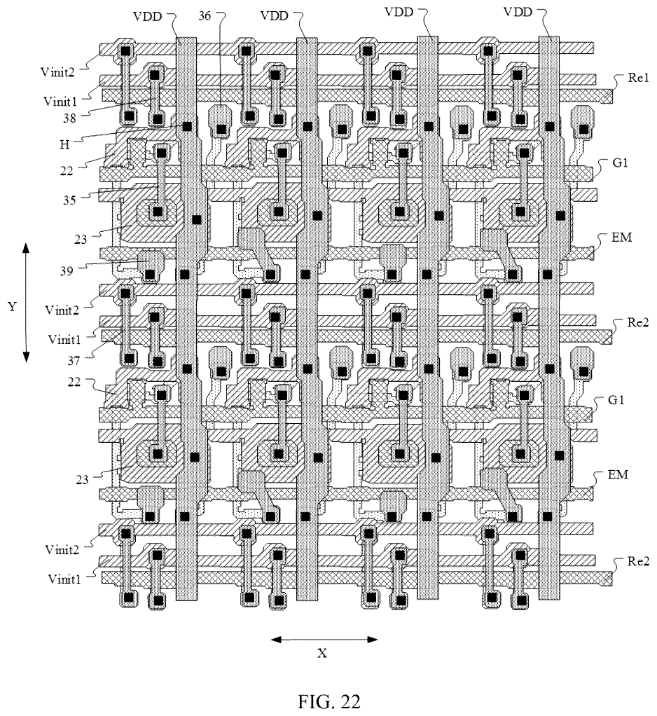

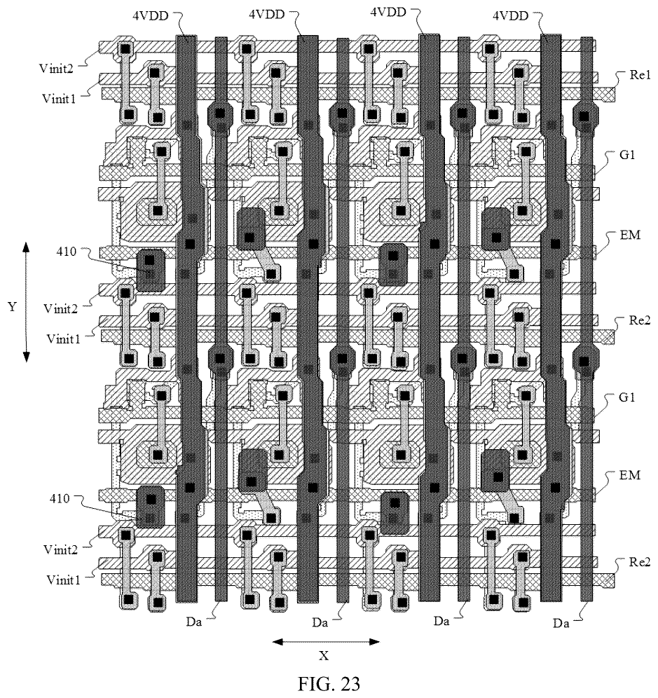

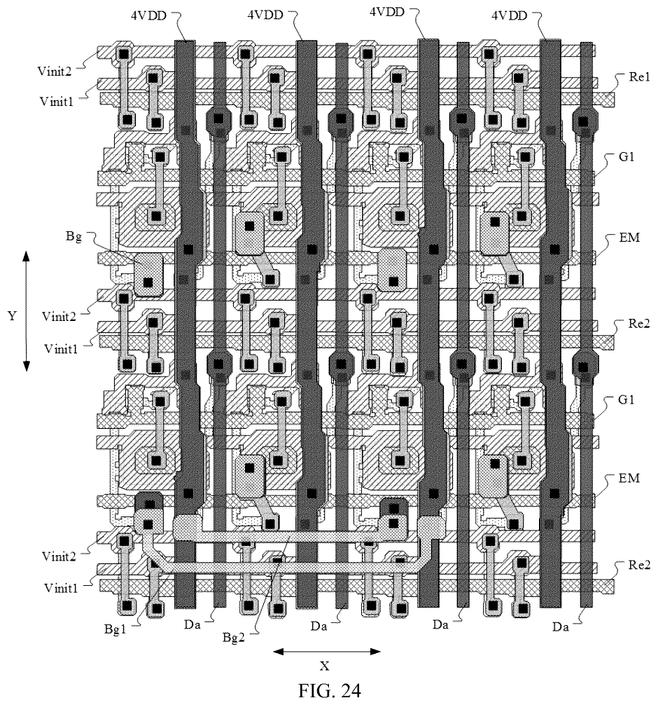

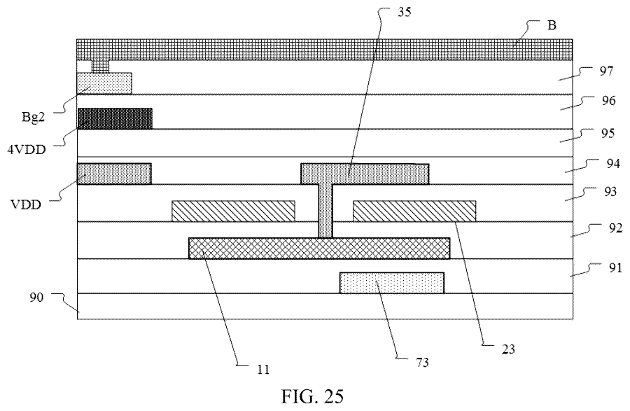

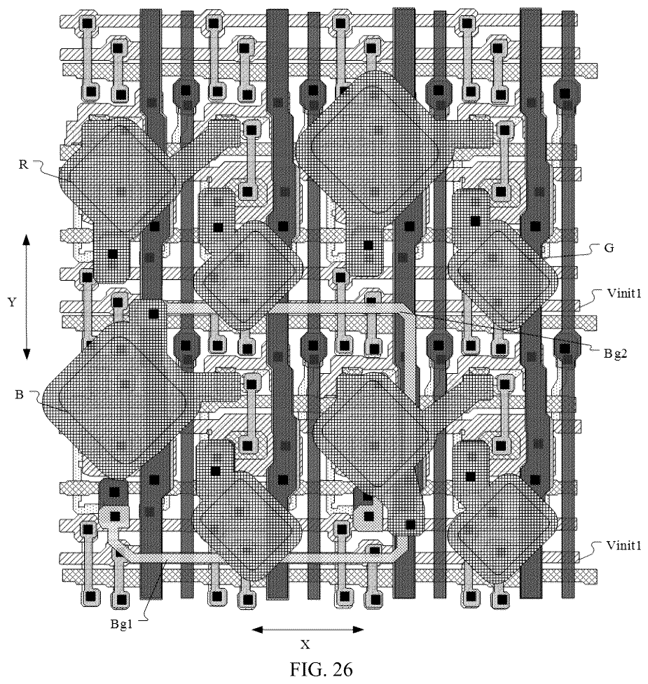

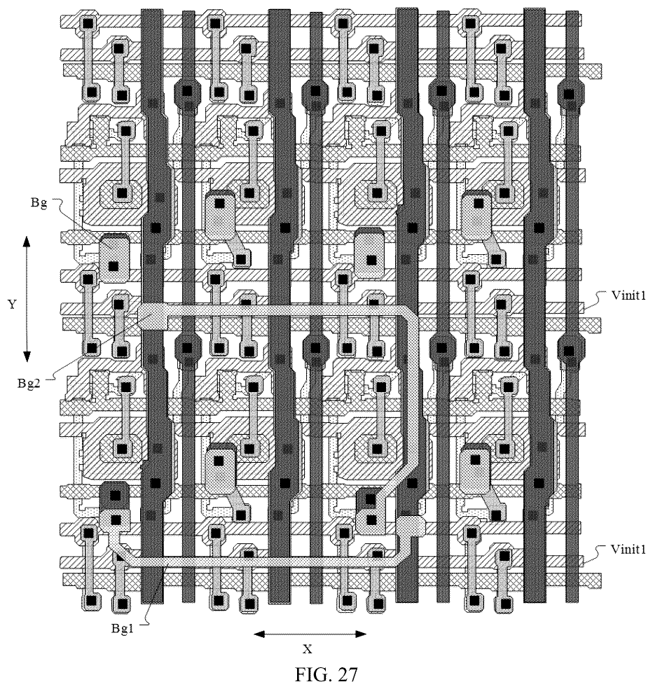

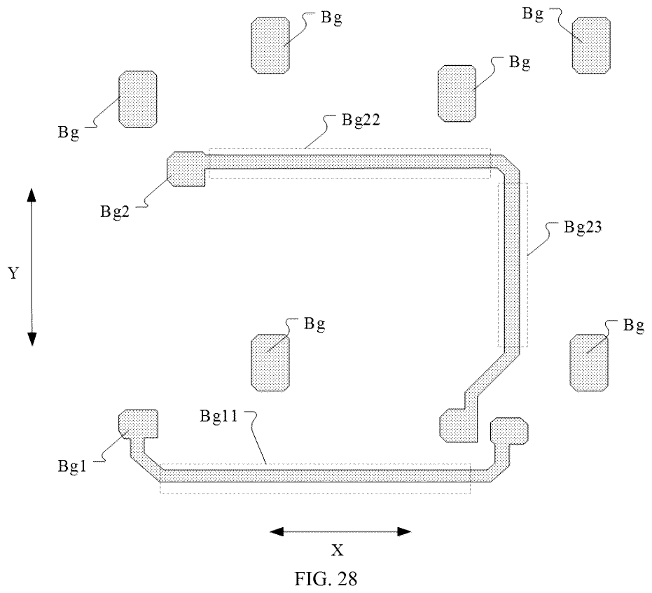

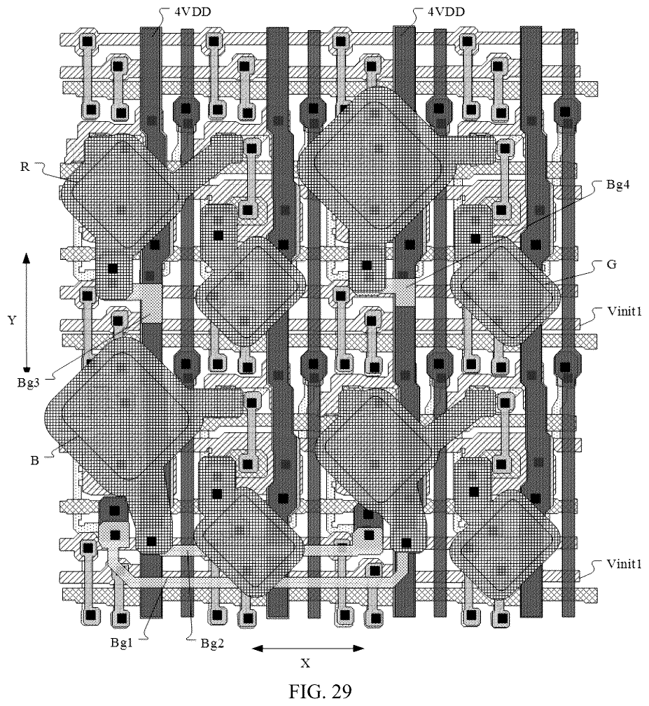

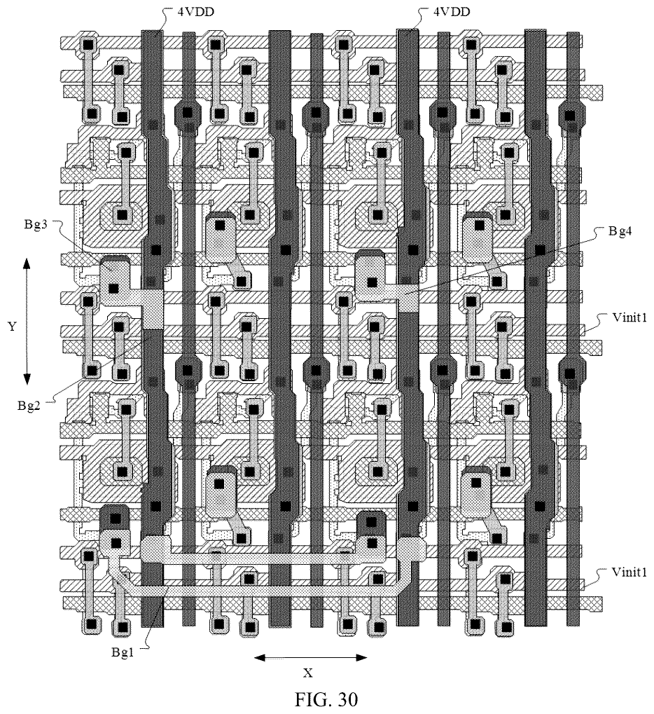

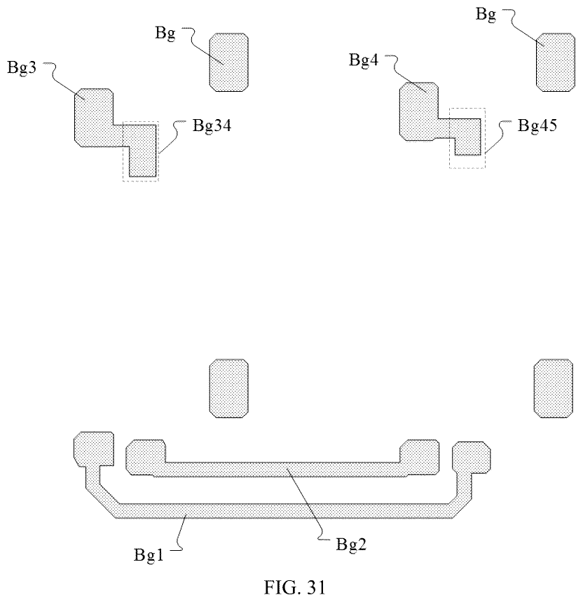

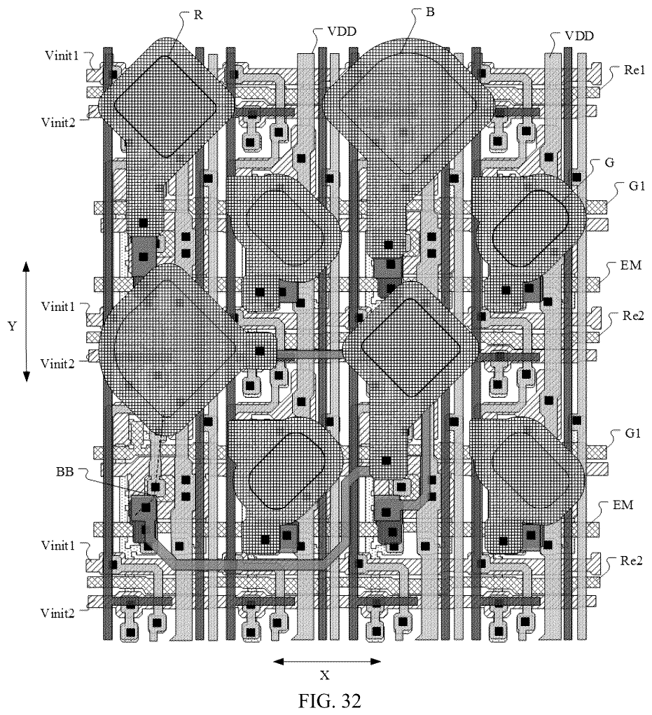

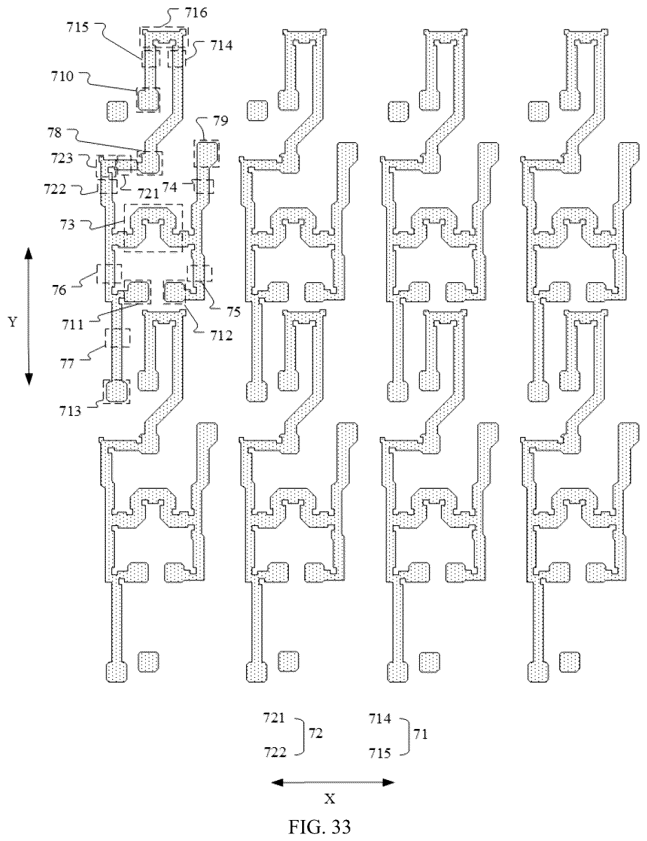

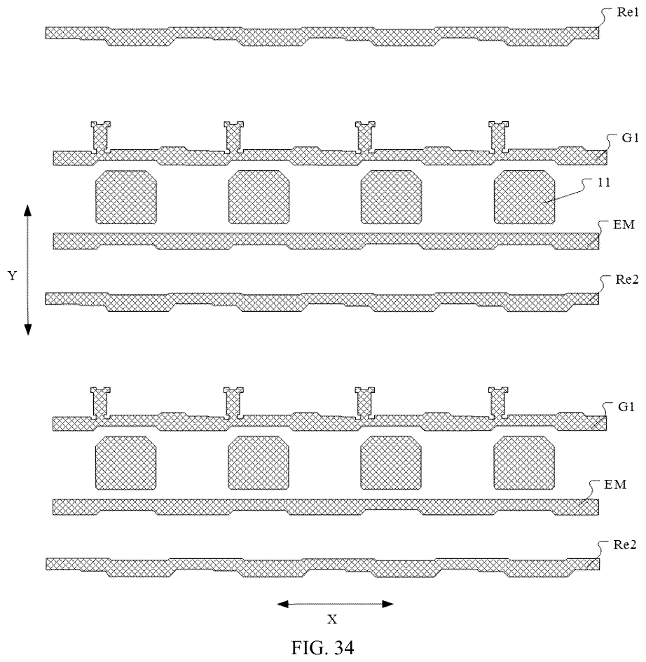

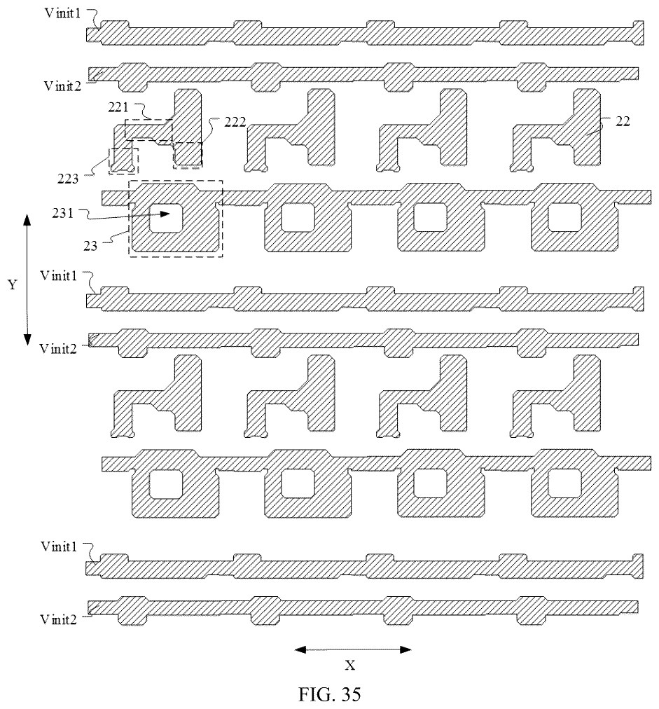

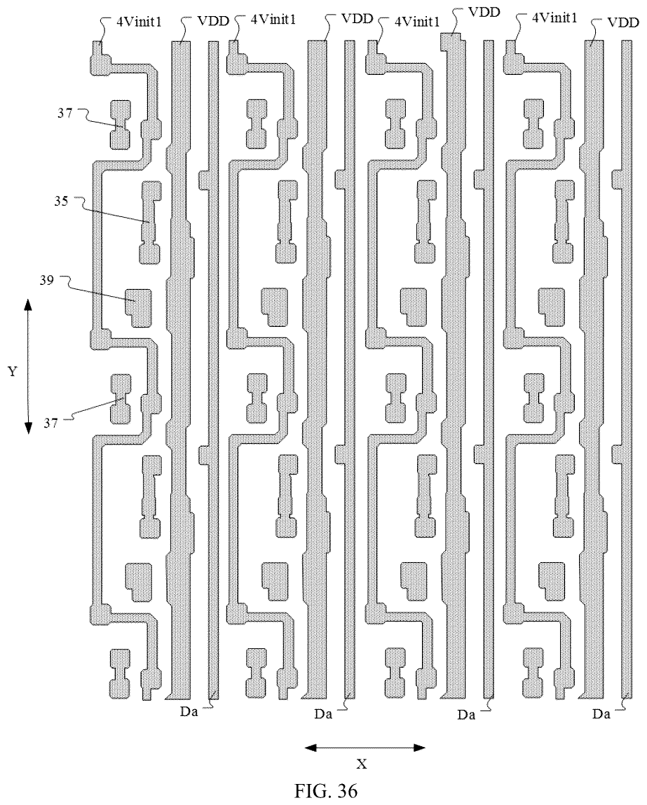

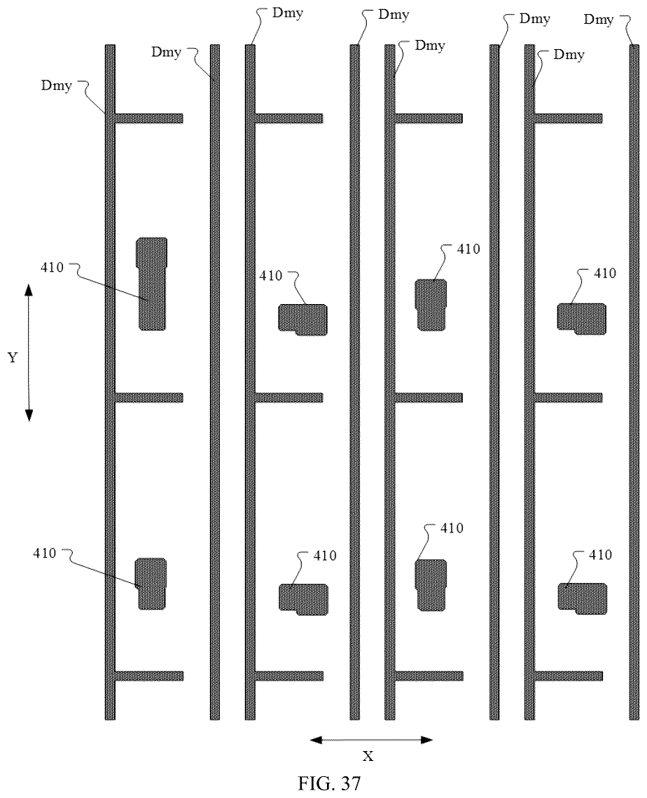

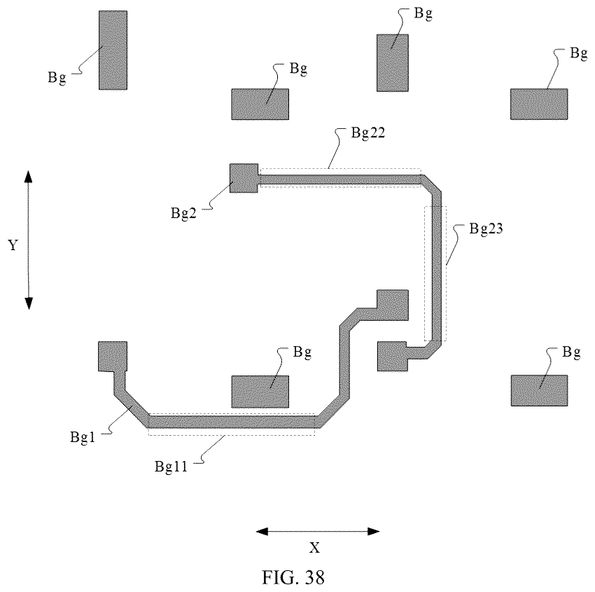

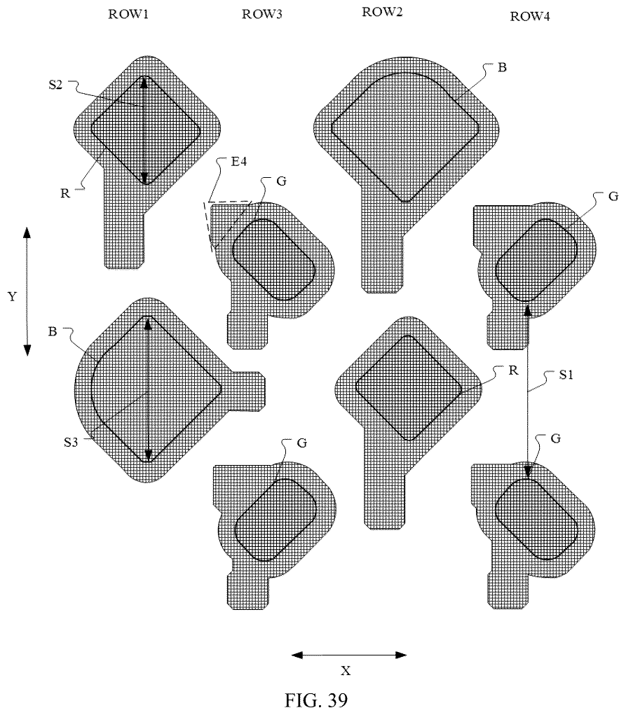

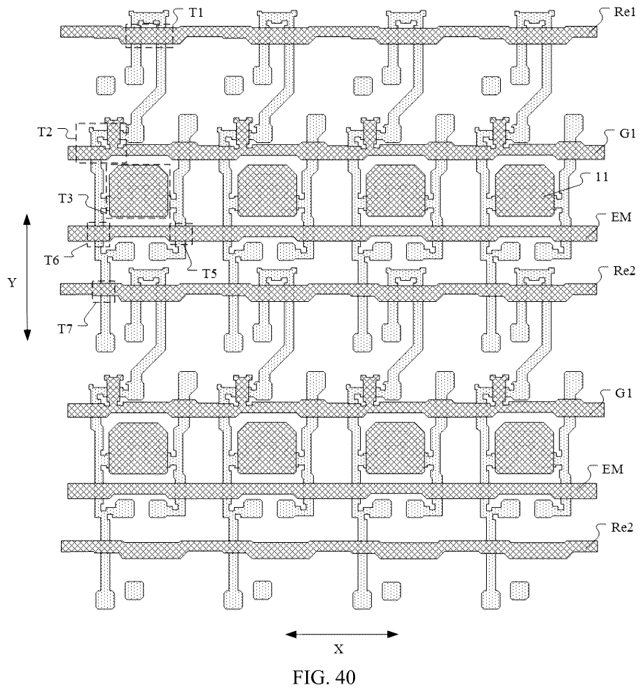

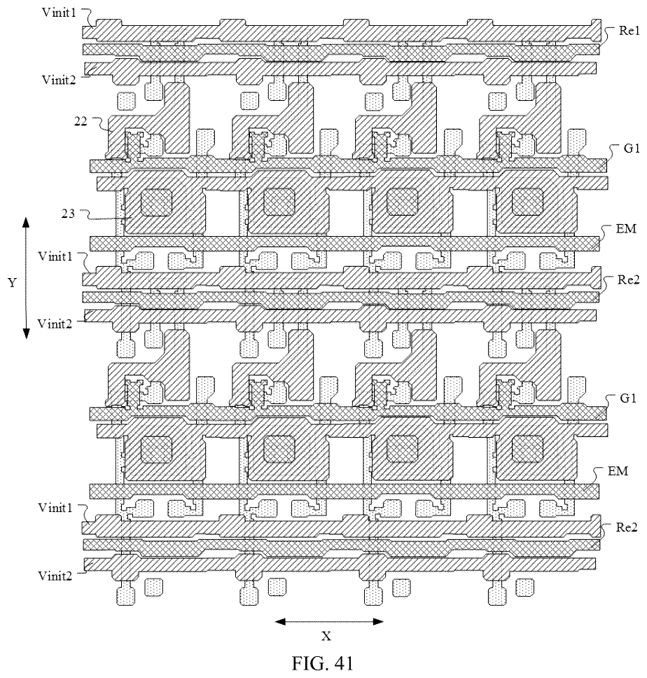

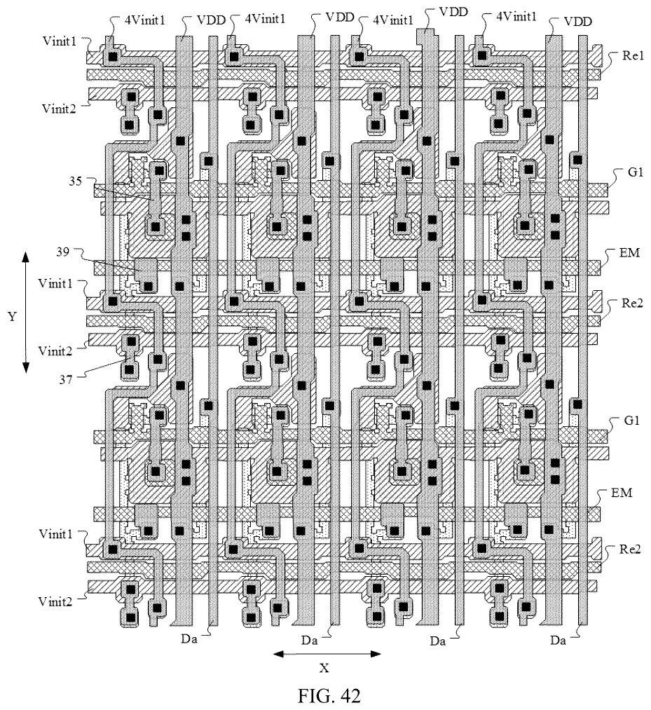

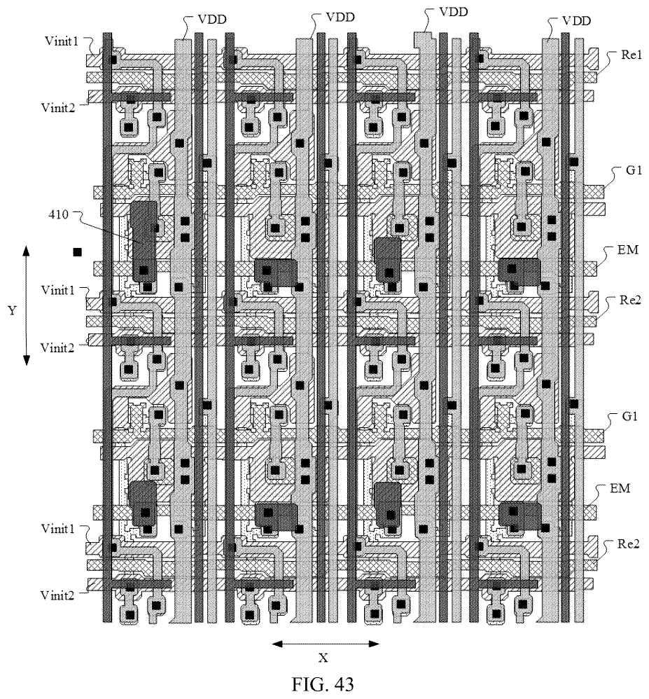

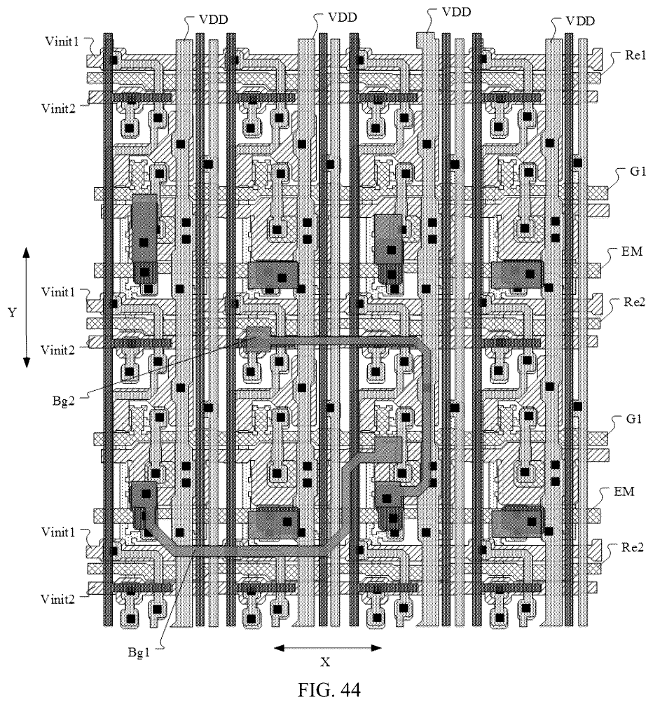

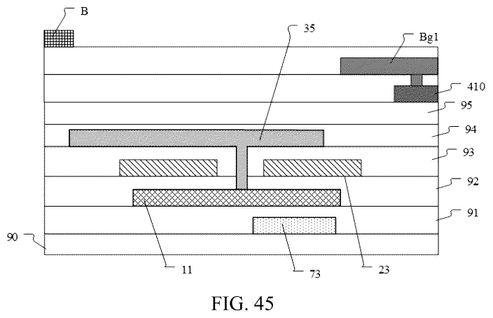

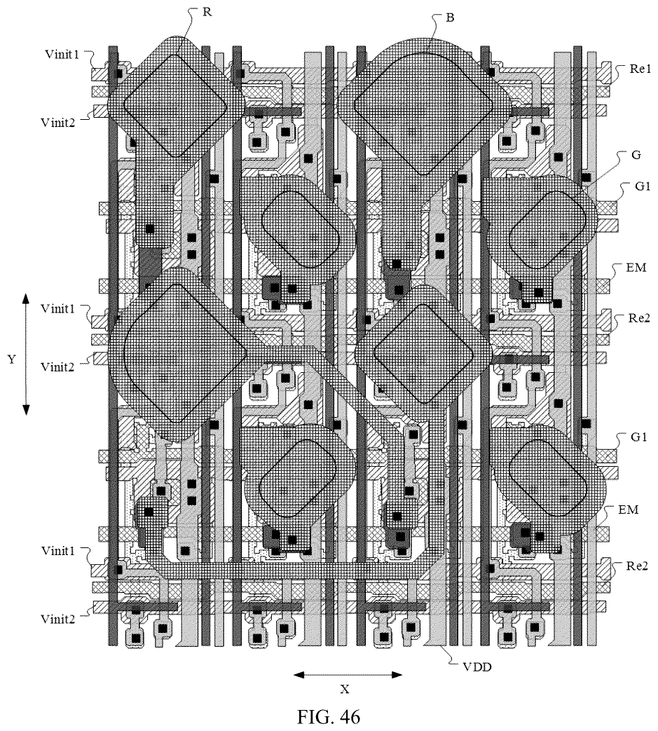

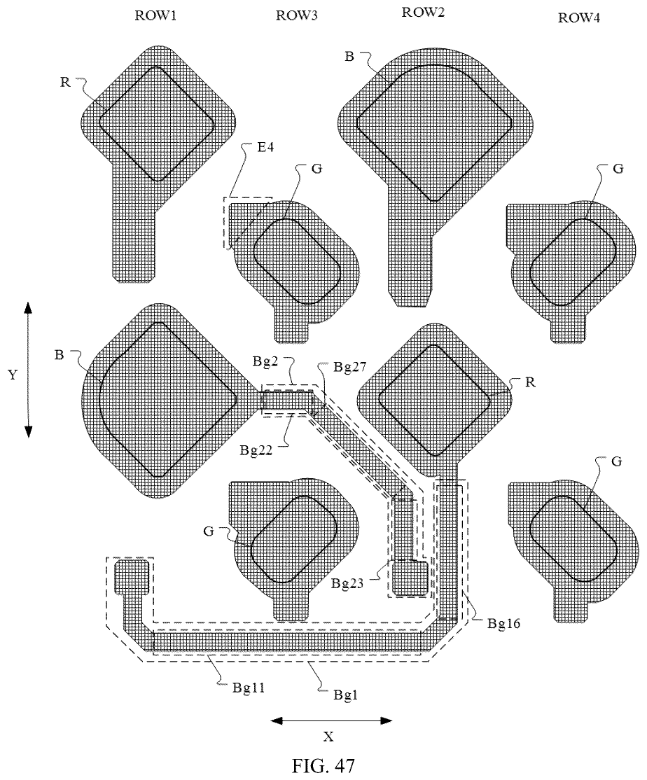

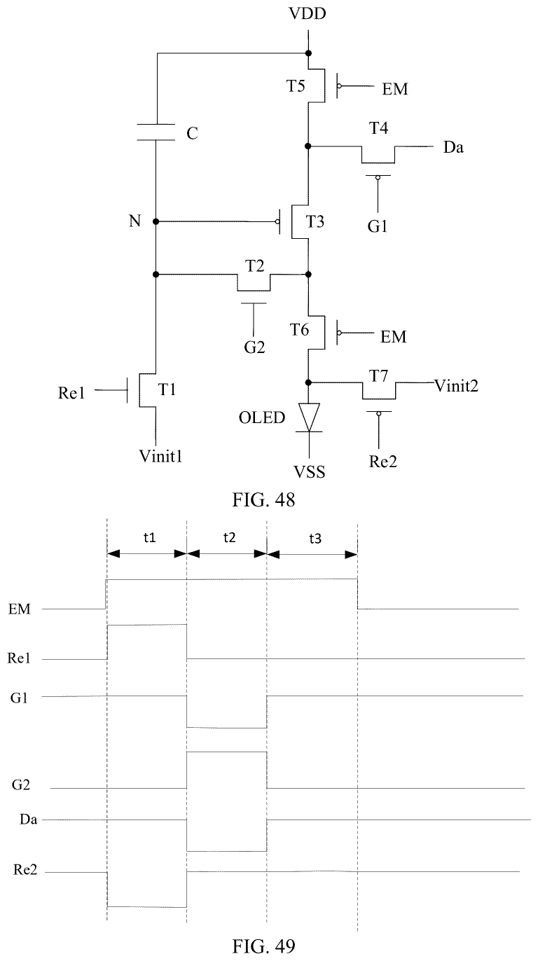

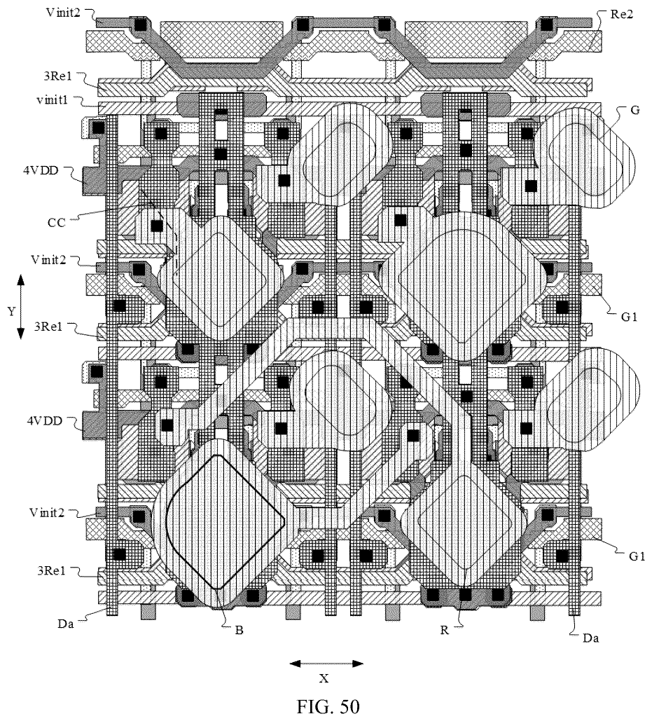

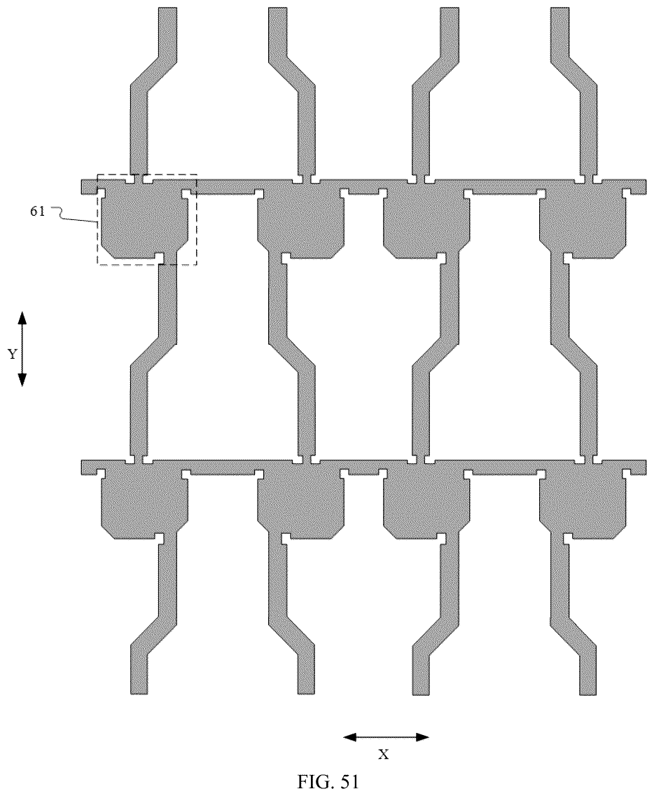

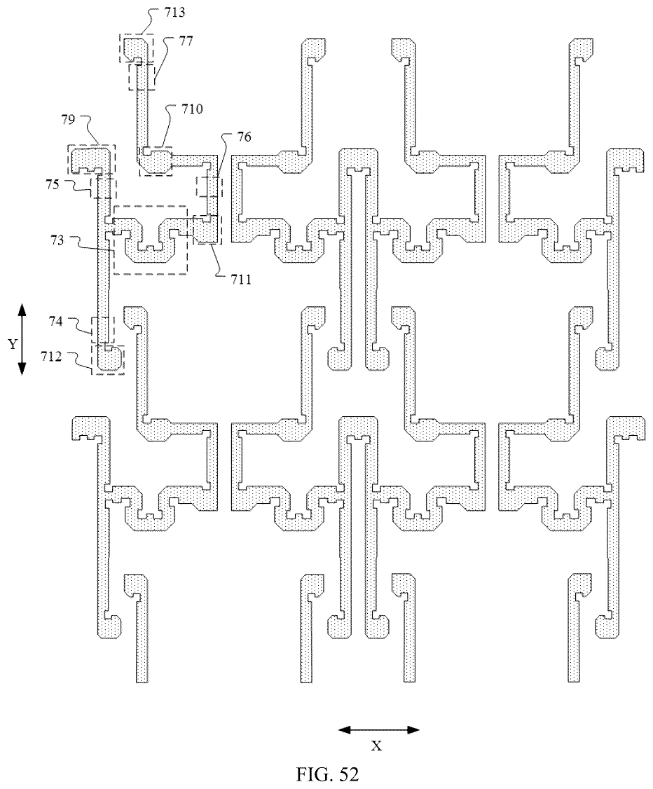

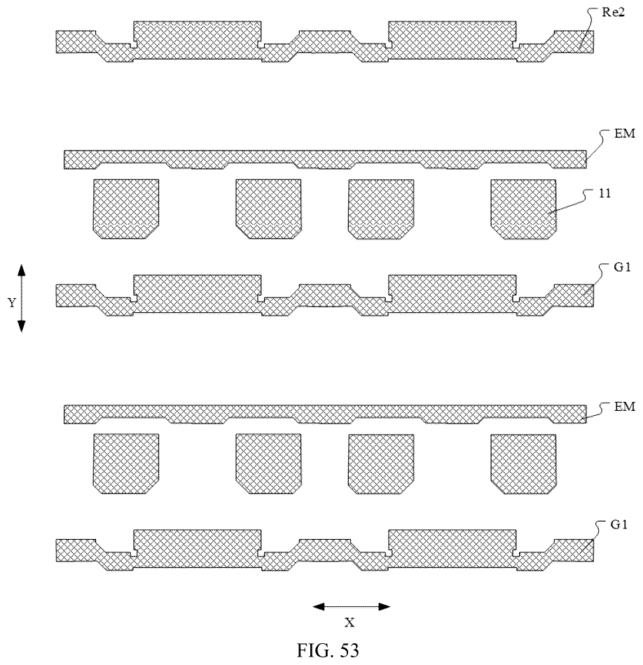

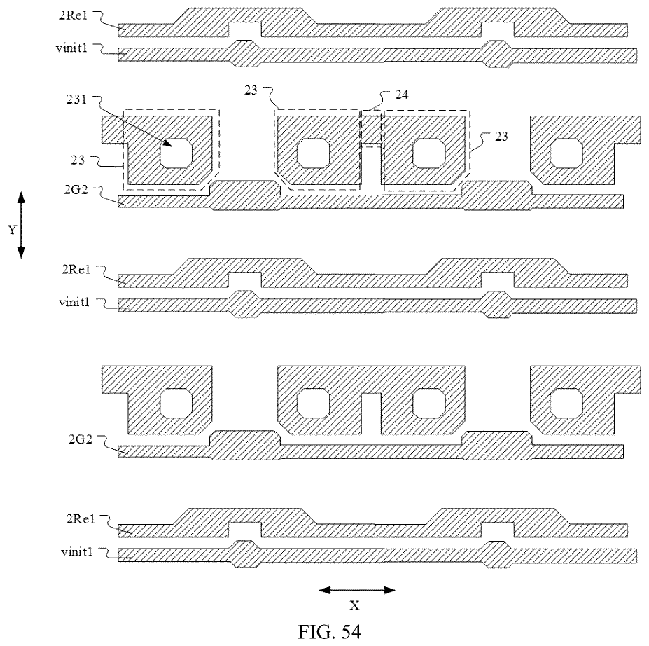

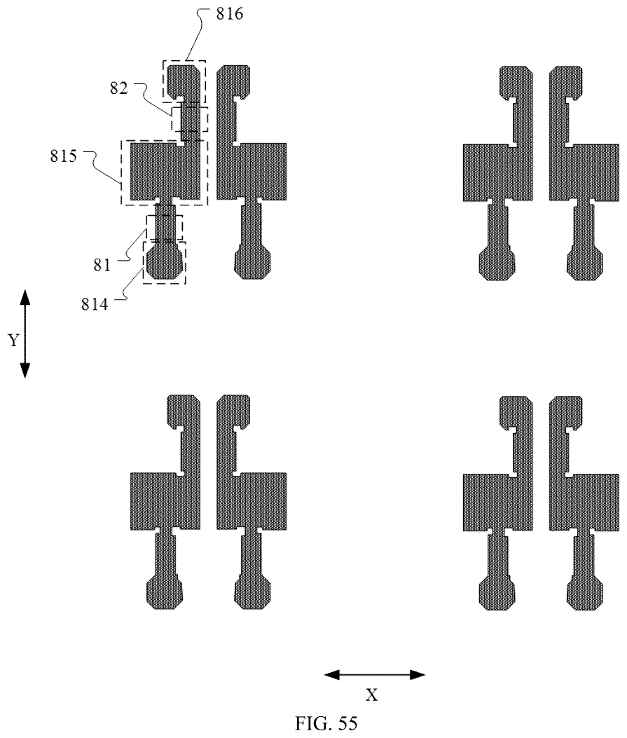

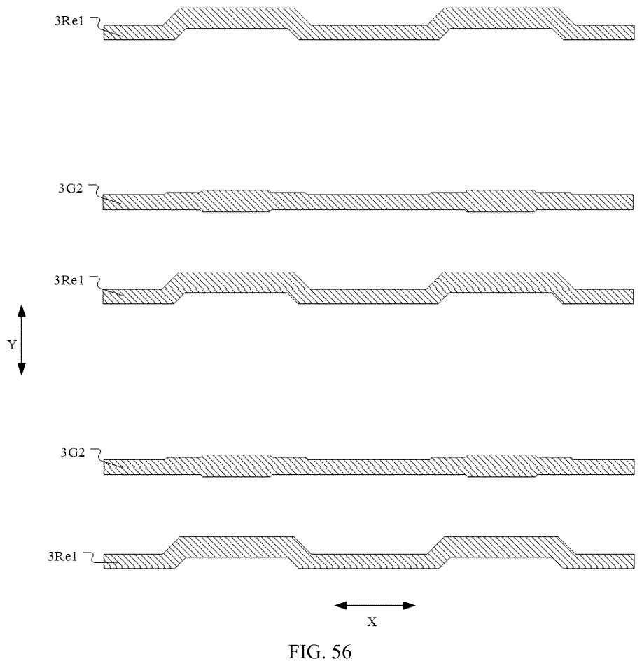

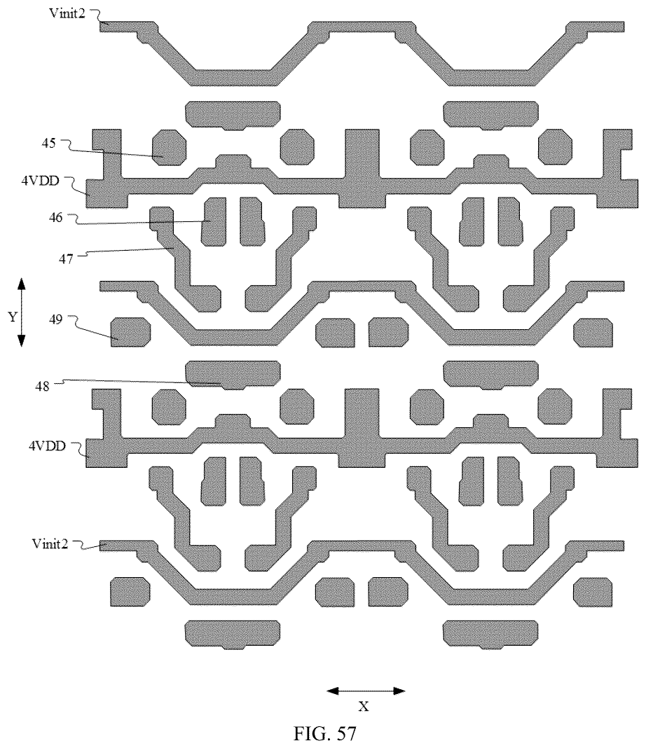

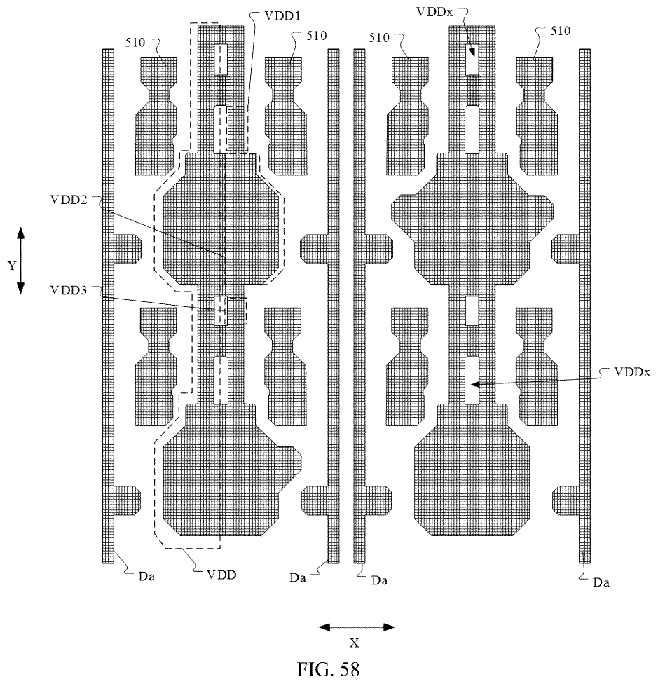

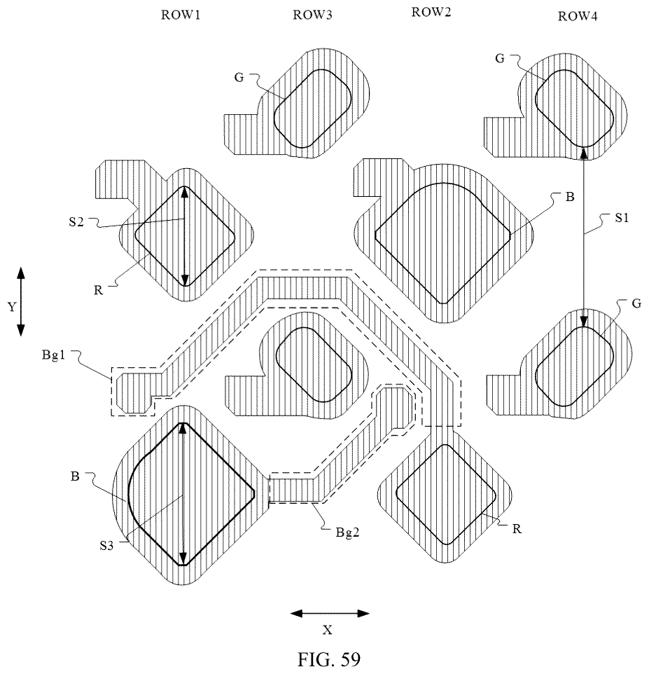

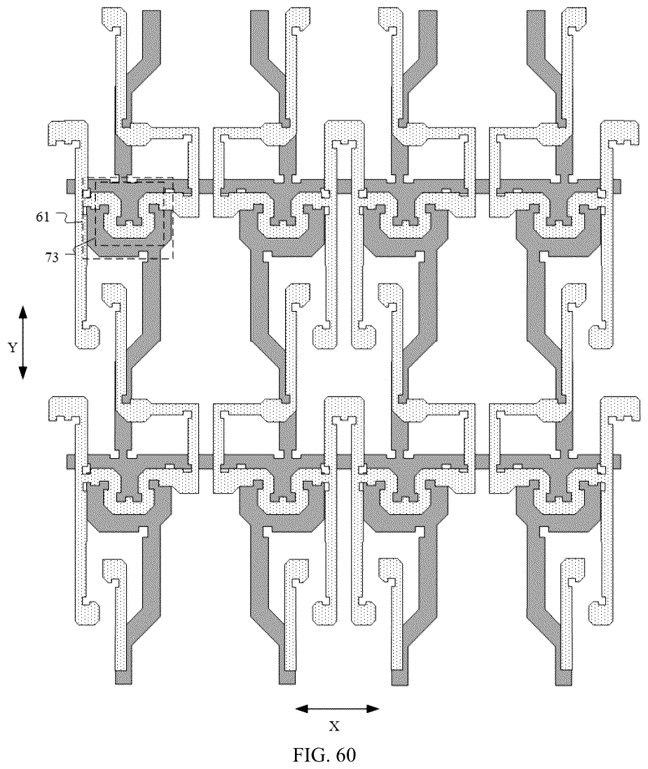

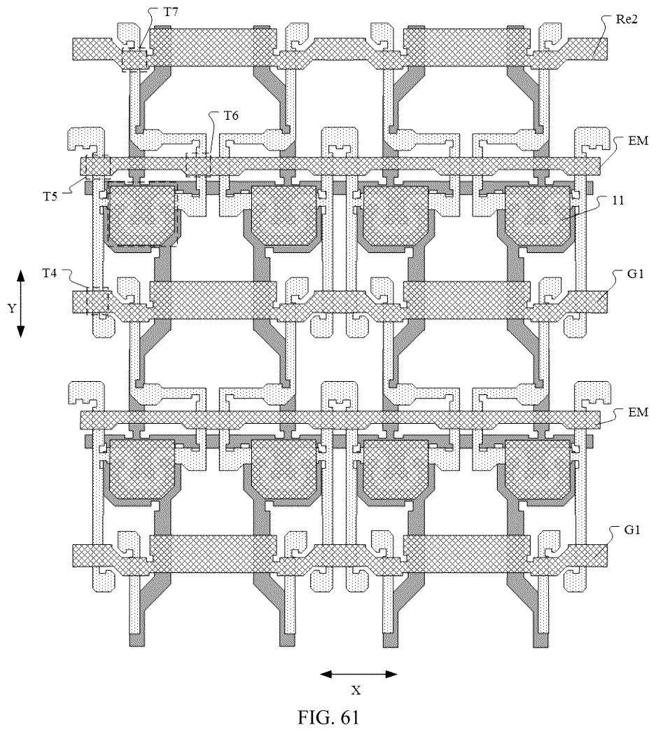

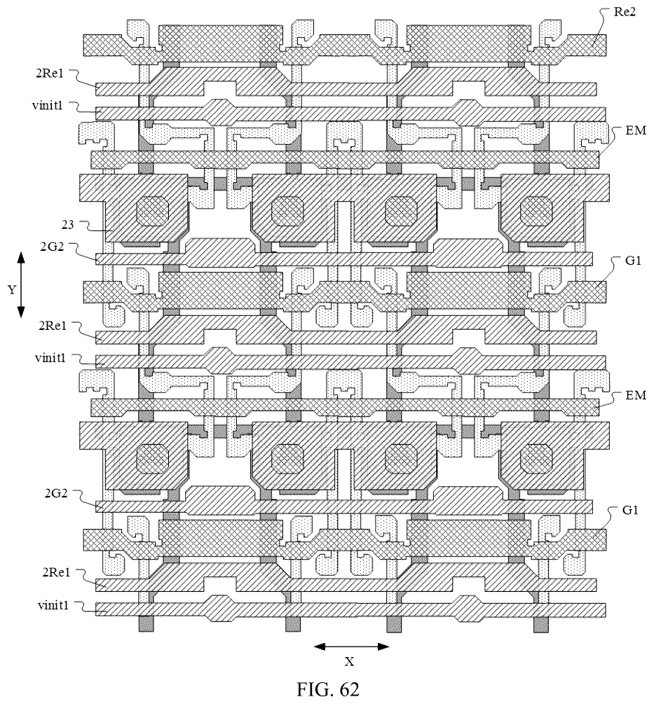

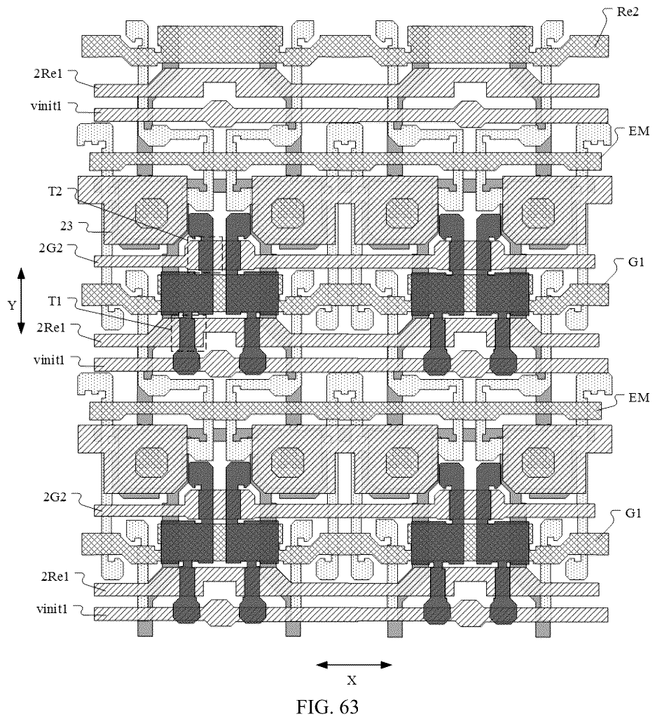

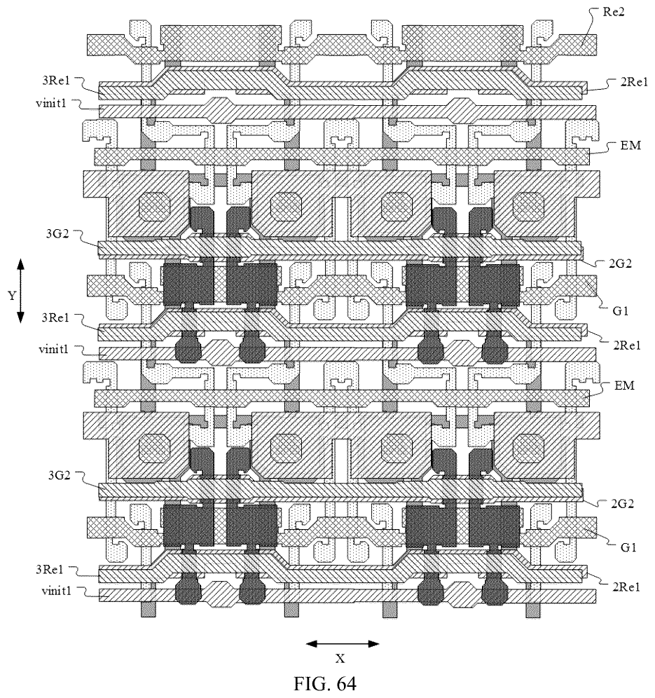

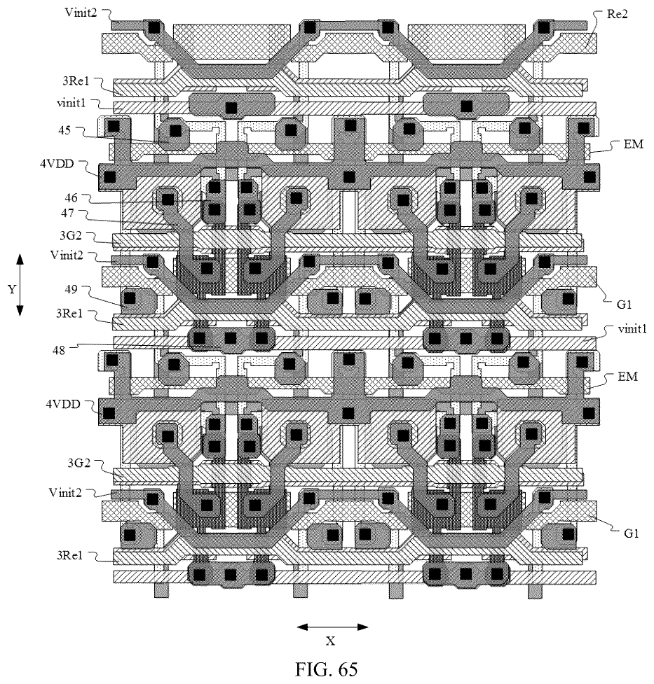

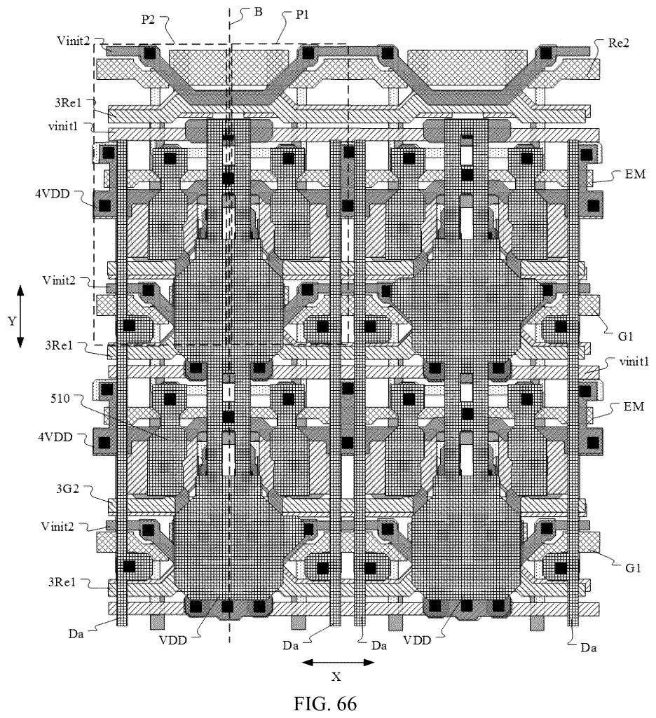

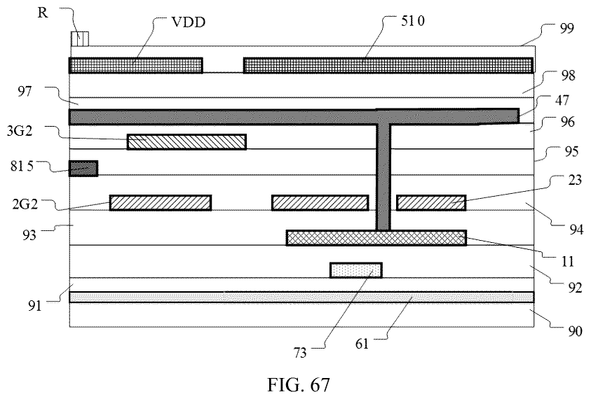

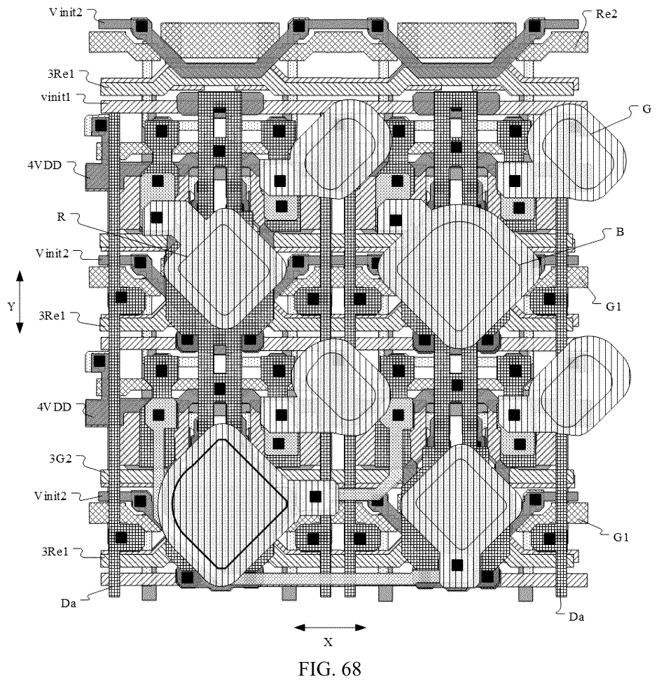

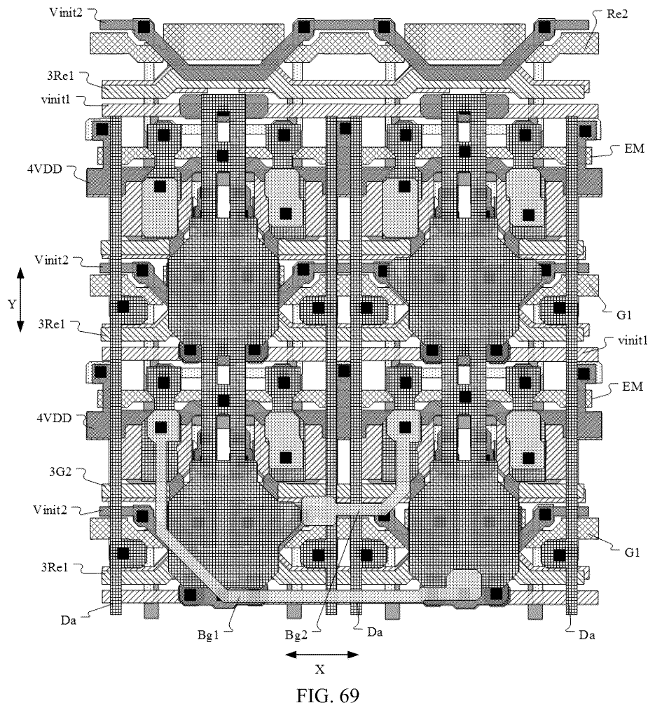

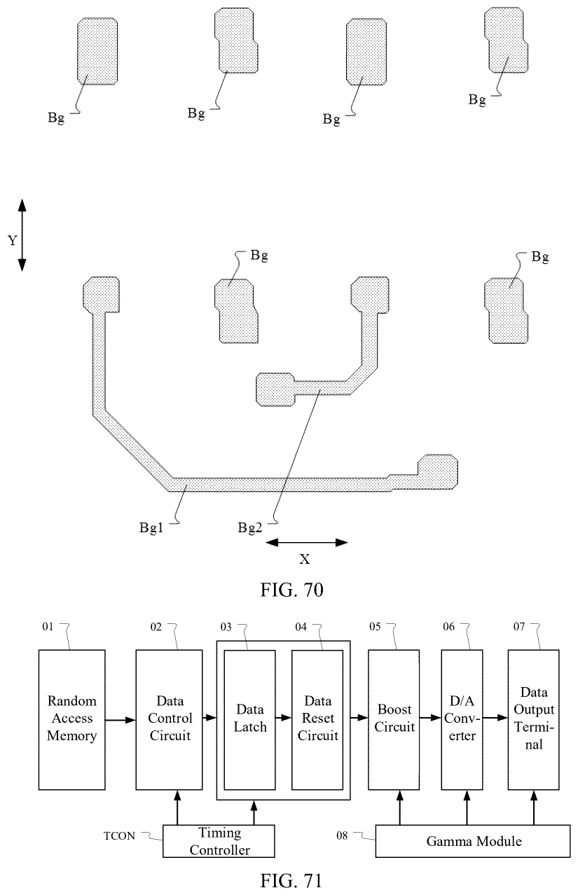

Some exemplary embodiments further provide another display panel, which may include a base substrate, a first active layer, a first gate layer, a second gate layer, a first source-drain layer, a second source-drain layer, a bridging layer and an electrode layer that are stacked in sequence, and an insulating layer(s) is provided between the above structural layers. As shown in FIGS. 12-24, FIG. 12 is a structural layout of a display panel according to an exemplary embodiment of this disclosure; FIG. 13 is a structural layout of the first active layer in FIG. 12; FIG. 14 is a structural layout of the first gate layer in FIG. 12; FIG. 15 is a structural layout of the second gate layer in FIG. 12; FIG. 16 is a structural layout of the first source-drain layer in FIG. 12; FIG. 17 is a structural layout of the second source-drain layer in FIG. 12; FIG. 18 is a structural layout of the bridging layer in FIG. 12; FIG. 19 is a structural layout of the electrode layer in FIG. 12; FIG. 20 is a structural layout of the first active layer and the first gate layer in FIG. 12; FIG. 21 is a structural layout of the first active layer, the first gate layer, and the second gate layer in FIG. 12; FIG. 22 is a structural layout of the first active layer, the first gate layer, the second gate layer, and the first source-drain layer in FIG. 12; FIG. 23 is a structural layout of the first active layer, the first gate layer, the second gate layer, the first source-drain layer, and the second source-drain layer in FIG. 12; and FIG. 24 is a structural layout of the first active layer, the first gate layer, the second gate layer, the first source-drain layer, the second source-drain layer, and the bridging layer in FIG. 12.

As shown in FIGS. 12, 13, and 20, the first active layer may include a first active part 71, a second active part 72, a third active part 73, a fourth active part 74, a fifth active part 75, a sixth active part 76 and a seventh active part 77. In some embodiments, the first active part 71 is configured to form the channel region of the first transistor T1, the second active part 72 is configured to form the channel region of the second transistor T2, the third active part 73 is configured to form the channel region of the driving transistor T3, the fourth active part 74 is configured to form the channel region of the fourth transistor T4, the fifth active part 75 is configured to form the channel region of the fifth transistor T5, the sixth active part 76 is configured to form the channel region of the sixth transistor T6, and the seventh active part 77 are configured to form the channel region of the seventh transistor T7. The first active part 71 includes a fourth active sub-part 714 and a fifth active sub-part 715, and the second active part 72 includes a first active sub-part 721 and a second active sub-part 722. The first active layer may further include a sixth active sub-part 716 connected between the fourth active sub-part 714 and the fifth active sub-part 715, a third active sub-part 723 connected between the first active sub-part 721 and the second active sub-part 722, an eighth active part 78 connected between the second active part 72 and the first active part 71, a ninth active part 79 connected on one side of fourth active part 74 away from the third active part 73, a tenth active part 710 connected on one side of the first active part 71 away from the second active part 72, an eleventh active part 711 connected between the sixth active part 76 and the seventh active part 77, a twelfth active part 712 connected on one side of the fifth active part 75 away from the third active part 73, and a thirteenth active part 713 connected on one side of the seventh active part 77 away from the sixth active part 76. The first active layer may be formed of polysilicon material. Correspondingly, the first transistor T1, the second transistor T2, the driving transistor T3, the fourth transistor T4, the fifth transistor T5, the sixth transistor T6, and the seventh transistor T7 may be P-type low temperature polysilicon thin film transistor.

As shown in FIGS. 12, 14, and 20, the first gate layer may include: a first reset signal line Re1, a second reset signal line Re2, a first gate line G1, an enable signal line EM, and a first conductive part 11. Herein, the first reset signal line Re1 is configured to provide the first reset signal terminal in FIG. 10, the second reset signal line Re2 is configured to provide the second reset signal terminal in FIG. 10, the first gate line G1 is configured to provide the first gate driving signal terminal in FIG. 10, and the enable signal line EM is configured to provide the enable signal terminal in FIG. 10. The orthographic projection of the first reset signal line Re1 on the base substrate may extend along the first direction X and cover the orthographic projection of the first active part 71 on the base substrate, and a partial structure of the first reset signal line Re1 is configured to form the gate of the first transistor T1. The orthographic projection of the second reset signal line Re2 on the base substrate may extend along the first direction X and cover the orthographic projection of the seventh active part 77 on the base substrate, and a partial structure of the second reset signal line Re2 is configured to form the gate of the seventh transistor T7. The orthographic projection of the enable signal line EM on the base substrate may extend along the first direction X, and cover the orthographic projection of the fifth active part 75 on the base substrate and the orthographic projection of the sixth active part 76 on the base substrate. A partial structure of the enable signal line EM is configured to form the gate of the fifth transistor T5, and another partial structure of the enable signal line EM is configured to form the gate of the sixth transistor T6. The orthographic projection of the first gate line G1 on the base substrate extends along the first direction X and covers the orthographic projection of the second active part 72 on the base substrate and the orthographic projection of the fourth active part 74 on the base substrate. A partial structure of the first gate line G1 is configured to form the gate of the second transistor T2, and another partial structure of the first gate line G1 is configured to form the gate of the fourth transistor T4. The orthographic projection of the first conductive part 11 on the base substrate covers the orthographic projection of the third active part 73 on the base substrate, and the first conductive part 11 is configured to form the gate of the driving transistor T3. The first conductive part 11 can also be reused as the first electrode of the capacitor C. Herein, the orthographic projection of the first conductive part 11 on the base substrate may be located between the orthographic projection of the first gate line G1 on the base substrate and the orthographic projection of the enable signal line EM on the base substrate. The orthographic projection of the first reset signal line Re1 on the base substrate may be located on a side of the orthographic projection of the first gate line G1 on the base substrate away from the orthographic projection of the first conductive part 11 on the base substrate. The orthographic projection of the second reset signal line Re2 on the base substrate may be located on a side of the orthographic projection of the enable signal line EM on the base substrate away from the orthographic projection of the first conductive part 11 on the base substrate. In the pixel driving circuits of adjacent rows, the second reset signal line Re2 in a pixel driving circuit of a previous row can be reused as the first reset signal line Re1 in a pixel driving circuit of the current row. This arrangement can reduce the size of the pixel driving circuits in the second direction Y. In addition, the first gate layer can be used as a mask to perform conductorization processing on the first active layer in the display panel, that is, a region of the first active layer covered by the first gate layer can be configured to form the channel region of the transistor, and another region of the first active layer not covered by the first gate layer can be configured to form a conductive structure.

As shown in FIGS. 12, 15, and 21, the second gate layer may include a first initial signal line Vinit1, a second initial signal line Vinit2, a second conductive part 22, and a third conductive part 23. The first initial signal line Vinit1 may be configured to provide the first initial signal terminal in FIG. 10, and the second initial signal line Vinit2 may be configured to provide the second initial signal terminal in FIG. 10. Both the orthographic projection of the first initial signal line Vinit1 on the base substrate and the orthographic projection of the second initial signal line Vinit2 on the base substrate can extend along the first direction X. The orthographic projection of the third conductive part 23 on the base substrate may at least partially overlap with the orthographic projection of the first conductive part 11 on the base substrate, and the third conductive part 23 may be configured to form the second electrode of the capacitor C. A plurality of third conductive parts 23 distributed in the first direction X may be connected in sequence. In adjacent rows of pixel driving circuits, the orthographic projection, on the base substrate, of the first initial signal line Vinit1 in the next row of pixel driving circuits may be located between the orthographic projection, on the base substrate, of the second initial signal line Vinit2 in the current row of pixel driving circuits and the orthographic projection, on the base substrate, of the second reset signal line Re2 in the current row of pixel driving circuits. This setting can further reduce the size of the pixel driving circuits in the second direction. The second conductive part 22 may include a third conductive sub-part 223, and the orthographic projection of the third conductive sub-part 223 on the base substrate at least partially overlaps with the orthographic projection of the third active sub-part 723 on the base substrate. The second conductive part 22 can be connected to a stable voltage source, and the third conductive sub-part 223 can stabilize the voltage of the third active sub-part 723, thereby alleviating the problem of source-drain leakage of the second transistor T2 caused by voltage variation of the third active sub-part 723. The orthographic projection of the first initial signal line Vinit1 on the base substrate may at least partially overlap with the orthographic projection, on the base substrate, of the sixth active sub-part 716 in the current row of pixel driving circuits, so the first initial signal line Vinit1 can stabilize the voltage of the sixth active sub-part 716, thereby alleviating the problem of source-drain leakage of the first transistor T1 caused by voltage variation of the sixth active sub-part 716.

As shown in FIGS. 12, 16, and 22, the first source-drain layer may include a first power line VDD, a fifth bridging part 35, a sixth bridging part 36, a seventh bridging part 37, an eighth bridging part 38, and a ninth bridging part 39. The first power line VDD may be configured to provide the first power terminal in the pixel driving circuit shown in FIG. 10. The orthographic projection of the first power line VDD on the base substrate may extend along the second direction Y, and the first power line VDD may be connected to the second conductive part 22 through the via H to provide a stable voltage source to the second conductive part 22. In this exemplary embodiment, black squares represent the locations of vias. It should be understood that in other exemplary embodiments, a stable voltage source may also be provided to the second conductive part 22 through other signal lines. For example, a stable voltage source may be provided to the second conductive part 22 through the first initial signal line Vinit1 and the second initial signal line Vinit2. The first power line VDD can also be connected to the third conductive part 23 through a via to connect the second electrode of the capacitor and the first power terminal. The first power line VDD may form a grid structure with the third conductive part 23 connected in the first direction X. This arrangement can reduce the voltage drop caused by the resistance drop of the first power line VDD itself. The first power line VDD may also be connected to the twelfth active part 712 through a via to connect the first electrode of the fifth transistor T5 and the first power terminal. The fifth bridging part 35 can be connected to the first conductive part 11 and the eighth active part 78 respectively through vias, thereby connecting the gate of the driving transistor T3 to the second electrode of the first transistor T1 and the first electrode of the second transistor T2. As shown in FIG. 15, the third conductive part 23 may be provided with an opening 231, and the orthographic projection, on the base substrate, of the via connected to the fifth bridging part 35 and the first conductive part 11 may be located within the orthographic projection of the opening 231 on the base substrate, so as to prevent the via from being connected to the third conductive part 23. The sixth bridging part 36 may be connected to the ninth active part 79 through a via to connect the first electrode of the fourth transistor T4. The seventh bridging part 37 can be connected with the thirteenth active part 713 and the second initial signal line Vinit2 through vias respectively, so as to connect the first electrode of the seventh transistor and the second initial signal terminal. The eighth bridging part 38 can be connected with the tenth active part 710 and the first initial signal line Vinit1 through vias respectively, so as to connect the first electrode of the first transistor T1 and the first initial signal terminal. The ninth bridging part 39 may be connected to the eleventh active part 711 through a via, so as to connect the second electrode of the sixth transistor T6 and the second electrode of the seventh transistor T7. As shown in FIGS. 12, 15, 16, and 22, the second conductive part 22 may also include a first conductive sub-part 221. The first conductive sub-part 221 is connected to the third conductive sub-part 223. The orthographic projection of the first conductive sub-part 221 on the base substrate may extend along the first direction X, and may be located between the orthographic projection of the fifth bridging part 35 on the base substrate and the orthographic projection of the first reset signal line Re1 on the base substrate. In other words, an area covered by the orthographic projection of the first conductive sub-part 221 on the base substrate moving infinitely in the second direction Y at least partially intersects with an area covered by the orthographic projection of the fifth bridging part 35 on the base substrate moving infinitely in the second direction Y, and the first conductive sub-part 221 can shield the noise influence of the first reset signal line Re1 on the fifth bridging part 35, thereby improving the voltage stability of the node N in the pixel driving circuit shown in FIG. 10. In this exemplary embodiment, the area covered by the orthographic projection of the first conductive sub-part 221 on the base substrate moving infinitely in the second direction Y may cover the area covered by the orthographic projection of the fifth bridging part 35 on the base substrate moving infinitely in the second direction Y.

As shown in FIGS. 12, 17, and 23, the second source-drain layer may include: a data line Da, a power connection line 4VDD, and a tenth bridging part 410. The data line Da is configured to provide the data signal terminal in the pixel driving circuit shown in FIG. 10. Each column of pixel driving circuits is provided with a data line, and the data line is connected to the first electrodes of the fourth transistors in the same column of pixel driving circuits. The orthographic projection of the power connection line 4VDD on the base substrate and the orthographic projection of the data line Da on the base substrate can both extend along the second direction Y. The power connection line 4VDD can be connected to the first power line VDD through a via. This dual power line arrangement can further reduce the resistance of the power line itself. The data line Da may be connected to the sixth bridging part 36 through a via, thereby connecting the first electrode of the fourth transistor T4 and the data signal terminal. As shown in FIG. 23, the orthographic projection of the first power line VDD on the base substrate may be located between the orthographic projection of the data line Da on the base substrate and the orthographic projection of the fifth bridging part 35 on the base substrate. The first power line VDD can shield the noise influence of the data line Da in the pixel driving circuit of a current column on the fifth bridging part 35 in the pixel driving circuit of the current column. The tenth bridging part 410 may be connected to the ninth bridging part 39 through a via, thereby being connected to the second electrode of the sixth transistor.

As shown in FIGS. 12, 15, 16, and 23, the second conductive part 22 may also include a second conductive sub-part 222. The second conductive sub-part 222 is connected to a side of the first conductive sub-part 221 away from the third conductive sub-part 223. The orthographic projection of the second conductive sub-part 222 on the base substrate may extend along the second direction Y, and may be located between the orthographic projection of the fifth bridging part 35 on the base substrate and the orthographic projection of the data line Da on the base substrate. In other words, an area covered by the orthographic projection of the second conductive sub-part 222 on the base substrate moving infinitely in the first direction X at least partially overlaps with an area covered by the orthographic projection of the fifth bridging part 35 on the base substrate moving infinitely in the first direction X. The second conductive sub-part 222 can shield the noise influence of the data line Da on the fifth bridging part 35.

As shown in FIGS. 12, 18, and 24, the bridging layer may include a plurality of bridging parts Bg, where the plurality of bridging parts include a first bridging part Bg1 and a second bridging part Bg2. The first bridging part Bg1 may be connected to the tenth bridging part 410 in the pixel driving circuit of the first column and second row through a via. The second bridging part Bg2 may be connected to the tenth bridging part 410 in the pixel driving circuit of the third column and second row through a via.

As shown in FIGS. 12 and 19, the pixel electrode layer may include a plurality of electrode parts: a first electrode part R, a third electrode part G, and a second electrode part B. Each electrode part may be connected to the bridging part Bg through a via, thereby being connected to the second electrode of the sixth transistor. In the same electrode row, the first electrode part R, the third electrode part G, the second electrode part B, and the third electrode part G are sequentially distributed alternately in the first direction X. The plurality of electrode parts form a plurality of electrode columns. The plurality of electrode columns include a first electrode column ROW1, a third electrode column ROW3, a second electrode column ROW2, and a fourth electrode column ROW4 that are sequentially adjacent. The first electrode column ROW1 includes first electrode parts R and second electrode parts B distributed alternately in the second direction Y. The third electrode column ROW3 includes a plurality of third electrode parts G distributed in the second direction Y. The second electrode column ROW2 includes second electrode parts B and first electrode parts R distributed alternately in the second direction Y. The fourth electrode column ROW4 includes a plurality of third electrode parts G distributed in the second direction Y. The minimum distance S1, in the second direction, between the orthographic projections, on the base substrate, of two third electrode parts G located in adjacent electrode rows and the same electrode column is greater than a dimension S2, in the second direction, of the orthographic projection of the first electrode part R on the base substrate, or is greater than a dimension S3, in the second direction, of the orthographic projection of the second electrode part B on the base substrate. In some embodiments, the display panel further includes a pixel definition layer located on a side of the electrode layer away from the base substrate, and a pixel opening for forming the light-emitting unit is formed on the pixel definition layer. The orthographic projection of the first electrode part R on the base substrate coincides with the orthographic projection, on the base substrate, of a corresponding opening on the pixel definition layer, the orthographic projection of the third electrode part G on the base substrate coincides with the orthographic projection, on the base substrate, of a corresponding opening on the pixel definition layer, and the orthographic projection of the second electrode part B on the base substrate coincides with the orthographic projection, on the base substrate, of a corresponding opening on the pixel definition layer.

As shown in FIGS. 12 and 19, the second electrode part B in the first electrode column may be connected to the second bridging part Bg2 through a via, thereby being connected to the pixel driving circuit in the second row of the third column. The first electrode part R in the second electrode column may be connected to the first bridging part Bg1 through a via, thereby being connected to the pixel driving circuit in the second row of the first column. This setting allows the pixel driving circuits connected to the same data line to drive the light-emitting units of the same color.

As shown in FIGS. 12, 18, and 24, the first bridging part Bg1 includes a first extension portion Bg11. The orthographic projection of the first extension portion Bg11 on the base substrate extends along the first direction X, and at least partially overlaps with the orthographic projection, on the base substrate, of the first initial signal line Vinit1 in the adjacent next row of pixel driving circuits. For example, the orthographic projection of the first extension portion Bg11 on the base substrate can be located on the orthographic projection, on the base substrate, of the first initial signal line Vinit1 in the adjacent next row of pixel driving circuits. The second bridging part Bg2 includes a second extension portion Bg22. The orthographic projection of the second extension portion Bg22 on the base substrate extends along the first direction X, and at least partially overlaps with the orthographic projection, on the base substrate, of the second initial signal line Vinit2 in the current row of pixel driving circuits. For example, the orthographic projection of the second extension portion Bg22 on the base substrate can be located on the orthographic projection, on the base substrate, of the second initial signal line Vinit2 in the current row of pixel driving circuits. Since the first initial signal line and the second initial signal line output stable voltage signals, this arrangement can reduce the coupling effect of other AC signals on the bridging parts and improve the voltage stability of the bridging parts. It should be understood that the orthographic projection of the first extension portion Bg11 on the base substrate may at least partially overlap with the orthographic projection, on the base substrate, of any first signal line that outputs a stable voltage signal. The orthographic projection of the second extension portion Bg22 on the base substrate may at least partially overlap with the orthographic projection, on the base substrate, of any second signal line that outputs a stable voltage signal. In some exemplary embodiments, the first signal line may include the above-mentioned first initial signal line; the second signal line may include the above-mentioned second initial signal line. In other exemplary embodiments, the first signal line may further include signal lines such as an equipotential signal line of the first power terminal VDD in FIG. 10 and an equipotential signal line of the second power terminal VSS, and an equipotential line of the second initial signal terminal; the second signal line may further include an equipotential signal line of the first power terminal VDD in FIG. 10, an equipotential signal line of the second power terminal VSS, and an equipotential signal line of the first initial signal terminal.

As shown in FIGS. 12 and 19, the electrode layer may further include a plurality of addition parts, and the plurality of addition parts include: a first addition part E1, a second addition part E2, and a third addition part E3. In some embodiments, the first addition part E1 and the second addition part E2 are connected to the first electrode part R, and the third addition part E3 is connected to the second electrode part B. The orthographic projection of the first addition part E1 on the base substrate at least partially overlaps with the orthographic projection, on the base substrate, of the second active part 72 located at the same row and same column. The first addition part E1 can be configured to shield light for the second transistor, so as to reduce the impact of light on the output characteristics of the second transistor. The orthographic projection of the second addition part E2 on the base substrate at least partially overlaps with the orthographic projection, on the base substrate, of the second active part located at the same row and adjacent column. The second addition part E2 is also configured to shield light for the second transistor. The orthographic projection of the third addition part E3 on the base substrate at least partially overlaps with the orthographic projection, on the base substrate, of the second active part located at the same row and adjacent column. The third addition part E3 is also configured to shield light for the second transistor. The number of rows and columns of each addition part is the same as the number of rows and columns of the electrode part connected thereto, and the number of rows and columns of the second active part is the same as the number of rows and columns of the pixel driving circuit in which it is located.

It should be noted that, as shown in FIGS. 12, 22, 23, and 24, the black squares illustrated on the side of the first source-drain layer away from the base substrate represent the vias through which the first source-drain layer is connected to other layers on the side facing the base substrate; the black squares illustrated on the side of the second source-drain layer away from the base substrate represent the vias through which the second source-drain layer is connected to other layers on the side facing the base substrate; the black squares illustrated on the side of the bridging layer away from the base substrate represent the vias through which the bridging layer is connected to other layers on the side facing the base substrate; the black square illustrated on the side of the electrode layer away from the base substrate represent the vias through which the electrode layer is connected to other layers on the side facing the base substrate. The black squares only indicate the location of the vias. Different vias represented by black squares at different positions may penetrate different insulation layers.

As shown in FIG. 25, it is a partial cross-sectional view of the display panel shown in FIG. 12 taken along the dotted line AA. The display panel may further include a first insulating layer 91, a second insulating layer 92, a dielectric layer 93, a passivation layer 94, a first planarization layer 95, a third insulating layer 96 and a second planarization layer 97. The base substrate 90, active layer, first insulating layer 91, first gate layer, second insulating layer 92, second gate layer, dielectric layer 93, first source-drain layer, passivation layer 94, first planarization layer 95, second source-drain layer, third insulating layer 96, bridging layer, second planarization layer 97, and electrode layer can be stacked in sequence. The first insulating layer 91, the second insulating layer 92, and the third insulating layer 96 may be silicon oxide layers. The dielectric layer 93 may be a silicon nitride layer. The material of the passivation layer 94 may be silicon oxide, silicon nitride, and the like. The materials of the first planarization layer 95 and the second planarization layer 97 may be organic materials, such as polyimide (PI), polyethylene terephthalate (PET), polyethylene naphthalate (PEN), silicon-glass bonding structure (SOG) and the like. The base substrate 90 may include a glass substrate, a barrier layer, and a polyimide layer that are stacked in sequence. The barrier layer may be an inorganic material. The material of the first gate layer and the second gate layer may be one of molybdenum, aluminum, copper, titanium, niobium or an alloy thereof, or a molybdenum/titanium alloy or a laminate or other conductive layer. The material of the first source-drain layer and the second source-drain layer may include a metal material, for example, it may be one of molybdenum, aluminum, copper, titanium, niobium or an alloy thereof, or a molybdenum/titanium alloy or laminate, or titanium/aluminum/titanium laminate or other conductive layers. The bridging layer may be a conductive layer such as an indium tin oxide layer.

As shown in FIGS. 26-28, FIG. 26 is a structural layout the display panel according to another exemplary embodiment of this disclosure, FIG. 27 shows a structural layout of the first active layer, the first gate layer, the second gate layer, the first source-drain layer, the second source-drain layer, and the bridging layer, and FIG. 28 is a structural layout of the bridging layer shown in FIG. 26.

The differences between the display panel shown in FIG. 26 and the display panel shown in FIG. 12 lie in the followings. In the display panel shown in FIG. 26, the second bridging part Bg2 may include a second extension portion Bg22 and a third extension portion Bg23. The orthographic projection of the second extension portion Bg22 on the base substrate extends along the first direction X and at least partially overlaps with the orthographic projection, on the base substrate, of the first initial signal line Vinit1 in the pixel driving circuit of the current row. The orthographic projection of the third extension portion Bg23 on the base substrate extends along the second direction Y and at least partially overlaps with the orthographic projection, on the base substrate, of the first power line VDD in the pixel driving circuit of the current column. For example, the orthographic projection of the second extension portion Bg22 on the base substrate may be located on the orthographic projection of the first initial signal line Vinit1 on the base substrate, and the orthographic projection of the third extension portion Bg23 on the base substrate may be located on the orthographic projection of the first power line VDD on the base substrate. This setting can also reduce the noise impact of other AC signals on the bridging parts. It should be understood that the orthographic projection of the third extension portion Bg23 on the base substrate may overlap with the orthographic projection, on the base substrate, of any third signal line outputting a stable voltage signal. In this exemplary embodiment, the third signal line may include the above-mentioned first power line VDD. In other exemplary embodiments, the third signal line may further include: an equipotential signal line of the second power terminal in FIG. 10, an equipotential signal line of the first initial signal terminal, an equipotential signal line of the second initial signal terminal, and the like. In addition, in this exemplary embodiment, the orthographic projections of the first bridging part Bg1 and the second bridging part Bg2 on the base substrate respectively overlap with the orthographic projections of different first initial signal lines Vinit1 on the base substrate, so that this setting can be applied to a display panel provided with a single initial signal line or a highly integrated display panel. The display panel with a single initial signal line refers to a display panel in which one row of pixel driving circuits is provided with one initial signal line, that is, the first transistor T1 and the seventh transistor T7 are connected to the same initial signal line.

As shown in FIGS. 29-31, FIG. 29 is a structural layout of the display panel according to another exemplary embodiment of this disclosure, FIG. 30 shows a structural layout of the first active layer, the first gate layer, the second gate layer, the first source-drain layer, the second source-drain layer, and the bridging layer, and FIG. 31 is a structural layout of the bridging layer in FIG. 29.

The differences between the display panel shown in FIG. 29 and the display panel shown in FIG. 12 lie in the followings. In the display panel shown in FIG. 29, the plurality of bridging parts Bg further include a third bridging part Bg3 and a fourth bridging part Bg4. The third bridging part Bg3 can be configured to connect the first electrode part R and the pixel driving circuit located in the same number of rows and columns, and the fourth bridging part Bg4 can be configured to connect the second electrode part B and the pixel driving circuit located in the same number of rows and columns. The third bridging part includes a fourth extension portion Bg34, and the orthographic projection of the fourth extension portion Bg34 on the base substrate may overlap with the orthographic projection of the power connection line 4VDD on the base substrate. The fourth bridging part Bg4 includes a fifth extension portion Bg45, and the orthographic projection of the fifth extension portion Bg45 on the base substrate may overlap with the orthographic projection of the power connection line 4VDD on the base substrate. This setting can compensate the parasitic capacitance of the third bridging part Bg3 through the fourth extension portion Bg34, and compensate the parasitic capacitance of the fourth bridging part Bg4 through the fifth extension portion Bg45, so that the first bridging part Bg1 and the third bridging part Bg3 can have their parasitic capacitances close to or consistent with each other, and the second bridging part Bg2 and the fourth bridging part Bg4 can have their parasitic capacitances close to or consistent with each other, so as to solve the problem of uneven parasitic capacitance at the equipotential points of different electrode parts, thereby improving the uniformity of the display panel. Herein, the parasitic capacitance between the first bridging part Bg1 and other structures is C1, the parasitic capacitance between the second bridging part Bg2 and other structures is C2, the parasitic capacitance between the third bridging part Bg3 and other structures is C3, and the parasitic capacitance between the fourth bridging part Bg4 and other structures is C4. In some embodiments, C1=N1*C3, C2=N2*C4. N1 is greater than or equal to 70% and less than or equal to 130%. For example, N1 can be equal to 70%, 80%, 90%, 95%, 100%, 105%, 110%, 120%, 130%, and the like. N2 can be greater than or equal to 70% and less than or equal to 130%. For example, N2 can be equal to 70%, 80%, 90%, 95%, 100%, 105%, 110%, 120%, 130%, and the like.

Some exemplary embodiments further provide another display panel, which may include a base substrate, a first active layer, a first gate layer, a second gate layer, a first source-drain layer, a second source-drain layer, a bridging layer and an electrode layer that are stacked in sequence, where an insulating layer(s) may be provided between the above structural layers. As shown in FIGS. 32-44, FIG. 32 is a structural layout of the display panel according to an exemplary embodiment of this disclosure; FIG. 33 is a structural layout of the first active layer in FIG. 32; FIG. 34 is a structural layout of the first gate layer in FIG. 32; FIG. 35 is a structural layout of the second gate layer in FIG. 32; FIG. 36 is a structural layout of the first source-drain layer in FIG. 32; FIG. 37 is a structural layout of the second source-drain layer in FIG. 32; FIG. 38 is a structural layout of the bridging layer in FIG. 32; FIG. 39 is a structural layout of the electrode layer in FIG. 32; FIG. 40 is a structural layout of the first active layer and the first gate layer in FIG. 32; FIG. 41 is a structural layout of the first active layer, the first gate layer and the second gate layer in FIG. 32; FIG. 42 is a structural layout of the first active layer, the first gate layer, the second gate layer, and the first source-drain layer in FIG. 32; FIG. 43 is a structural layout of the first active layer, the first gate layer, the second gate layer, the first source-drain layer, and the second source-drain layer in FIG. 32; and FIG. 44 is a structural layout of the first active layer, the first gate layer, the second gate layer, the first source-drain layer, the second source-drain layer and the bridging layer in FIG. 32.

As shown in FIGS. 32, 33, and 40, the first active layer may include a first active part 71, a second active part 72, a third active part 73, a fourth active part 74, a fifth active part 75, a sixth active part 76 and a seventh active part 77. In some embodiments, the first active part 71 is configured to form the channel region of the first transistor T1, the second active part 72 is configured to form the channel region of the second transistor T2, the third active part 73 is configured to form the channel region of the driving transistor T3, the fourth active part 74 is configured to form the channel region of the fourth transistor T4, the fifth active part 75 is configured to form the channel region of the fifth transistor T5, the sixth active part 76 is configured to form the channel region of the sixth transistor T6, and the seventh active part 77 is configured to form the channel region of the seventh transistor T7. The first active part 71 includes a fourth active sub-part 714 and a fifth active sub-part 715, and the second active part 72 includes a first active sub-part 721 and a second active sub-part 722. The first active layer may further include a sixth active sub-part 716 connected between the fourth active sub-part 714 and the fifth active sub-part 715, a third active sub-part 723 connected between the first active sub-part 721 and the second active sub-part 722, an eighth active part 78 connected between the second active part 72 and the first active part 71, a ninth active part 79 connected on one side of the fourth active part 74 away from the third active part 73, a tenth active part 710 connected on one side of the first active part 71 away from the second active part 72, an eleventh active part 711 connected between the sixth active part 76 and the seventh active part 77, a twelfth active part 712 connected to one side of the fifth active part 75 away from the third active part 73, and a thirteenth active part 713 connected to one side of the seventh active part 77 away from the sixth active part 76. The first active layer may be formed of polysilicon material. Correspondingly, the first transistor T1, the second transistor T2, the driving transistor T3, the fourth transistor T4, the fifth transistor T5, the sixth transistor T6, and the seventh transistor T7 may be P-type low temperature polysilicon thin film transistor.

As shown in FIGS. 32, 34, and 40, the first gate layer may include: a first reset signal line Re1, a second reset signal line Re2, a first gate line G1, an enable signal line EM, and a first conductive part 11. In some embodiments, the first reset signal line Re1 is configured to provide the first reset signal terminal in FIG. 10, the second reset signal line Re2 is configured to provide the second reset signal terminal in FIG. 10, the first gate line G1 is configured to provide the first gate driving signal terminal in FIG. 10, the enable signal line EM is configured to provide the enable signal terminal in FIG. 10. The orthographic projection of the first reset signal line Re1 on the base substrate may extend along the first direction X and cover the orthographic projection of the first active part 71 on the base substrate, and a partial structure of the first reset signal line Re1 is configured to form the gate of the first transistor T1. The orthographic projection of the second reset signal line Re2 on the base substrate may extend along the first direction X and cover the orthographic projection of the seventh active part 77 on the base substrate, and a partial structure of the second reset signal line Re2 is configured to form the gate of the seventh transistor T7. The orthographic projection of the enable signal line EM on the base substrate may extend along the first direction X and cover the orthographic projection of the fifth active part 75 on the base substrate and the orthographic projection of the sixth active part 76 on the base substrate. A partial structure of the enable signal line EM is configured to form the gate of the fifth transistor T5, and another partial structure of the enable signal line EM is configured to form the gate of the sixth transistor T6. The orthographic projection of the first gate line G1 on the base substrate extends along the first direction X and covers the orthographic projection of the second active part 72 on the base substrate and the orthographic projection of the fourth active part 74 on the base substrate. A partial structure of the first gate line G1 is configured to form the gate of the second transistor T2, and another partial structure of the first gate line G1 is configured to form the gate of the fourth transistor T4. The orthographic projection of the first conductive part 11 on the base substrate covers the orthographic projection of the third active part 73 on the base substrate, and the first conductive part 11 is configured to form the gate of the driving transistor T3. The first conductive part 11 can also be reused as the first electrode of the capacitor C. In some embodiments, the orthographic projection of the first conductive part 11 on the base substrate may be located between the orthographic projection of the first gate line G1 on the base substrate and the orthographic projection of the enable signal line EM on the base substrate. The orthographic projection of the first reset signal line Re1 on the base substrate may be located on a side of the orthographic projection of the first gate line G1 on the base substrate away from the orthographic projection of the first conductive part 11 on the base substrate. The orthographic projection of the second reset signal line Re2 on the base substrate may be located on a side of the orthographic projection of the enable signal line EM on the base substrate away from the orthographic projection of the first conductive part 11 on the base substrate. In the pixel driving circuits of adjacent rows, the second reset signal line Re2 in the pixel driving circuit of the previous row can be shared as the first reset signal line Re1 in the pixel driving circuit of this row. This setting can reduce the size of the pixel driving circuit in the second direction Y. In addition, conduction processing can be performed on the first active layer by using the first gate layer as a mask in this display panel, that is, the area of the first active layer covered by the first gate layer can form the channel region of the transistor, and the area of the first active layer not covered by the first gate layer forms a conductor structure.

As shown in FIGS. 32, 35, and 41, the second gate layer may include a first initial signal line Vinit1, a second initial signal line Vinit2, a second conductive part 22, and a third conductive part 23. The first initial signal line Vinit1 may be configured to provide the first initial signal terminal in FIG. 10, and the second initial signal line Vinit2 may be configured to provide the second initial signal terminal in FIG. 10. Both the orthographic projection of the first initial signal line Vinit1 on the base substrate and the orthographic projection of the second initial signal line Vinit2 on the base substrate can extend along the first direction X. The orthographic projection of the third conductive part 23 on the base substrate may at least partially overlap with the orthographic projection of the first conductive part 11 on the base substrate, and the third conductive part 23 may be configured to form the second electrode of the capacitor C. In some embodiments, a plurality of third conductive parts 23 distributed in the first direction X may be connected in sequence. In the adjacent rows of pixel driving circuits, the orthographic projection, on the base substrate, of the first initial signal line Vinit1 in the next row of pixel driving circuits may be located between the orthographic projection, on the base substrate, of the enable signal line EM in the current row of pixel driving circuits and the orthographic projection, on the base substrate, of the second reset signal line Re2 in the current row of pixel driving circuits. This setting can further reduce the size of the pixel driving circuit in the second direction. The second conductive part 22 may include a third conductive sub-part 223, and the orthographic projection of the third conductive sub-part 223 on the base substrate at least partially overlaps with the orthographic projection of the third active sub-part 723 on the base substrate. The second conductive part 22 can be connected to a stable voltage source, and the third conductive sub-part 223 can stabilize the voltage of the third active sub-part 723, thereby alleviating the problem of source-drain leakage of the second transistor T2 caused by voltage variation of the third active sub-part 723. The orthographic projection of the first initial signal line Vinit1 on the base substrate may at least partially overlap with the orthographic projection of the sixth active sub-part 716 on the base substrate, and the first initial signal line Vinit1 can stabilize the voltage of the sixth active sub-part 716, thereby alleviating the problem of source-drain leakage of the first transistor T1 caused by voltage variation of the sixth active sub-part 716.

As shown in FIGS. 32, 36, and 42, the first source-drain layer may include a first power line VDD, a data line Da, a first initial connection line 4Vinit1, a fifth bridging part 35, a seventh bridging part 37, and a ninth bridging part 39. The first power line VDD may be configured to provide the first power terminal in the pixel driving circuit shown in FIG. 10. The orthographic projection of the first power line VDD on the base substrate may extend along the second direction Y, and the first power line VDD may be connected to the second conductive part 22 through a via to provide a stable voltage source to the second conductive part 22. It should be understood that in other exemplary embodiments, a stable voltage source may also be provided to the second conductive part 22 through other signal lines. For example, a stable voltage source may be provided to the second conductive part 22 through the first initial signal line Vinit1 and the second initial signal line Vinit2. The first power line VDD can also be connected to the third conductive part 23 through a via, thereby being connected to the second electrode of the capacitor and the first power terminal. The first power line VDD may form a grid structure with the third conductive part 23 connected in the first direction X, thereby reducing the voltage drop caused by the resistance of the first power line VDD itself. The first power line VDD may also be connected to the twelfth active part 712 through a via, thereby being connected to the first electrode of the fifth transistor T5 and the second power terminal. The data line Da is configured to provide the data signal terminal in the pixel driving circuit shown in FIG. 10. Each column of pixel driving circuits is provided with a data line, and the data line is connected to the first electrode of the fourth transistor in the same column of pixel driving circuits. The orthographic projection of the data line Da on the base substrate can extend along the second direction Y. The data line Da can be connected to the ninth active part 79 through a via, thereby being connected to the first electrode of the fourth transistor T4 and the data signal terminal. The orthographic projection of the first initial connection line 4Vinit1 on the base substrate extends along the second direction Y. The first initial connection line 4Vinit1 is connected, through a via, to the first initial signal line Vinit1 that intersects with the orthographic projection of the first initial connection line 4Vinit1 on the base substrate. The first initial connection line 4 Vinit1 and the first initial signal line Vinit1 may form a grid structure, thereby reducing the resistance of the first initial signal line Vinit1. The first initial connection line 4Vinit1 is also connected to the tenth active part 710 through a via, thereby being connected to the first initial signal terminal and the first electrode of the first transistor. The fifth bridging part 35 can be connected to the first conductive part 11 and the eighth active part 78 respectively through vias, thereby being connected to the gate of the driving transistor T3, the second electrode of the first transistor T1, and the first electrode of the second transistor T2. As shown in FIG. 35, the third conductive part 23 may be provided with an opening 231, and the orthographic projection, on the base substrate, of the via connected to the fifth bridging part 35 and the first conductive part 11 may be located within the orthographic projection of the opening 231 on the base substrate, so as to prevent the via from being connected to the third conductive part 23. The seventh bridging part 37 can be connected to the thirteenth active part 713 and the second initial signal line Vinit2 through vias respectively, thereby being connected to the first electrode of the seventh transistor and the second initial signal terminal. The ninth bridging part 39 may be connected to the eleventh active part 711 through a via, thereby being connected to the second electrode of the sixth transistor T6 and the second electrode of the seventh transistor T7.

As shown in FIGS. 32, 35, 36, and 42, the second conductive part 22 may also include a first conductive sub-part 221. The first conductive sub-part 221 is connected to the third conductive sub-part 223. The orthographic projection of the first conductive sub-part 221 on the base substrate may extend along the first direction X and be located between the orthographic projection of the fifth bridging part 35 on the base substrate and the orthographic projection of the first reset signal line Re1 on the base substrate. In other words, the area covered by the orthographic projection of the first conductive sub-part 221 on the base substrate moving infinitely in the second direction Y at least partially intersects with the area covered by the orthographic projection of the fifth bridging part 35 on the base substrate moving infinitely in the second direction Y. The first conductive sub-part 221 can shield the noise influence of the first reset signal line Re1 on the fifth bridging part 35, thereby improving the voltage stability of the node N in the pixel driving circuit shown in FIG. 10. In this exemplary embodiment, the area covered by the orthographic projection of the first conductive sub-part 221 on the base substrate moving infinitely in the second direction Y can cover the area covered by the orthographic projection of the fifth bridging part 35 on the base substrate moving infinitely in the second direction Y. The second conductive part 22 may also include a second conductive sub-part 222. The second conductive sub-part 222 is connected to one side of the first conductive sub-part 221 away from the third conductive sub-part 223. The orthographic projection of the second conductive sub-part 222 on the base substrate can extend along the second direction Y and be located between the orthographic projection of the fifth bridging part 35 on the base substrate and the orthographic projection of the data line Da on the base substrate. In other words, the area covered by the orthographic projection of the second conductive sub-part 222 on the base substrate moving infinitely in the first direction X at least partially intersects with the area covered by the orthographic projection of the fifth bridging part 35 on the base substrate moving infinitely in the first direction X. The second conductive sub-part 222 can shield the noise influence of the data line Da on the fifth bridging part 35. The orthographic projection, on the base substrate, of the second initial signal line Vinit2 in the previous adjacent row of pixel driving circuits can be located between the orthographic projection, on the base substrate, of the first reset signal line Re1 in the current row of pixel driving circuits and the orthographic projection of the fifth bridging part 35 on the base substrate. The second initial signal line Vinit2 can also shield the noise influence of the first reset signal line Re1 on the fifth bridging part 35.

As shown in FIGS. 32, 37, and 43, the second source-drain layer may include: a virtual data line Dmy and a tenth bridging part 410. The fan-out area of the display panel may be located in the display area, and data bridging lines located at the second source-drain layer may be provided in the fan-out area so that the data lines can be fan-out in a local area. The virtual data line Dmy is configured to simulate the occlusion state and parasitic capacitance of the data bridging line in the fan-out area so that the entire display area can display uniformly. The tenth bridging part 410 may be connected to the ninth bridging part 39 through a via, thereby being connected to the second electrode of the sixth transistor.

As shown in FIGS. 32, 38, and 44, the bridging layer may include a plurality of bridging parts Bg, where the plurality of bridging parts include a first bridging part Bg1 and a second bridging part Bg2. The first bridging part Bg1 may be connected to the tenth bridging part 410 in the pixel driving circuit of the first column and second row through a via. The second bridging part Bg2 may be connected to the tenth bridging part 410 in the pixel driving circuit of the third column and second row through a via. The first bridging part Bg1 includes a first extension portion Bg11. The orthographic projection of the first extension portion Bg11 on the base substrate extends along the first direction X, and at least partially overlaps with the orthographic projection, on the base substrate, of the first initial signal line Vinit1 in the adjacent next row of pixel driving circuits. For example, the orthographic projection of the first extension portion Bg11 on the base substrate is located on the orthographic projection, on the base substrate, of the first initial signal line Vinit1 in the adjacent next row of pixel driving circuits. The second bridging part Bg2 may include a second extension portion Bg22 and a third extension portion Bg23. The orthographic projection of the second extension portion Bg22 on the base substrate extends along the first direction X, and at least partially overlaps with the orthographic projection, on the base substrate, of the second initial signal line Vinit2 in the adjacent previous row of pixel driving circuits. For example, the orthographic projection of the second extension portion Bg22 on the base substrate can be located on the orthographic projection, on the base substrate, of the second initial signal line Vinit2 in the adjacent previous row of pixel driving circuits. The orthographic projection of the third extension portion Bg23 on the base substrate extends along the second direction Y, and at least partially overlaps with the orthographic projection, on the base substrate, of the first power line VDD in the current column of pixel driving circuits. For example, the orthographic projection of the third extension portion Bg23 on the base substrate may be located on the orthographic projection, on the base substrate, of the first power line VDD in the current column of pixel driving circuits. Since the first initial signal line Vinit1, the second initial signal line Vinit2, and the first power line VDD are configured to provide a stable voltage source, this setting can reduce the coupling effect of the AC signal on the bridging part and improve the voltage stability of the bridging part. In addition, this setting can also improve the transmittance of the display panel.

As shown in FIGS. 32 and 39, the pixel electrode layer may include a plurality of electrode parts: a first electrode part R, a third electrode part G, and a second electrode part B. Each electrode part may be connected to a bridging part Bg through a via, thereby being connected to the second electrode of the six transistor. In the same row of electrodes, the first electrode part R, the third electrode part G, the second electrode part B, and the third electrode part G are sequentially distributed alternately in the first direction X. The plurality of electrode parts form a plurality of electrode columns. The plurality of electrode columns include a first electrode column ROW1, a third electrode column ROW3, a second electrode column ROW2, and a fourth electrode column ROW4 that are sequentially adjacent. The first electrode column ROW1 includes the first electrode part R and the second electrode part B distributed alternately in the second direction Y; the third electrode column ROW3 includes a plurality of third electrode parts G distributed in the second direction Y; the second electrode column ROW2 includes the second electrode part B and the first electrode part R distributed alternately in the second direction Y; and the fourth electrode column ROW4 includes a plurality of third electrode parts G distributed in the second direction Y. The minimum distance S1, in the second direction, between the orthographic projections, on the base substrate, of two third electrode parts G located in the same electrode column and adjacent electrode row is greater than the dimension S2, in the second direction, of the orthographic projection of the first electrode part R on the base substrate, or is greater than the dimension S3, in the second direction, of the orthographic projection of the second electrode part B on the base substrate. In some embodiments, the orthographic projection of the first electrode part R on the base substrate coincides with the orthographic projection, on the base substrate, of a corresponding opening on the pixel definition layer, the orthographic projection of the third electrode part G on the base substrate coincides with the orthographic projection, on the base substrate, of a corresponding opening on the pixel definition layer, and the orthographic projection of the second electrode part B on the base substrate coincides with the orthographic projection, on the base substrate, of a corresponding opening on the pixel definition layer.

As shown in FIGS. 32 and 39, the second electrode part B in the first electrode column may be connected to the second bridging part Bg2 through a via, thereby being connected to the pixel driving circuit in the second row and the third column. The first electrode part R in the second electrode row of the second electrode column may be connected to the first bridging part Bg1 through a via, thereby being connected to the pixel driving circuit in the first column and second row. In other words, according to this application, at least part of the bridging parts Bg are used to connect pixel driving circuits and electrode parts located at different columns, so that the pixel driving circuits connected to the same data line can drive the light-emitting units of the same color. In this exemplary embodiment, the pixel driving circuits and electrode parts connected to the first bridging part Bg1 may be located in the same row but in different columns, and the pixel driving circuits and electrode parts connected to the second bridging part Bg2 may be located in the same row but in different columns. It should be understood that in other exemplary embodiments, the pixel driving circuits and the electrode parts connected by the bridging part may be located in different rows and different columns.

As shown in FIGS. 32 and 39, the electrode layer may further include a fourth addition part E4, which is connected to the third electrode part G. The orthographic projection of the fourth addition part E4 on the base substrate at least partially overlaps with the orthographic projection of the second active the portion 72 on the base substrate, and the fourth addition part E4 can shield light for the second transistor, thereby reducing the impact of light on the output characteristics of the second transistor.

It should be noted that, as shown in FIGS. 32, 42, 43, and 44, the black squares illustrated on the side of the first source-drain layer away from the base substrate represent the vias through which the first source-drain layer is connected to other layers on the side facing the base substrate; the black squares illustrated on the side of the second source-drain layer away from the base substrate represent the vias through which the second source-drain layer is connected to other layers on the side facing the base substrate; the black squares illustrated on the side of the bridging layer away from the base substrate represent the vias through which the bridging layer is connected to other layers on the side facing the base substrate; and the black squares illustrated on the side of the electrode layer away from the base substrate represent the vias through which the electrode layer is connected to other layers on the side facing the base substrate. The black squares only indicate the positions of the vias. Different vias represented by black squares at different positions may penetrate different insulation layers.

As shown in FIG. 45, it is a partial cross-sectional view of the display panel shown in FIG. 32 taken along the dotted line BB. The display panel may further include a first insulating layer 91, a second insulating layer 92, a dielectric layer 93, a passivation layer 94, a first planarization layer 95, a third insulating layer 96, and a second planarization layer 97. The base substrate 90, active layer, first insulating layer 91, first gate layer, second insulating layer 92, second gate layer, dielectric layer 93, first source-drain layer, passivation layer 94, first planarization layer 95, second source-drain layer, third insulating layer 96, bridging layer, second planarization layer 97, and electrode layer can be stacked in sequence. The first insulating layer 91, the second insulating layer 92, and the third insulating layer 96 can be silicon oxide layers. The dielectric layer 93 can be a silicon nitride layer. The material of the passivation layer 94 can be silicon oxide, silicon nitride, or the like. The materials of the first planarization layer 95 and the second planarization layer 97 can be organic materials, such as polyimide (PI), polyethylene terephthalate (PET), polyethylene naphthalate (PEN), silicon-glass bonding structure (SOG) and the like. The base substrate 90 may include a glass base substrate, a barrier layer, and a polyimide layer that are stacked in sequence. The barrier layer may be an inorganic material. The material of the first gate layer and the second gate layer may be one of molybdenum, aluminum, copper, titanium, niobium or an alloy thereof, or a molybdenum/titanium alloy or laminate or other conductive layer. The material of the first source-drain layer and the second source-drain layer may include a metal material, for example, it may be one of molybdenum, aluminum, copper, titanium, niobium or an alloy thereof, or a molybdenum/titanium alloy or laminate, or titanium/aluminum/titanium laminate or other conductive layers. The bridging layer may be a conductive layer such as an indium tin oxide layer.

As shown in FIGS. 46-47, FIG. 46 is a structural layout of the display panel according to another exemplary embodiment of this disclosure, and FIG. 47 is a structural layout of the electrode layer in FIG. 46. The display panel shown in FIG. 46 is different from the display panel shown in FIG. 32 in that the display panel shown in FIG. 46 is not provided with a bridging layer. In addition, the electrode layer in the display panel shown in FIG. 46 includes a first bridging part Bg1 and a second bridging part Bg2. The first bridging part Bg1 is connected to the first electrode part R of the second electrode column ROW2, and the first bridging part Bg1 is connected to the tenth bridging part 410 in the pixel driving circuit of the second row and first column through a via. The second bridging part Bg2 is connected to the second electrode part B of the first electrode column ROW1, and the second bridging part Bg2 is connected to the tenth bridging part 410 in the pixel driving circuit of the second row and third column through a via. The first bridging part Bg1 may include a first extension portion Bg11 and a sixth extension portion Bg16. The orthographic projection of the first extension portion Bg11 on the base substrate extends along the first direction X and at least partially overlaps with the orthographic projection, on the base substrate, of an initial signal line Vinit1 in the next adjacent row of pixel driving circuits. The orthographic projection of the sixth extension portion Bg16 on the base substrate extends along the second direction Y and at least partially overlaps with the orthographic projection, on the base substrate, of the first power line VDD in the current column of pixel driving circuits. It should be understood that the orthographic projection of the sixth extension portion Bg16 on the base substrate may overlap with the orthographic projection, on the base substrate, of any fourth signal line that outputs a stable voltage signal. In this exemplary embodiment, the fourth signal line may include the above-mentioned first power line VDD. In other exemplary embodiments, the fourth signal line may further include: an equipotential signal line of the second power supply terminal in FIG. 10, an equipotential signal line of the first initial signal terminal, an equipotential signal line of the second initial signal terminal, and the like. The second bridging part Bg2 includes a second extension portion Bg22, a third extension portion Bg23, and a seventh extension portion Bg27. The seventh extension portion Bg27 is connected between the second extension portion Bg22 and the third extension portion Bg23. The orthographic projection of the second extension portion Bg22 on the base substrate extends along the first direction X and at least partially overlaps with the orthographic projection, on the base substrate, of the second initial signal line Vinit2 in the previous adjacent row of pixel driving circuits. The orthographic projection of the third extending portion Bg23 on the base substrate extends along the second direction Y and at least partially overlaps with the orthographic projection of the third conductive part 23 on the base substrate. This setting can reduce the coupling effect of other AC signals on the bridging part, and can also reduce the impact of the first bridging part Bg1 and the second bridging part Bg2 on the transmittance of the display panel. In addition, the orthographic projection of the seventh extension portion Bg27 on the base substrate can overlap with the orthographic projection of the second active part 72 on the base substrate, and the seventh extension portion Bg27 can reduce the impact of light on the output characteristics of the second transistor T2.

As shown in FIG. 48, it is a schematic circuit structure diagram of the pixel driving circuit in the display panel of this disclosure. The pixel driving circuit may include: a driving transistor T3, a first transistor T1, a second transistor T2, a fourth transistor T4, a fifth transistor T5, a sixth transistor T6, a seventh transistor T7, and a capacitor C. Herein, the first electrode of the fourth transistor T4 is connected to the data signal terminal Da, the second electrode of the fourth transistor T4 is connected to the first electrode of the driving transistor T3, and the gate of the fourth transistor T4 is connected to the first gate driving signal terminal G1. The first electrode of the fifth transistor T5 is connected to the first power terminal VDD, the second electrode of the fifth transistor T5 is connected to the first electrode of the driving transistor T3, and the gate of the fifth transistor T5 is connected to the enable signal terminal EM. The gate of the driving transistor T3 is connected to the node N. The first electrode of the second transistor T2 is connected to the node N, the second electrode of the second transistor T2 is connected to the second electrode of the driving transistor T3, and the gate of the second transistor T2 is connected to the second gate driving signal terminal G2. The first electrode of the sixth transistor T6 is connected to the second electrode of the driving transistor T3, the second electrode of the sixth transistor T6 is connected to the second electrode of the seventh transistor T7, and the gate of the sixth transistor T6 is connected to the enable signal terminal EM. The first electrode of the seventh transistor T7 is connected to the second initial signal terminal Vinit2, and the gate of the seventh transistor T7 is connected to the second reset signal terminal Re2. The second electrode of the first transistor T1 is connected to the node N, the first electrode of the first transistor T1 is connected to the first initial signal terminal Vinit1, and the gate of the first transistor T1 is connected to the first reset signal terminal Re1. The first electrode of the capacitor C is connected to the node N, and the second electrode of the capacitor C is connected to the first power terminal VDD. The pixel driving circuit can be connected to a light-emitting unit OLED for driving the light-emitting unit OLED to emit light. The light-emitting unit OLED can be connected between the second electrode of the sixth transistor T6 and the second power terminal VSS. The first electrode of the light-emitting unit may be the anode of the light-emitting unit, and the second electrode of the light-emitting unit may be the cathode of the light-emitting unit. The first transistor T1 and the second transistor T2 may be N-type transistors. For example, the first transistor T1 and the second transistor T2 may be N-type metal oxide transistors. N-type transistors have small leakage current, thereby avoiding current leaking from the node N through the first transistor T1 and the second transistor T2 in the light emitting phase. In addition, the driving transistor T3, the fourth transistor T4, the fifth transistor T5, the sixth transistor T6, and the seventh transistor T7 may be P-type transistors. For example, the driving transistor T3, the fourth transistor T4, the fifth transistor T5, the sixth transistor T6 and the seventh transistor T7 may be P-type low-temperature polycrystalline silicon transistors. P-type transistors have high carrier mobility, which is conducive to the display panel achieving high resolution, high response speed, high pixel density, and high aperture ratio. The first initial signal terminal and the second initial signal terminal may output the same or different voltage signals according to actual conditions.

As shown in FIG. 49, it is a timing diagram of each node in a driving method of the pixel driving circuit in FIG. 48. Herein, G1 represents the timing of the first gate driving signal terminal G1, G2 represents the timing of the second gate driving signal terminal G2, Re1 represents the timing of the first reset signal terminal Re1, Re2 represents the timing of the second reset signal terminal Re2, EM represents the timing of the enable signal terminal EM, and Da represents the timing of the data signal terminal Da. The driving method of the pixel driving circuit may include a reset phase t1, a data writing phase t2, and a light emitting phase t3. In the reset phase t1, the first reset signal terminal Re1 outputs a high-level signal, the second reset signal terminal Re2 outputs a low-level signal, the first transistor T1 and the seventh transistor T7 are turned on, the first initial signal terminal Vinit1 inputs the first initial signal to the node N, and the second initial signal terminal Vinit2 inputs the second initial signal to the first electrode of the light-emitting unit OLED. In the data writing phase t2, the second gate driving signal terminal G2 outputs a high-level signal, the first gate driving signal terminal G1 outputs a low-level signal, the fourth transistor T4 and the second transistor T2 are turned on, and the data signal terminal Da outputs the data signal to write the compensation voltage Vdata+Vth to the node N, where Vdata is the voltage of the data signal, and Vth is the threshold voltage of the driving transistor T3. In the light emitting phase t3, the enable signal terminal EM outputs a low-level signal, the sixth transistor T6 and the fifth transistor T5 are turned on, and the driving transistor T3 drives the light-emitting unit to emit light under the action of the compensation voltage Vdata+Vth stored in the capacitor C.

Output current formula of the driving transistor is as follows:

$$I = ( μ WCox / 2 L ) {( Vgs - Vth )}^{2}$$

where I is the output current of the driving transistor; u is the carrier mobility; Cox is the gate capacitance per unit area, W is the channel width of the driving transistor, L is the channel length of the driving transistor, Vgs is the gate-source voltage difference of the driving transistor, and Vth is the threshold voltage of the driving transistor. The output current of the driving transistor in the pixel driving circuit of this disclosure is I=(μWCox/2L) (Vdata+Vth−Vdd−Vth)². The influence of the driving transistor threshold on the output current can be avoided in the pixel driving circuit.

This exemplary embodiment further provides another display panel. The display panel may include a base substrate, a shielding layer, a first active layer, a first gate layer, a second gate layer, a second active layer, a third gate layer, a first source-drain layer, a second source-drain layer, and an electrode layer that are stacked in sequence, where an insulating layer(s) may be provided between the adjacent layers. As shown in FIGS. 50-66, FIG. 50 is a structural layout of the display panel according to an exemplary embodiment of this disclosure; FIG. 51 is a structural layout of the shielding layer in FIG. 50; FIG. 52 is a structural layout of the first active layer in FIG. 50; FIG. 53 is a structural layout of the first gate layer in FIG. 50; FIG. 54 is a structural layout of the second gate layer in FIG. 50; FIG. 55 is a structural layout of the second active layer in FIG. 50; FIG. 56 is a structural layout of the third gate layer in FIG. 50; FIG. 57 is a structural layout of the first source-drain layer in FIG. 50; FIG. 58 is a structural layout of the second source-drain layer in FIG. 50; FIG. 59 is a structural layout of the electrode layer in FIG. 50; FIG. 60 is a structural layout of the shielding layer and the first active layer in FIG. 50; FIG. 61 is a structural layout of the shielding layer, the first active layer and the first gate layer in FIG. 50; FIG. 62 is a structural layout of the shielding layer, the first active layer, the first gate layer, and the second gate layer in FIG. 50; FIG. 63 is a structural layout of the shielding layer, the first active layer, the first gate layer, the second gate layer and the second active layer in FIG. 50; FIG. 64 is a structural layout of the shielding layer, the first active layer, the first gate layer, the second gate layer, the second active layer, and the third gate layer in FIG. 50; FIG. 65 is a structural layout of the shielding layer, the first active layer, the first gate layer, the second gate layer, the second active layer, the third gate layer, and first source-drain layer in FIG. 50; and FIG. 66 is a structural layout of the shielding layer, the first active layer, the first gate layer, the second gate layer, the second active layer, the third gate layer, the first source-drain layer, and the second source-drain layer in FIG. 50. The display panel may include a plurality of pixel driving circuits shown in FIG. 48. As shown in FIG. 66, the plurality of pixel driving circuits may include a first pixel driving circuit P1 and a second pixel driving circuit P2 adjacently distributed in the first direction X, and the first pixel driving circuit P1 and the second pixel driving circuit P2 may be arranged with mirror symmetry on the mirror symmetry plane BB. The mirror symmetry plane BB may be perpendicular to the base substrate. The orthographic projection of the first pixel driving circuit P1 on the base substrate and the orthographic projection of the second pixel driving circuit P2 on the base substrate may be arranged symmetrically with the intersection line between the mirror symmetry plane BB and the base substrate as the symmetry axis. The first pixel driving circuit P1 and the second pixel driving circuit P2 may form a repeating unit, and the display panel may include a plurality of repeating units distributed in an array in the first direction X and the second direction Y.

As shown in FIGS. 50, 51, and 60, the shielding layer may include multiple shielding parts 61, and adjacent shielding parts 61 may be connected to each other. It should be understood that in other exemplary embodiments, the display panel may not include the shielding layer.

As shown in FIGS. 50, 52, 60, and 61, the first active layer may include a third active part 73, a fourth active part 74, a fifth active part 75, a sixth active part 76 and a seventh active part 76. The third active part 73 may be configured to form a channel region of the driving transistor T3; the fourth active part 74 may be configured to form a channel region of the fourth transistor T4; the fifth active part 75 may be configured to form a channel region of the fifth transistor T5; the sixth active part 76 may be configured to form the channel region of the sixth transistor T6; and the seventh active part 77 may be configured to form the channel region of the seventh transistor T7. The first active layer further includes a ninth active part 79, a tenth active part 710, an eleventh active part 711, a twelfth active part 712, and a thirteenth active part 713. Herein, the ninth active part 79 is connected to a side of the fifth active part 75 away from the third active part 73, and the ninth active part 79 is connected between two adjacent fifth active parts 75 in two repeating units adjacent in the first direction X. The tenth active part 710 is connected between the sixth active part 76 and the seventh active part 77. The eleventh active part 711 is connected between the sixth active part 76 and the third active part 73. The twelfth active part 712 is connected to an end of the fourth active part 74 away from the third active part 73, and the thirteenth active part 713 is connected to an end of the seventh active part 77 away from the sixth active part 76. The orthographic projection of the shielding part 61 on the base substrate can cover the orthographic projection of the third active part 73 on the base substrate, and the shielding part 61 can reduce the impact of light on the driving characteristics of the driving transistor T3. The first active layer may be formed of polysilicon material. Correspondingly, the driving transistor T3, the fourth transistor T4, the fifth transistor T5, the sixth transistor T6, and the seventh transistor T7 may be P-type low-temperature polysilicon thin film transistors.

As shown in FIGS. 50, 53, and 61, the first gate layer may include: a first conductive part 11, a first gate line G1, an enable signal line EM, and a second reset signal line Re2. The first gate line G1 can be configured to provide the first gate driving signal terminal in FIG. 48; the enable signal line EM can be configured to provide the enable signal terminal in FIG. 48; and the second reset signal line Re2 can be configured to provide the second reset signal terminal in FIG. 48. The orthographic projection of the first gate line G1 on the base substrate, the orthographic projection of the enable signal line EM on the base substrate, and the orthographic projection of the second reset signal line Re2 on the base substrate can all extend along the first direction X. The orthographic projection of the first gate line G1 on the base substrate covers the orthographic projection of the fourth active part 74 on the base substrate, a partial structure of the first gate line G1 is configured to form the gate of the fourth transistor. The orthographic projection of the enable signal line EM on the base substrate covers the orthographic projection of the fifth active part 75 on the base substrate and the orthographic projection of the sixth active part 76 on the base substrate, and a partial structure of the enable signal line EM may be configured to form gates of the fifth transistor T5 and the sixth transistor T6 respectively. The orthographic projection of the second reset signal line Re2 on the base substrate can cover the orthographic projection of the seventh active part 77 on the base substrate, and a partial structure of the second reset signal line Re2 can be configured to form the gate of the seventh transistor T7. The orthographic projection of the first conductive part 11 on the base substrate covers the orthographic projection of the third active part 73 on the base substrate. The first conductive part 11 can be configured to form the gate of the driving transistor T3 and the first electrode of the first capacitor C. As shown in FIG. 61, the first gate line G1 in the pixel driving circuit of the current row can be reused as the second reset signal line Re2 in the pixel driving circuit of the next row, and the display panel can be driven row by row from top to bottom. This setting can improve the integration level of the pixel driving circuits and reduce the layout area of the pixel driving circuits. The shielding layer can also be connected to a stable power terminal. For example, the shielding layer can be connected to the first power terminal, the first initial signal terminal, the second initial signal terminal, or the like in FIG. 48. The shielding part 61 can shield the noise impact of other signals on the driving transistor T3. In addition, conduction processing can be performed on the first active layer by using the first gate layer as a mask in the display panel, that is, an area of the first active layer covered by the first gate layer can form the channel region of the transistor, and an area of the first active layer not covered by the first gate layer forms a conductor structure.

As shown in FIGS. 50, 54, and 62, the second gate layer may include: a first initial signal line Vinit1, a third reset signal line 2Re1, a third gate line 2G2, and a plurality of third conductive parts 23. In some embodiments, the first initial signal line Vinit1 is configured to provide the first initial signal terminal in FIG. 48, the third reset signal line 2Re1 can be configured to provide the first reset signal terminal in FIG. 48, and the third gate line 2G2 can be configured to provide the second gate driving signal terminal in FIG. 48. The orthographic projection of the first initial signal line Vinit1 on the base substrate, the orthographic projection of the third reset signal line 2Re1 on the base substrate, and the orthographic projection of the third gate line 2G2 on the base substrate can all extend along the first direction X. As shown in FIG. 54, the second gate layer may further include a plurality of connecting parts 24. In the repeating units adjacent in the first direction X, a connecting part 24 is connected between two third conductive parts 23 adjacent in the first direction X. Furthermore, in other exemplary embodiments, the adjacent third conductive parts 23 in the same repeating unit may also be connected.

As shown in FIGS. 50, 55, and 63, the second active layer may include a first active part 81, a second active part 82, a fourteenth active part 814, a fifteenth active part 815, and a sixteenth active part 816. The first active part 81 is configured to form a channel region of the first transistor T1, and the second active part 82 is configured to form a channel region of the second transistor T2. The fifteenth active part 815 is connected between the first active part 81 and the second active part 82. The fourteenth active part 814 is connected to an end of the first active part 81 away from the second active part 82, and the sixteenth active part 816 is connected to an end of the second active part 82 away from the first active part 81. The second active layer may be formed of indium gallium zinc oxide, and accordingly, the first transistor T1 and the second transistor T2 may be N-type metal oxide thin film transistors. The orthographic projection of the third gate line 2G2 on the base substrate can cover the orthographic projection of the second active part 82 on the base substrate, and a partial structure of the third gate line 2G2 can be configured to form the bottom gate of the second transistor T2. The orthographic projection of the third reset signal line 2Re1 on the base substrate can cover the orthographic projection of the first active part 81 on the base substrate, and a partial structure of the third reset signal line 2Re1 can be configured to form the bottom gate of the first transistor T1.

As shown in FIGS. 50, 56, and 64, the third gate layer may include a first reset signal line 3Re1 and a second gate line 3G2. Both the orthographic projection of the first reset signal line 3Re1 on the base substrate and the orthographic projection of the second gate line 3G2 on the base substrate can extend along the first direction X. The first reset signal line 3Re1 can be configured to provide the first reset signal terminal in FIG. 48. The orthographic projection of the first reset signal line 3Re1 on the base substrate can cover the orthographic projection of the first active part 81 on the base substrate, and a partial structure of the first reset signal line 3Re1 can be configured to form the top gate of the first transistor T1. In addition, the first reset signal line 3Re1 can be connected to the third reset signal line 2Re1 through a via located in the frame area of the display panel. The second gate line 3G2 can be configured to provide the second gate driving signal terminal in FIG. 48. The orthographic projection of the second gate line 3G2 on the base substrate can cover the orthographic projection of the second active part 82 on the base substrate, and a partial structure of the second gate line 3G2 can be configured to form the top gate of the second transistor T2. In addition, the second gate line 3G2 can be connected to the third gate line 2G2 through a via located in the frame area of the display panel. Moreover, conduction processing can be performed on the second active layer by using the third gate layer as a mask in this display panel, that is, an area of the second active layer covered by the third gate layer can form the channel region of the transistor, and an area of the second active layer not covered by the third gate layer forms a conductor structure.

As shown in FIGS. 50, 57, and 65, the first source-drain layer may include a power connection line 4VDD, a second initial signal line Vinit2, a fifth bridging part 45, a sixth bridging part 46, a seventh bridging part 47, an eighth bridging part 48 and a ninth bridging part 49. In some embodiments, the orthographic projection of the power connection line 4VDD on the base substrate extends along the first direction X, and it is connected the connecting part 24 and the ninth active part 79, respectively, through vias, thereby being connected to the first electrode of the fifth transistor and the second electrode of the capacitor. The fifth bridging part 45 may be connected to the tenth active part 710 through a via, thereby being connected to the second electrode of the sixth transistor T6 and the second electrode of the seventh transistor T7. The sixth bridging part 46 can be connected to the eleventh active part 711 and the sixteenth active part 816 respectively through vias, thereby being connected to the second electrode of the second transistor T2, the first electrode of the sixth transistor T6, and the second electrode of the driving transistor T3. The seventh bridging part 47 can be connected to the fifteenth active part 815 and the first conductive part 11 through vias respectively, thereby being connected to the first electrode of the second transistor T2 and the gate of the driving transistor. An opening 231 is formed on the third conductive part 23, and the orthographic projection of the via connected between the first conductive part 11 and the seventh bridging part 47 on the base substrate is located within the orthographic projection of the opening 231 on the base substrate, so that the via and the third conductive part 23 are insulated from each other. The eighth bridging part 48 can be connected to the fourteenth active part 814 and the first initial signal line Vinit1 through vias respectively, thereby being connected to the first electrode of the first transistor and the first initial signal terminal. Herein, in the same repeating unit, two adjacent pixel driving circuits may share the same eighth bridging part 48. The ninth bridging part 49 may be connected to the twelfth active part 712 through a via to connect the first electrode of the fourth transistor. The second initial signal line Vinit2 can be configured to provide the second initial signal terminal in FIG. 48. The orthographic projection of the second initial signal line Vinit2 on the base substrate can extend along the first direction X. The second initial signal line Vinit2 can be connected to the thirteenth active part 713 through a via, thereby being connected to the first electrode of the seventh transistor and the second initial signal terminal.

As shown in FIGS. 50, 58, and 66, the second source-drain layer may include a plurality of first power lines VDD, a plurality of data lines Da, and a tenth bridging part 510. The orthographic projection of the first power line VDD on the base substrate and the orthographic projection of the data line Da on the base substrate can both extend along the second direction Y. The first power line VDD may be configured to provide the first power terminal in FIG. 48, and the data line Da may be configured to provide the data signal terminal in FIG. 48. As shown in FIGS. 50 and 66, each column of pixel driving circuits can be provided with a first power line VDD. The first power line VDD can be connected to the power connection line 4VDD through a via, thereby being connected to the first electrode of the fifth transistor and the first power terminal. The data line Da may be connected to the ninth bridging part 49 through a via, thereby being connected to the first electrode of the fourth transistor and the data signal terminal. The tenth bridging part 510 may be connected to the fifth bridging part 45 through a via, thereby being connected to the second electrode of the seventh transistor. As shown in FIG. 58, in the same repeating unit, adjacent first power lines VDD are connected to each other, so that the first power line VDD, the power connection line 4VDD, and the third conductive part 23 can form a grid structure. Power lines of the grid structure can reduce the voltage drop on the power signal across them. In the same repeating unit, multiple openings VDDx may be formed on the connected first power lines VDD. The openings VDDx may be located in the light-transmitting area of the display panel, that is, the orthographic projection of the openings VDDx on the base substrate may not overlap with the orthographic projection of other non-transparent structural layers on the base substrate. This setting can improve the transmittance of the display panel. The other non-transparent structural layers may include the first gate layer, the second gate layer, the first source-drain layer, a first active layer, and a second active layer.

As shown in FIGS. 50, 58, and 66, the first power line VDD may include a first power line segment VDD1, a second power line segment VDD2, and a third power line segment VDD3. The second power line segment VDD2 is connected between the first power line segment VDD1 and the third power line segment VDD3. The size, in the first direction X, of the orthographic projection of the second power line segment VDD2 on the base substrate may be greater than the size, in the first direction X, of the orthogonal projection of the first power line segment VDD1 on the base substrate, and the size, in the first direction X, of the orthographic projection of the second power line segment VDD2 on the base substrate may be greater than the size, in the first direction X, of the orthogonal projection of the third power line segment VDD3 on the base substrate. In addition, the orthographic projection of the second power line segment VDD2 on the base substrate can also cover the orthographic projection of the first active part 81 on the base substrate and the orthographic projection of the second active part 82 on the base substrate. The second power line segment VDD2 can reduce the impact of light on the characteristics of the first transistor T1 and the second transistor T2. In addition, the orthographic projection of the first power line VDD on the base substrate can also at least partially overlap with the orthographic projection of the seventh bridging part 47 on the base substrate. The first power line VDD can be configured to shield noise interference of other signals on the seventh bridging part 47, thereby improving the stability of the gate voltage of the driving transistor T3.

As shown in FIGS. 50 and 59, the pixel electrode layer may include a plurality of electrode parts: a first electrode part R, a third electrode part G, and a second electrode part B. Each electrode part may be connected to the second electrode of the sixth transistor through a bridging part Bg. In the same electrode row, the first electrode part R, the third electrode part G, the second electrode part B, and the third electrode part G are sequentially distributed alternately in the first direction X. The plurality of electrode parts form a plurality of electrode columns. The plurality of electrode columns include a first electrode column ROW1, a third electrode column ROW3, a second electrode column ROW2, and a fourth electrode column ROW4 that are sequentially adjacent. The first electrode column ROW1 includes the first electrode part R and the second electrode part B distributed alternately in the second direction Y. The third electrode column ROW3 includes a plurality of third electrode parts G distributed in the second direction Y. The second electrode column ROW2 includes the second electrode part B and the first electrode part R distributed alternately in the second direction Y. The fourth electrode column ROW4 includes a plurality of third electrode parts G distributed in the second direction Y. The minimum distance S1, in the second direction Y, between the orthographic projections, on the base substrate, of two third electrode parts G located in adjacent electrode rows of the same electrode column is greater than the dimension S2, in the second direction Y, of the orthogonal projection of the first electrode part R on the base substrate, or greater than the dimension S3, in the second direction Y, of the orthogonal projection of the second electrode part B on the base substrate. In some embodiments, the orthographic projection of the first electrode part R on the base substrate coincides with the orthographic projection, on the base substrate, of its corresponding opening on the pixel definition layer; the orthographic projection of the third electrode part G on the base substrate coincides with the orthographic projection, on the base substrate, of its corresponding opening on the pixel definition layer; and the orthographic projection of the second electrode part B on the base substrate coincides with the orthographic projection, on the base substrate, of its corresponding opening on the pixel definition layer. In the same repeating unit, two second power line segments VDD2 in adjacent first power lines VDD are connected. The orthographic projections of the two connected second power line segments VDD2 on the base substrate cover the orthographic projection of the electrode part on the base substrate that intersects with the orthographic projections of the two connected second power line segments VDD2. This setting can make the height of each position of the electrode part more uniform.

As shown in FIGS. 50 and 59, the electrode layer may further include a first bridging part Bg1 and a second bridging part Bg2. The first bridging part Bg1 is connected to the first electrode part R in the third electrode column ROW3, and the first bridging part Bg1 is connected to the tenth bridging part 510 in the pixel driving circuit of the second row and first column through a via. The second bridging part Bg2 is connected to the second electrode part B in the first electrode column ROW1, and the second bridging part Bg2 is connected to the tenth bridging part 510 in the pixel driving circuit of the second row and third column through a via.

It should be noted that, as shown in FIGS. 50, 65, and 66, the black squares illustrated on the side of the first source-drain layer away from the base substrate represent the vias through which the first source-drain layer is connected to other layers on the side facing the base substrate; the black squares illustrated on the side of the second source-drain layer away from the base substrate represent the vias through which the second source-drain layer is connected to other layers on the side facing the base substrate; the black squares illustrated on the side of the electrode layer away from the base substrate represent the vias through which the electrode layer is connected to other layers on the side facing the base substrate. The black squares only indicate the positions of the vias. Different vias represented by black squares at different positions can penetrate different insulation layers.

As shown in FIG. 67, it is a partial cross-sectional view of the display panel shown in FIG. 50 taken along the dotted line CC. The display panel may further include a first insulating layer 91, a second insulating layer 92, a third insulating layer 93, a fourth insulating layer 94, a fifth insulating layer 95, a first dielectric layer 96, a passivation layer 97, a first planarization layer 98, and a second planarization layer 99, where the base substrate 90, the shielding layer, the first insulating layer 91, the first active layer, the second insulating layer 92, the first gate layer, the third insulating layer 93, the second gate layer, the fourth insulating layer 94, the second active layer, the fifth insulating layer 95, the third gate layer, the first dielectric layer 96, the first source-drain layer, the passivation layer 97, the first planarization layer 98, the second source-drain layer, and the second planarization layer 99 are stacked in sequence. The first insulating layer 91, the second insulating layer 92, the third insulating layer 93, the fourth insulating layer 94 and the fifth insulating layer 95 can be a single-layer structure or a multi-layer structure, and the material of the first insulating layer 91, the second insulating layer 92, the third insulating layer 93, the fourth insulating layer 94, and the fifth insulating layer 95 can be at least one of silicon nitride, silicon oxide, and silicon oxynitride. The first dielectric layer 96 can be silicon nitride layer. The material of the first planarization layer 98 and the second planarization layer 99 can be organic materials, such as polyimide (PI), polyethylene terephthalate (PET), polyethylene naphthalate (PEN), silicon-glass bonding structure (SOG) and the like. The passivation layer 97 may be a silicon oxide layer. The base substrate 90 may include a glass base substrate, a barrier layer, and a polyimide layer that are stacked in sequence. The barrier layer may be an inorganic material. The material of the first gate layer, the second gate layer, and the third gate layer may be one of molybdenum, aluminum, copper, titanium, niobium or an alloy thereof, or a molybdenum/titanium alloy or laminate or other conductive layer. The material of the first source-drain layer and the second source-drain layer may include a metal material, for example, it may be one of molybdenum, aluminum, copper, titanium, niobium or an alloy thereof, or a molybdenum/titanium alloy or laminate, or titanium/aluminum/titanium laminate or other conductive layers.

It should be understood that in other exemplary embodiments, the first bridging part and the second bridging part may also be located on other conductive layers. For example, the first bridging part and the second bridging part may be located on a bridging layer added between the second source-drain layer and the electrode layer.

As shown in FIGS. 68-70, FIG. 68 is a structural layout of the display panel according to another exemplary embodiment of this disclosure, FIG. 69 is a structural layout of the first active layer, the first gate layer, the second gate layer, the first source-drain layer, the second source-drain layer, and the bridging layer in FIG. 68, and FIG. 70 is a structural layout of the bridging layer in FIG. 68.

The display panel shown in FIG. 68 is different from the display panel shown in FIG. 50 in the followings. In the display panel shown in FIG. 68, the bridging layer may include a plurality of bridging parts Bg, and the bridging parts Bg are respectively connected to the tenth bridging parts 510 and the electrode parts through vias. The plurality of bridging parts include a first bridging part Bg1 and a second bridging part Bg2. The first bridging part Bg1 may be connected to the tenth bridging part 510 in the pixel driving circuit of the first column and the second row and the first electrode part R in the third electrode column through vias. The second bridging part Bg2 may be connected to the tenth bridging part 510 in the pixel driving circuit of the third column and the second row and the second electrode part B in the first electrode column through vias.

As shown in FIG. 71, it is a schematic structural diagram of a source driving circuit in a display panel of this disclosure. The source driving circuit may include a data latch 03 and a data reset circuit 04. The data latch 03 may be configured to receive multiple original data signals, where the original data signals include multiple original data in series, and at least part of the original data in the original data signals is configured to drive light-emitting units of different colors. The reset circuit 04 is configured to generate a reset data signal according to the original data signal, where the reset data signal includes multiple reset data in series, and the reset data in the same reset data signal is configured to drive light-emitting units of the same color. The source driving circuit may further include a random access memory 01, a data control circuit 02, a boost circuit 05, a digital-to-analog (D/A) converter 06, a data output terminal 07, a timing controller TCON, and a gamma module 08. The random access memory 01 is configured to receive picture data. The data control circuit 02 is configured to optimize the picture data to generate the original data signals. The boost circuit 05 boosts the reset data signal. The digital-to-analog converter 06 performs digital-to-analog conversion on the boosted reset data signal. The data output terminal 07 transmits the reset data signal after digital-to-analog conversion to the corresponding data lines. The timing controller TCON controls the operation timing of the data control circuit 02, the data latch 03, and the data reset circuit 04. The gamma module 08 is configured to provide gamma data, and the gamma data may include gamma voltages corresponding to each gray scale under each brightness value. For example, in the display panel shown in FIG. 6, the original data signal corresponding to the first data line connected to the first pixel circuit column PX1 includes multiple series of original data, and the multiple series of original data are used for alternately driving the red light-emitting unit and blue light-emitting unit; the original data signal corresponding to the second data line connected to the second pixel circuit column PX2 includes multiple series of original data, and the multiple series of original data are used for alternately driving the red light-emitting unit and blue light-emitting unit. The data reset circuit 04 can replace the original data corresponding to the first data line for driving the blue light-emitting unit with the original data corresponding to the second data line for driving the red light-emitting unit and, also, replace the original data corresponding to the second data line for driving the red light-emitting unit with the original data corresponding to the first data line for driving the blue light-emitting unit, thereby generating the reset data signal.

It should be noted that the scale of the drawings in this disclosure can be used as a reference in the actual process, but is not limited thereto. For example, the width-to-length ratio of the channel, the thickness and spacing of each film layer, the width and spacing of each signal line, and the like can be adjusted according to actual needs. The number of pixels in the display base substrate and the number of sub-pixels in each pixel are not limited to the numbers shown in the drawings. The drawings described in this disclosure are only structural schematic diagrams. In addition, the qualifiers such as “first” and “second” are only configured to define different structure names and have no specific order meaning. The same structural layer can be formed through the same patterning process. In this exemplary embodiment, when referring to that the orthographic projection of a certain structure on the base substrate extends along a certain direction, it may be understood as that the orthographic projection of the structure on the base substrate extends straightly or in a bend manner along the direction.

This exemplary embodiment further provides a display device, which includes the above-mentioned display panel. The display device can be a display device such as a mobile phone, a tablet computer, or a television.

Other embodiments of the disclosure will be readily apparent to those skilled in the art from consideration of the specification and practice of the disclosure herein. This application is intended to cover any variations, uses, or adaptations of the disclosure that follow the general principles of the disclosure and include common knowledge or customary technical means in the technical field that are not disclosed in the disclosure. It is intended that the specification and examples be considered as exemplary only, with a true scope and spirit of the disclosure being indicated by the following claims.

It is to be understood that this disclosure is not limited to the precise structures described above and illustrated in the accompanying drawings, and various modifications and changes may be made without departing from the scope thereof. The scope of the disclosure is limited only by the appended claims.

1. A display panel, comprising:
a base substrate;
an electrode layer, located on a side of the base substrate, wherein the electrode layer comprises a plurality of electrode parts forming first electrodes of light-emitting units, orthographic projections of the electrode parts on the base substrate are distributed in an array along a first direction and a second direction, the first direction intersects with the second direction, electrode columns are formed by the electrode parts distributed in the second direction, and at least part of the electrode columns comprises electrode parts forming the first electrodes of the light-emitting units of different colors;
a plurality of pixel driving circuits, provided corresponding to the electrode parts, wherein the pixel driving circuits are connected to corresponding electrode parts, respectively, and the pixel driving circuits drive the light-emitting units to emit light; and
a plurality of data lines, wherein orthographic projections of the data lines on the base substrate are spaced apart along the first direction and extend along the second direction, the data lines are connected to the pixel driving circuits and configured to provide data signals to connected pixel driving circuits, respectively, and multiple ones of the pixel driving circuits connected to a same one of the data lines drive the light-emitting units of a same color.

2. The display panel according to claim 1, wherein the electrode parts comprise first electrode parts and second electrode parts, and the first electrode parts and the second electrode parts respectively form the first electrodes of the light-emitting units of different colors;
wherein the electrode columns comprise:
a first electrode column, comprising at least one of the first electrode parts and at least one of the second electrode parts, wherein in the first electrode column, orthographic projections of the first electrode part and the second electrode part on the base substrate are alternately distributed along the second direction;
a second electrode column, comprising at least one of the first electrode parts and at least one of the second electrode parts, wherein in the second electrode column, orthographic projections of the first electrode part and the second electrode part on the base substrate are alternately distributed along the second direction;
wherein, in the first electrode column and the second electrode column, the first electrode part and the second electrode part are located in a same row; and
wherein the data lines comprise:
a first data line, wherein a pixel driving circuit connected to the first data line is connected to the first electrode parts in the first electrode column and the second electrode column; and
a second data line, wherein a pixel driving circuit connected to the second data line is connected to the second electrode parts in the first electrode column and the second electrode column.

3. The display panel according to claim 2, wherein the electrode parts further comprise third electrode parts, wherein the first electrode parts, the second electrode parts, and the third electrode parts respectively form the first electrodes of the light-emitting units of different colors;
wherein the electrode columns further comprise: a third electrode column and a fourth electrode column, and the first electrode column, the third electrode column, the second electrode column and the fourth electrode column are alternately distributed in sequence along the first direction;
wherein the third electrode column comprises multiple ones of the third electrode parts, and orthographic projections of the third electrode parts in the third electrode column on the base substrate are spaced apart in the second direction; and
wherein the fourth electrode column comprises multiple ones of the third electrode parts, and orthographic projections of the third electrode parts in the fourth electrode column on the base substrate are spaced apart in the second direction.

4. The display panel according to claim 2, wherein orthographic projections of the pixel driving circuits on the base substrate are distributed in an array along the first direction and the second direction, pixel circuit columns are formed by the pixel driving circuits distributed in the second direction, and the pixel circuit columns comprise a first pixel circuit column and a second pixel circuit column;
pixel driving circuits in the first pixel circuit column are connected to the electrode parts in the first electrode column;
pixel driving circuits in the second pixel circuit column are connected to the electrode parts in the second electrode column;
the first data line is connected to the pixel driving circuit connected to the first electrode parts in the first electrode column and the second electrode column; and
the second data line is connected to the pixel driving circuit connected to the second electrode parts in the first electrode column and the second electrode column.

5. The display panel according to claim 2, wherein orthographic projections of the pixel driving circuits on the base substrate are distributed in an array along the first direction and the second direction, pixel circuit columns are formed by the pixel driving circuits distributed in the second direction, and the pixel circuit columns comprise a first pixel circuit column and a second pixel circuit column;
wherein the first data line is connected to pixel driving circuits in the first pixel circuit column, and the second data line is connected to pixel driving circuits in the second pixel circuit column; and
wherein the display panel further comprises:
a first bridging part, connected between the pixel driving circuit in the first pixel circuit column and the first electrode part in the second electrode column; and
a second bridging part, connected between the pixel driving circuit in the second pixel circuit column and the second electrode part in the first electrode column.

6. The display panel according to claim 5, further comprising:
a first signal line, wherein an orthographic projection of the first signal line on the base substrate extends along the first direction; and
a second signal line, wherein an orthographic projection of the second signal line on the base substrate extends along the first direction,
wherein the first signal line and the second signal line are configured to provide stable voltage signals;
wherein the first bridging part comprises a first extension portion, the second bridging part comprises a second extension portion, and an orthographic projection of the first extension portion on the base substrate and an orthographic projection of the second extension portion on the base substrate extend along the first direction; and
wherein the orthographic projection of the first extension portion on the base substrate at least partially overlaps with the orthographic projection of the first signal line on the base substrate, and/or the orthographic projection of the second extension portion on the base substrate at least partially overlaps with the orthographic projection of the second signal line on the base substrate.

7. The display panel according to claim 6, wherein the pixel driving circuit comprises a driving transistor, a first transistor, and a seventh transistor, a first electrode of the first transistor is connected to a first initial signal line, a second electrode of the first transistor is connected to a gate of the driving transistor, a first electrode of the seventh transistor is connected to a second initial signal line, and a second electrode of the seventh transistor is connected to a second electrode of the driving transistor; and
the first initial signal line forms the first signal line, and the second initial signal line forms the second signal line; or, the first initial signal line forms the second signal line, and the second initial signal line forms the first signal line.

8. The display panel according to claim 6, wherein the pixel driving circuit comprises a driving transistor and a first transistor, a first electrode of the first transistor is connected to a first initial signal line, and a second electrode of the first transistor is connected to a gate of the driving transistor; and
two adjacent first initial signal lines form the first signal line and the second signal line respectively.

9. The display panel according to claim 5, further comprising:
a third signal line, wherein an orthographic projection of the third signal line on the base substrate extends along the second direction, and the third signal line is configured to provide a stable voltage signal;
wherein the second bridging part further comprises a third extension portion, an orthographic projection of the third extension portion on the base substrate extends along the second direction, and the orthographic projection of the third extension portion on the base substrate at least partially overlaps with the orthographic projection of the third signal line on the base substrate.

10. The display panel according to claim 5, further comprising:
a fourth signal line, wherein an orthographic projection of the fourth signal line on the base substrate extends along the second direction, and the fourth signal line is configured to provide a stable voltage signal;
wherein the first bridging part further comprises a sixth extension portion, an orthographic projection of the sixth extension portion on the base substrate extends along the second direction, and the orthographic projection of the sixth extension portion on the base substrate at least partially overlaps with the orthographic projection of the fourth signal line on the base substrate.

11. The display panel according to claim 5, wherein the pixel driving circuit comprises a driving transistor and a second transistor, a first electrode of the second transistor is connected to a gate of the driving transistor, and a second electrode of the second transistor is connected to a second electrode of the driving transistor;
wherein the display panel further comprises:
a first active layer, located between the base substrate and the electrode layer, wherein the first active layer comprises a second active part forming a channel region of the second transistor, and
wherein the second bridging part comprises a second extension portion, a third extension portion, and a seventh extension portion connected between the second extension portion and the third extension portion, an orthographic projection of the second extension portion on the base substrate extends along the first direction, an orthographic projection of the third extension portion on the base substrate extends along the second direction, and an orthographic projection of the seventh extension portion on the base substrate at least partially overlaps with an orthographic projection of the second active part on the base substrate.

12. The display panel according to claim 5, further comprising:
a third bridging part, connected between the pixel driving circuit in the first pixel circuit column and the first electrode part in the first electrode column; and
a fourth bridging part, connected between the pixel driving circuit in the second pixel circuit column and the second electrode part in the second electrode column.

13. The display panel according to claim 12, wherein the first bridging part is connected between a pixel driving circuit and an electrode part located in a same row, the second bridging part is connected between a pixel driving circuit and an electrode part located in a same row, the third bridging part is connected between a pixel driving circuit and an electrode part located in a same row and column, and the fourth bridging part is connected between a pixel driving circuit and an electrode part located in a same row and column.

14. The display panel according to claim 12, wherein a parasitic capacitance formed by the first bridging part and other structures is C1, a parasitic capacitance formed by the second bridging part and other structures is C2, a parasitic capacitance formed by the third bridging part and other structures is C3, and a parasitic capacitance formed by the fourth bridging part and other structures is C4;
wherein C1=N1*C3, C2=N2*C4, where N1 is greater than or equal to 70% and less than or equal to 130%, and N2 is greater than or equal to 70% and less than or equal to 130%.

15. The display panel according to claim 12, further comprising:
a plurality of third signal lines, wherein orthogonal projections of the third signal lines on the base substrate are spaced apart along the first direction and extend along the second direction, and the third signal lines are configured to provide a stable voltage signal;
wherein the third bridging part comprises a fourth extension portion, the fourth bridging part comprises a fifth extension portion, and an orthogonal projection of the fourth extension portion on the base substrate and an orthogonal projection of the fifth extension portion on the base substrate extend along the second direction; and
wherein the orthographic projection of the fourth extension portion on the base substrate at least partially overlaps with an orthographic projection of a third signal line on the base substrate, and the orthographic projection of the fifth extension portion on the base substrate at least partially overlaps with an orthographic projection of another third signal line on the base substrate.

16. The display panel according to claim 9, wherein the pixel driving circuit comprises a driving transistor, and the display panel further comprises:
a first power line, connected to a first electrode of the driving transistor, and the first power line forms the third signal line.

17. The display panel according to claim 12, further comprising:
a first source-drain layer, located between the base substrate and the electrode layer; and
a second source-drain layer, located between the first source-drain layer and the electrode layer,
wherein the first bridging part, the second bridging part, the third bridging part, and the fourth bridging part are located on the electrode layer; or, the first bridging part, the second bridging part, the third bridging part, and the fourth bridging part are located on a conductive layer between the second source-drain layer and the electrode layer; or, the first bridging part, the second bridging part, the third bridging part, and the fourth bridging part are located on a conductive layer between the second source-drain layer and the first source-drain layer.

18. The display panel according to claim 1, further comprising a source driving circuit, wherein the source driving circuit comprises:
a data latch, configured to receive a plurality of original data signals, wherein the original data signals comprise multiple pieces of serial original data, the original data in at least part of the original data signals is configured to drive the light-emitting units of different colors; and
a data resetter, configured to generate a reset data signal according to the original data signal, wherein the reset data signal comprises multiple pieces of serial reset data, and the reset data in the reset data signal is configured to drive the light-emitting units of the same color.

19. The display panel according to claim 1, wherein the pixel driving circuit comprises a driving transistor and a second transistor, a first electrode of the second transistor is connected to a gate of the driving transistor, and a second electrode of the second transistor is connected to a second electrode of the driving transistor;
wherein the display panel further comprises:
a first active layer, located between the base substrate and the electrode layer, wherein the first active layer comprises a second active part, and the second active part forms a channel region of the second transistor; and
wherein the electrode layer further comprises:
an addition part, connected to the electrode part, wherein an orthographic projection of the addition part on the base substrate at least partially overlaps with an orthographic projection of the second active part on the base substrate.

20-25. (canceled)

26. A display device, a display panel, wherein the display panel comprises:
a base substrate;
an electrode layer, located on a side of the base substrate, wherein the electrode layer comprises a plurality of electrode parts forming first electrodes of light-emitting units, orthographic projections of the electrode parts on the base substrate are distributed in an array along a first direction and a second direction, the first direction intersects with the second direction, electrode columns are formed by the electrode parts distributed in the second direction, and at least part of the electrode columns comprises electrode parts forming the first electrodes of the light-emitting units of different colors;
a plurality of pixel driving circuits, provided corresponding to the electrode parts, wherein the pixel driving circuits are connected to corresponding electrode parts, respectively, and the pixel driving circuits drive the light-emitting units to emit light; and
a plurality of data lines, wherein orthographic projections of the data lines on the base substrate are spaced apart along the first direction and extend along the second direction, the data lines are connected to the pixel driving circuits and configured to provide data signals to connected pixel driving circuits, respectively, and multiple ones of the pixel driving circuits connected to a same one of the data lines drive the light-emitting units of a same color.
